(19) United States
(12) Patent Application Publication
(10) Pub. No.: US 2022/0310935 A1
(43) Pub. Date: Sep. 29, 2022

(54) ORGANIC LIGHT-EMITTING DEVICE

(71) Applicant: LG CHEM, LTD., Seoul (KR)

(72) Inventors: So Young CHOI, Daejeon (KR); Yongbum CHA, Daejeon (KR); Hoon Jun KIM, Daejeon (KR); Eunjin HAN, Daejeon (KR); Hyungjin LEE, Daejeon (KR); Wanpyo HONG, Daejeon (KR); Min Woo LEE, Daejeon (KR); Mina KIM, Daejeon (KR); Sangmin OH, Daejeon (KR); Sangjoon KIM, Daejeon (KR)

(21) Appl. No.: 17/615,908

(22) PCT Filed: Jun. 18, 2020
(86) PCT No.: PCT/KR2020/007914

§ 371 Date: Dec. 2, 2021

(30) Foreign Application Priority Data
Feb. 28, 2020 (KR) 10-2020-0025088

(51) Int. Cl. H01L 51/00

(52) U.S. Cl. CPC H01L 51/0072; H01L 51/0073; H01L 51/0054; H01L 51/5206

(57) ABSTRACT

Provided is an organic light-emitting device comprising an anode, a cathode, and a first organic layer and a second organic layer provided between the anode and the cathode, wherein the first organic layer comprises a compound of Chemical Formula 1:

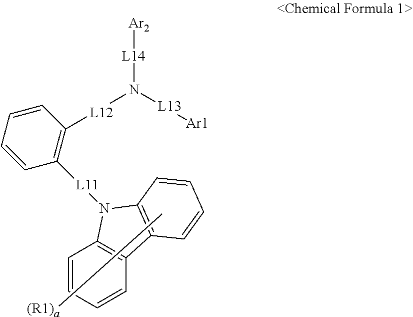

and the second organic layer comprises a compound Chemical Formula 2:

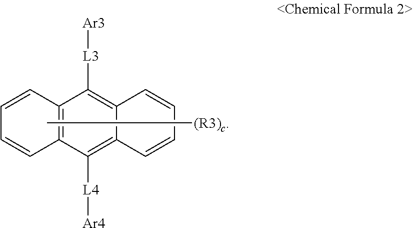

### CROSS-REFERENCE TO RELATED APPLICATION

This application is a National Stage Application of International Application No. PCT/KR2020/007914 filed on Jun. 18, 2020, which claims priority to and the benefits of Korean Patent Application No. 10-2020-0025088, filed with the Korean Intellectual Property Office on Feb. 28, 2020, the entire contents of which are incorporated herein by reference.

### TECHNICAL FIELD

The present specification relates to an organic light emitting device.

### BACKGROUND ART

An organic light emitting device has a structure disposing an organic thin film between two electrodes. When a voltage is applied to an organic light emitting device having such a structure, electrons and holes injected from the two electrodes bind and pair in the organic thin film, and light emits as these annihilate. The organic thin film can be formed in a single layer or a multilayer as necessary.

Materials used in an organic light emitting device are mostly pure organic materials or complex compounds in which organic materials and metals form complexes, and can be divided into hole injection materials, hole transfer materials, light emitting materials, electron transfer materials, electron injection materials and the like depending on the application. Herein, as the hole injection material or the hole transfer material, organic materials having a p-type property, that is, organic materials readily oxidized and having an electrochemically stable state when oxidized, are generally used. Meanwhile, as the electron injection material or the electron transfer material, organic materials having an n-type property, that is, organic materials readily reduced and having an electrochemically stable state when reduced, are generally used. As the light emitting layer material, materials having both a p-type property and an n-type property, that is, materials having a stable form in both oxidized and reduced states, are preferred, and materials having high light emission efficiency converting, when excitons produced by holes and electrons recombining in a light emitting layer are formed, the excitons to light are preferred.

Development of an organic thin film material has been continuously required for enhancing performance, lifetime or efficiency of an organic light emitting device.

### PRIOR ART DOCUMENTS

(Patent Document 1) KR 2018-0043744 A

### BRIEF DESCRIPTION

### Technical Problem

The present specification describes an organic light emitting device having low driving voltage, high efficiency or long lifetime properties.

### Technical Solution

One embodiment of the present specification provides an organic light emitting device including

an anode;

a cathode; and

a first organic material layer and a second organic material layer provided between the anode and the cathode,

wherein the first organic material layer includes a compound of the following Chemical Formula 1, and the second organic material layer includes a compound of the following Chemical Formula 2:

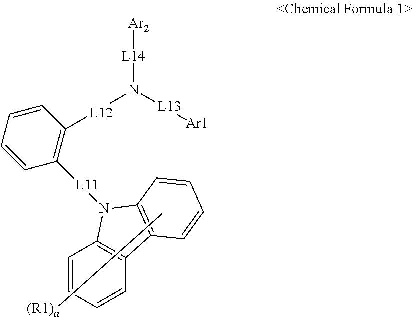

wherein in Chemical Formula 1:

L11 to L14 are the same as or different from each other, and each independently is a direct bond or a substituted or unsubstituted arylene group,

Ar1 and Ar2 are the same as or different from each other, and each independently is a substituted or unsubstituted aryl group or a substituted or unsubstituted heterocyclic group;

R1 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group; and

a is an integer of 0 to 8, and when a is 2 or greater, the two or more R1s are the same as or different from each other;

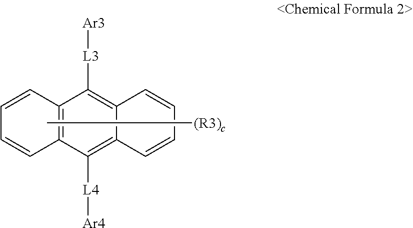

wherein in Chemical Formula 2:

L3 and L4 are the same as or different from each other, and each independently is a direct bond or a substituted or unsubstituted arylene group;

Ar3 and Ar4 are the same as or different from each other, and each independently is a substituted or unsubstituted aryl group or a substituted or unsubstituted heterocyclic group;

R3 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group;

c is an integer of 0 to 8, and when c is 2 or greater, the two or more R3s are the same as or different from each other; and

the compound of Chemical Formula 2 is substituted with deuterium by at least 40%.

### Advantageous Effects

By an organic light emitting device of the present disclosure including a compound of Chemical Formula 1 in a first organic material layer, and a compound of Chemical Formula 2 in a second organic material layer at the same time, an organic light emitting device having low driving voltage, high efficiency or long lifetime is provided.

### DESCRIPTION OF THE DRAWINGS

FIG. 1 illustrates an example of an organic light emitting device formed with a substrate (1), an anode (2), an electron blocking layer (5), a light emitting layer (6) and a cathode (10).

FIG. 2 illustrates an example of an organic light emitting device formed with a substrate (1), an anode (2), a hole injection layer (3), a hole transfer layer (4), an electron blocking layer (5), a light emitting layer (6), a hole blocking layer (7), an electron transfer layer (8), an electron injection layer (9) and a cathode (10).

### REFERENCE NUMERALS

1: Substrate
2: Anode
3: Hole Injection Layer
4: Hole Transfer Layer
5: Electron Blocking Layer
6: Light Emitting Layer
7: Hole Blocking Layer
8: Electron Transfer Layer
9: Electron Injection Layer
10: Cathode

### DETAILED DESCRIPTION

Hereinafter, the present specification will be described in more detail.

One embodiment of the present specification provides an organic light emitting device including an anode; a cathode; and a first organic material layer and a second organic material layer provided between the anode and the cathode, wherein the first organic material layer includes a compound of Chemical Formula 1, and the second organic material layer includes a compound of Chemical Formula 2.

Chemical Formula 1 has a structure in which N of a carbazole group and an amine group bond through an ortho position of a phenylene group, and the amine group is substituted with dibenzofuran or dibenzothiophene. When the ortho-phenylene functions as a linker, the material becomes bulky, which is effective in increasing device efficiency.

In Chemical Formula 2, an aryl group or a heterocyclic group is linked to the number 9 and 10 carbons of anthracene. In addition, Chemical Formula 2 includes deuterium in at least 40%, which improves device efficiency and lifetime. Specifically, when hydrogen is replaced by deuterium, chemical properties of a compound hardly change. However, since an atomic weight of deuterium is twice the atomic weight of hydrogen, the deuterated compound can have its physical properties changed. For example, the compound substituted with deuterium has a decreased vibration energy level. The compound substituted with deuterium can prevent a decrease in the intermolecular Van der Waals force or a decrease in the quantum efficiency caused by collision due to intermolecular vibration. In addition, the C-D bond can improve compound stability. As a result, by the compound of Chemical Formula 2 including deuterium in an amount of 40% or greater, device efficiency and lifetime can be improved.

The compound of Chemical Formula 2 including deuterium can be prepared using known deuteration reactions. According to one embodiment of the present specification, the compound of Chemical Formula 2 can be formed using a deuterated compound as a precursor, or deuterium can also be introduced to the compound through a hydrogen-deuterium exchange reaction using a deuterated solvent under an acid catalyst.

Through the high efficiency properties of Chemical Formula 1 described above and through the long lifetime properties based on material stability of Chemical Formula 2 described above, an organic light emitting device with high efficiency and long lifetime can be obtained.

In the present specification, a certain part “including” certain constituents means capable of further including other constituents, and does not exclude other constituents unless particularly stated on the contrary.

In the present specification, one member being placed “on” another member includes not only a case of the one member being in contact with the another member but a case of still another member being present between the two members.

In the present specification, the “layer” has a meaning compatible with a ‘film’ normally used in the art, and means a coating covering a target area. The size of the ‘layer’ is not limited, and each ‘layer’ can have the same or a different size. In one embodiment, the size of the ‘layer’ can be the same as the size of the whole device, can corresponding to a size of a specific functional region, or can be as small as a single sub-pixel.

In the present specification, the meaning of a specific A material being included in a B layer includes both i) one or more types of A materials being included in one B layer and ii) a B layer being formed in one or more layers, and an A material being included in one or more layers of the multilayered-B layer.

In the present specification, the meaning of a specific A material being included in a C layer or a D layer includes all of i) being included in one or more layers of one or more C layers, ii) being included in one or more layers of one or more D layers, or iii) being included in each of one or more C layers and one or more D layers.

In the present specification, being substituted with deuterium means at least one of hydrogens available in the corresponding structure being substituted with deuterium.

In the present specification, being substituted with deuterium by N % means N % of hydrogens available in the corresponding structure being substituted with deuterium. For example, being substituted with deuterium by 25% in dibenzofuran means two of eight hydrogens of dibenzofuran being substituted with deuterium.

In the present specification, the degree of deuteration can be identified using known methods such as nuclear magnetic resonance spectroscopy (¹H NMR) or GC/MS.

In the present specification,

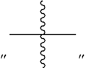

means a position bonding to a chemical formula or compound.

Examples of substituents in the present specification are described below, however, the substituents are not limited thereto.

The term “substitution” means a hydrogen atom bonding to a carbon atom of a compound being changed to another substituent, and the position of substitution is not limited as long as it is a position at which the hydrogen atom is substituted, that is, a position at which a substituent can substitute, and when two or more substituents substitute, the two or more substituents can be the same as or different from each other.

The term “substituted or unsubstituted” in the present specification means being substituted with one, two or more substituents selected from the group consisting of deuterium, a halogen group, a nitrile group, a nitro group, an imide group, an amide group, a carbonyl group, an ether group, an ester group, a hydroxyl group, an alkyl group, a cycloalkyl group, an alkoxy group, an aryloxy group; an alkylthioxy group, an arylthioxy group, an alkylsulfoxy group, an arylsulfoxy group, an alkenyl group, a silyl group, a boron group, an amine group, an arylphosphine group, a phosphine oxide group, an aryl group, and a heteroaryl group, or being substituted with a substituent linking two or more substituents among the substituents illustrated above, or having no substituents. For example, “a substituent linking two or more substituents” can include a biphenyl group. In other words, a biphenyl group can be an aryl group, or interpreted as a substituent linking two phenyl groups.

The term “substituted or unsubstituted” in the present specification means being substituted with one, two or more substituents selected from the group consisting of deuterium, a halogen group, an alkyl group, a cycloalkyl group, an amine group, an aryl group; and a heterocyclic group, or being substituted with a substituent linking two or more substituents among the substituents illustrated above, or having no substituents.

The term “substituted or unsubstituted” in the present specification can mean being substituted with one, two or more substituents selected from the group consisting of deuterium; an alkyl group; a cycloalkyl group; an amine group; an aryl group; and a heterocyclic group, or being substituted with a substituent linking two or more substituents among the substituents illustrated above, or having no substituents.

The term “substituted or unsubstituted” in the present specification can mean being substituted with one, two or more substituents selected from the group consisting of deuterium; an alkyl group; an aryl group; and a heterocyclic group, or being substituted with a substituent linking two or more substituents among the substituents illustrated above, or having no substituents.

The term “substituted or unsubstituted” in the present specification can mean being substituted with one, two or more substituents selected from the group consisting of deuterium; an aryl group; and a heterocyclic group, or being substituted with a substituent linking two or more substituents among the substituents illustrated above, or having no substituents.

The term “substituted or unsubstituted” in the present specification can mean being substituted with one, two or more substituents selected from the group consisting of deuterium; or an aryl group, or being substituted with a substituent linking two or more substituents among the substituents illustrated above, or having no substituents.

Examples of the substituents are described below, however, the substituents are not limited thereto.

In the present specification, examples of the halogen group can include fluorine (—F), chlorine (—Cl), bromine (—Br) or iodine (—I).

In the present specification, the silyl group can be of a chemical formula of —SiYₐY_{b}Y_{c}, and Yₐ, Y_{b} and Y_{c} can each be hydrogen, a substituted or unsubstituted alkyl group, or a substituted or unsubstituted aryl group. Specific examples of the silyl group can include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but are not limited thereto.

In the present specification, the boron group can be a chemical formula of —BY_{d}Yₑ, and Y_{d} and Yₑ can each be hydrogen, a substituted or unsubstituted alkyl group, or a substituted or unsubstituted aryl group. Specific examples of the boron group can include a trimethylboron group, a triethylboron group, a t-butyldimethylboron group, a triphenylboron group, a phenylboron group and the like, but are not limited thereto.

In the present specification, the alkyl group can be linear or branched, and although not particularly limited thereto, the number of carbon atoms is preferably from 1 to 60. According to one embodiment, the number of carbon atoms of the alkyl group is from 1 to 30. According to another embodiment, the number of carbon atoms of the alkyl group is from 1 to 20. According to another embodiment, the number of carbon atoms of the alkyl group is from 1 to 10. Specific examples of the alkyl group can include a methyl group, an ethyl group, a propyl group, an n-propyl group, an isopropyl group, a butyl group, an n-butyl group, an isobutyl group, a tert-butyl group, a pentyl group, an n-pentyl group, a hexyl group, an n-hexyl group, a heptyl group, an n-heptyl group, an octyl group, an n-octyl group and the like, but are not limited thereto.

In the present specification, the arylalkyl group means an alkyl group substituted with an aryl group.

In the present specification, the alkoxy group can be linear, branched or cyclic. The number of carbon atoms of the alkoxy group is not particularly limited, but is preferably from 1 to 20. Specific examples thereof can include methoxy, ethoxy, n-propoxy, i-propyloxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy and the like, but are not limited thereto.

In the present specification, the alkenyl group can be linear or branched, and although not particularly limited thereto, the number of carbon atoms is preferably from 2 to 30, 2 to 20, 2 to 10, or 2 to 5. Specific examples thereof can include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group and the like, but are not limited thereto.

In the present specification, the alkynyl group is a substituent including a triple bond between carbon atoms, and can be linear or branched. Although not particularly limited thereto, the number of carbon atoms of the alkynyl group is preferably from 2 to 40. According to one embodiment, the number of carbon atoms of the alkynyl group is from 2 to 20. According to another embodiment, the number of carbon atoms of the alkynyl group is from 2 to 10.

The alkyl group, the alkoxy group and substituents including other alkyl group parts described in the present specification include all of linear or branched forms.

In the present specification, the cycloalkyl group is not particularly limited, but preferably has 3 to 60 carbon atoms, and according to one embodiment, the number of carbon atoms of the cycloalkyl group is from 3 to 30. According to another embodiment, the number of carbon atoms of the cycloalkyl group is from 3 to 20. According to another embodiment, the number of carbon atoms of the cycloalkyl group is from 3 to 6. Specific examples thereof can include a cyclopropyl group, a cyclobutyl group, a cyclopentyl group, a cyclohexyl group, a cycloheptyl group, a cyclooctyl group and the like, but are not limited thereto.

In the present specification, the amine group can be selected from the group consisting of —NH₂, an alkylamine group, an arylalkylamine group, an arylamine group, an arylheteroarylamine group, an alkylheteroarylamine group, and a heteroarylamine group, but is not limited thereto. The number of carbon atoms of the amine group is not particularly limited, but is preferably from 1 to 60.

In the present specification, the number of carbon atoms of the alkylamine group is not particularly limited, but can be from 1 to 40, and, according to one embodiment, can be from 1 to 20. Specific examples of the alkylamine group can include a methylamine group, a dimethylamine group, an ethylamine group, a diethylamine group and the like, but are not limited thereto.

In the present specification, examples of the arylamine group include a substituted or unsubstituted monoarylamine group, a substituted or unsubstituted diarylamine group, or a substituted or unsubstituted triarylamine group. The aryl group in the arylamine group can be a monocyclic aryl group or a polycyclic aryl group. The arylamine group including two or more aryl groups can include monocyclic aryl groups, polycyclic aryl groups, or both monocyclic aryl groups and polycyclic aryl groups.

Specific examples of the arylamine group can include a phenylamine group, a naphthylamine group, a biphenylamine group, an anthracenylamine group, a diphenylamine group, a phenylnaphthylamine group, a biphenylphenylamine group, a dibiphenylamine group, a fluorenylphenylamine group and the like, but are not limited thereto.

In the present specification, examples of the heteroarylamine group include a substituted or unsubstituted monoheteroarylamine group, a substituted or unsubstituted diheteroarylamine group, or a substituted or unsubstituted triheteroarylamine group. The heteroaryl group in the heteroarylamine group can be a monocyclic heteroaryl group or a polycyclic heteroaryl group. The heteroarylamine group including two or more heteroaryl groups can include monocyclic heteroaryl groups, polycyclic heteroaryl groups, or both monocyclic heteroaryl groups and polycyclic heteroaryl groups.

In the present specification, the aryl group is not particularly limited, but preferably has 6 to 60 carbon atoms, and can be a monocyclic aryl group or a polycyclic aryl group. According to one embodiment, the number of carbon atoms of the aryl group is from 6 to 30. According to one embodiment, the number of carbon atoms of the aryl group is from 6 to 20. When the aryl group is a monocyclic aryl group, examples thereof can include a phenyl group, a biphenyl group, a terphenyl group, a quaterphenyl group and the like, but are not limited thereto. Examples of the polycyclic aryl group can include a naphthyl group, an anthracenyl group, a phenanthrenyl group, a pyrenyl group, a perylenyl group, a triphenyl group, a chrysenyl group, a fluorenyl group, a triphenylenyl group and the like, but are not limited thereto.

In the present specification, the fluorenyl group can be substituted, and two substituents can bond to each other to form a spiro structure.

When the fluorenyl group is substituted, structures as below can be obtained, however, the structure is not limited thereto:

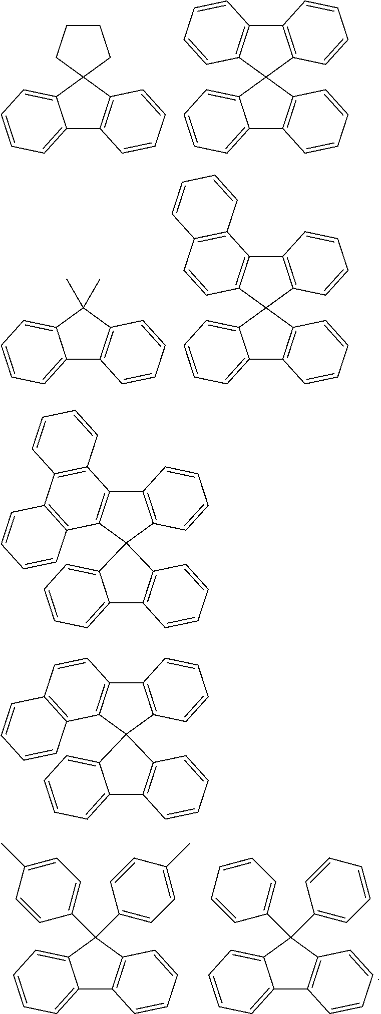

In the present specification, the descriptions on the aryl group provided above can be applied to the aryl group in the aryloxy group.

In the present specification, the heterocyclic group is a cyclic group including one or more of atoms such as N, O, P, S, Si and Se as a heteroatom, and although not particularly limited thereto, the number of carbon atoms is preferably from 2 to 60. According to one embodiment, the number of carbon atoms of the heterocyclic group is from 2 to 30. Examples of the heterocyclic group can include a pyridine group, a pyrrole group, a pyrimidine group, a quinoline group, a pyridazinyl group, a furan group, a thiophene group, an imidazole group, a pyrazole group, a dibenzofuran group, a dibenzothiophene group, a carbazole group, a benzocarbazole group, a naphthobenzofuran group, a benzonaphthothiophene group, an indenocarbazole group, a triazinyl group and the like, but are not limited thereto.

In the present specification, the descriptions on the heterocyclic group provided above can be applied to the heteroaryl group except that it is aromatic.

In the present specification, the “ring” in the substituted or unsubstituted ring formed by bonding to adjacent groups means a hydrocarbon ring; or a heteroring.

The hydrocarbon ring can be aromatic, aliphatic or a fused ring of aromatic and aliphatic, and can be selected from among the examples of the cycloalkyl group or the aryl group.

In the present specification, the meaning of bonding to adjacent groups to form a ring means bonding to adjacent groups to form a substituted or unsubstituted aliphatic hydrocarbon ring, a substituted or unsubstituted aromatic hydrocarbon ring, a substituted or unsubstituted aliphatic heteroring, a substituted or unsubstituted aromatic heteroring, or a fused ring thereof. The hydrocarbon ring means a ring formed only with carbon and hydrogen atoms. The heteroring means a ring including one or more selected from among atoms such as N, O, P, S, Si and Se. In the present specification, the aliphatic hydrocarbon ring, the aromatic hydrocarbon ring, the aliphatic heteroring and the aromatic heteroring can be monocyclic or polycyclic.

In the present specification, the aliphatic hydrocarbon ring means, as a ring that is not aromatic, a ring formed only with carbon and hydrogen atoms. Examples of the aliphatic hydrocarbon ring can include cyclopropane, cyclobutane, cyclobutene, cyclopentane, cyclopentene, cyclohexane, cyclohexene, 1,4-cyclohexadiene, cycloheptane, cycloheptene, cyclooctane, cyclooctene and the like, but are not limited thereto.

In the present specification, the aromatic hydrocarbon ring means an aromatic ring formed only with carbon and hydrogen atoms. Examples of the aromatic hydrocarbon ring can include benzene, naphthalene, anthracene, phenanthrene, perylene, fluoranthene, triphenylene, phenalene, pyrene, tetracene, chrysene, pentacene, fluorene, indene, acenaphthylene, benzofluorene, spirofluorene and the like, but are not limited thereto. In the present specification, the aromatic hydrocarbon ring can be interpreted to have the same meaning as the aryl group.

In the present specification, the aliphatic heteroring means an aliphatic ring including one or more of heteroatoms. Examples of the aliphatic heteroring can include oxirane, tetrahydrofuran, 1,4-dioxane, pyrrolidine, piperidine, morpholine, oxepane, azokane, thiokane and the like, but are not limited thereto.

In the present specification, the aromatic heteroring means an aromatic ring including one or more of heteroatoms. Examples of the aromatic heteroring can include pyridine, pyrrole, pyrimidine, pyridazine, furan, thiophene, imidazole, parazole, oxazole, isoxazole, thiazole, isothiazole, triazole, oxadiazole, thiadiazole, dithiazole, tetrazole, pyran, thiopyran, diazine, oxazine, thiazine, dioxin, triazine, tetrazine, isoquinoline, quinoline, quinone, quinazoline, quinoxaline, naphthyridine, acridine, phenanthridine, diazanaphthalene, triazaindene, indole, indolizine, benzothiazole, benzoxazole, benzimidazole, benzothiophene, benzofuran, dibenzothiophene, dibenzofuran, carbazole, benzocarbazole, dibenzocarbazole, phenazine, imidazopyridine, phenoxazine, indolocarbazole, indenocarbazole and the like, but are not limited thereto.

In the present specification, descriptions on the aryl group provided above can be applied to the arylene group except for being a divalent group.

In the present specification, a divalent heterocyclic group means a heterocyclic group having two bonding sites, that is, a divalent group. Descriptions on the heterocyclic group provided above can be applied to the divalent heterocyclic group except for being a divalent group.

Hereinafter, preferred embodiments of the present disclosure will be described in detail. However, embodiments of the present disclosure can be modified in various forms, and the scope of the present disclosure is not limited to the embodiments described below.

Hereinafter, Chemical Formula 1 will be described in detail.

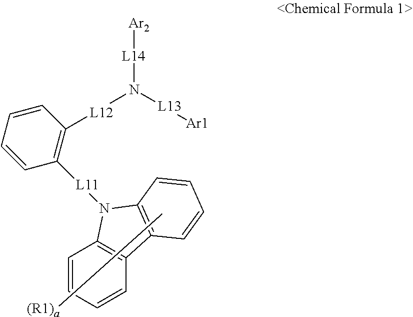

In Chemical Formula 1:

L11 to L14 are the same as or different from each other, and each independently is a direct bond or a substituted or unsubstituted arylene group;

Ar1 and Ar2 are the same as or different from each other, and each independently is a substituted or unsubstituted aryl group or a substituted or unsubstituted heterocyclic group;

R1 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group; and

a is an integer of 0 to 8, and when a is 2 or greater, the two or more R1s are the same as or different from each other.

In one embodiment of the present specification, L11 to L14 are the same as or different from each other, and each independently is a direct bond or a substituted or unsubstituted arylene group having 6 to 60 carbon atoms.

In one embodiment of the present specification, L11 to L14 are the same as or different from each other, and each independently id a direct bond or a substituted or unsubstituted arylene group having 6 to 30 carbon atoms.

In one embodiment of the present specification, L11 to L14 are the same as or different from each other, and each independently is a direct bond or a substituted or unsubstituted arylene group having 6 to 20 carbon atoms.

In one embodiment of the present specification, L11 to L14 are the same as or different from each other, and each independently is a direct bond or a substituted or unsubstituted monocyclic to hexacyclic arylene group.

In one embodiment of the present specification, L11 to L14 are the same as or different from each other, and each independently is a direct bond or a substituted or unsubstituted monocyclic to tetracyclic arylene group.

In one embodiment of the present specification, L11 to L14 are the same as or different from each other, and each independently is a direct bond or a substituted or unsubstituted dicyclic to tetracyclic arylene group.

In one embodiment of the present specification, L11 to L14 are the same as or different from each other, and each independently id a direct bond, a substituted or unsubstituted phenylene group, a substituted or unsubstituted biphenylene group, a substituted or unsubstituted terphenylene group, or a substituted or unsubstituted naphthylene group.

In one embodiment of the present specification, L11 to L14 are the same as or different from each other, and each independently is a direct bond, a phenylene group, a biphenylene group, or a naphthylene group.

In one embodiment of the present specification, L11 is a direct bond.

In one embodiment of the present specification, L12 is a substituted or unsubstituted phenylene group.

In one embodiment of the present specification, L12 is a phenylene group.

In one embodiment of the present specification, L12 is any one of the following structures:

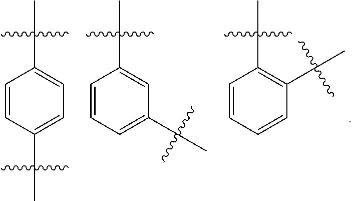

In one embodiment of the present specification, L12 is the following structure:

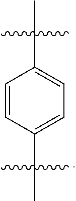 [SMILES: *c1ccc(*)cc1]

In one embodiment of the present specification, L13 and L14 are the same as or different from each other, and each independently is a direct bond, a substituted or unsubstituted phenylene group, a substituted or unsubstituted biphenylene group, a substituted or unsubstituted terphenylene group, or a substituted or unsubstituted naphthylene group.

In one embodiment of the present specification, L13 and L14 are the same as or different from each other, and each independently is a direct bond, a phenylene group, a biphenylene group, a terphenylene group, or a naphthylene group.

In one embodiment of the present specification, L13 and L14 are the same as or different from each other, and each independently is a direct bond, a phenylene group, a biphenylene group, or a naphthylene group.

In one embodiment of the present specification, L13 and L14 are the same as or different from each other, and each independently is a direct bond or a phenylene group.

In one embodiment of the present specification, L13 and L14 are a direct bond.

In one embodiment of the present specification, Ar1 and Ar2 are the same as or different from each other, and each independently is a substituted or unsubstituted aryl group having 6 to 60 carbon atoms, or a substituted or unsubstituted heterocyclic group having 2 to 60 carbon atoms.

In one embodiment of the present specification, Ar1 and Ar2 are the same as or different from each other, and each independently is a substituted or unsubstituted aryl group having 6 to 30 carbon atoms, or a substituted or unsubstituted heterocyclic group having 2 to 30 carbon atoms.

In one embodiment of the present specification, Ar1 and Ar2 are the same as or different from each other, and each independently is a substituted or unsubstituted aryl group having 6 to 20 carbon atoms, or a substituted or unsubstituted heterocyclic group having 2 to 20 carbon atoms.

In one embodiment of the present specification, Ar1 and Ar2 are the same as or different from each other, and each independently is a substituted or unsubstituted monocyclic to hexacyclic aryl group, or a substituted or unsubstituted monocyclic to hexacyclic heterocyclic group.

In one embodiment of the present specification, Ar1 and Ar2 are the same as or different from each other, and each independently is a substituted or unsubstituted monocyclic to tetracyclic aryl group, or a substituted or unsubstituted monocyclic to tetracyclic heterocyclic group.

In one embodiment of the present specification, Ar1 and Ar2 are the same as or different from each other, and each independently is a substituted or unsubstituted dicyclic to tetracyclic aryl group; or a substituted or unsubstituted dicyclic to tetracyclic heterocyclic group.

In one embodiment of the present specification, Ar1 and Ar2 are the same as or different from each other, and each independently is a substituted or unsubstituted phenyl group, a substituted or unsubstituted biphenyl group, a substituted or unsubstituted terphenyl group, a substituted or unsubstituted naphthyl group, a substituted or unsubstituted fluorenyl group, a substituted or unsubstituted phenanthrenyl group; a substituted or unsubstituted triphenylenyl group, a substituted or unsubstituted dibenzofuran group, or a substituted or unsubstituted dibenzothiophene group.

In one embodiment of the present specification, Ar1 and Ar2 are the same as or different from each other, and each independently is a phenyl group that is unsubstituted or substituted with an alkyl group or an aryl group; a biphenyl group that is unsubstituted or substituted with an alkyl group or an aryl group; a terphenyl group that is unsubstituted or substituted with an alkyl group or an aryl group; a naphthyl group that is unsubstituted or substituted with an alkyl group or an aryl group; a fluorenyl group that is unsubstituted or substituted with an alkyl group or an aryl group; a phenanthrenyl group that is unsubstituted or substituted with an alkyl group or an aryl group; a triphenylenyl group that is unsubstituted or substituted with an alkyl group or an aryl group; a dibenzofuran group that is unsubstituted or substituted with an alkyl group or an aryl group; or a dibenzothiophene group that is unsubstituted or substituted with an alkyl group or an aryl group.

In one embodiment of the present specification, Ar1 and Ar2 are the same as or different from each other, and each independently is a phenyl group that is unsubstituted or substituted with an alkyl group having 1 to 10 carbon atoms or an aryl group having 6 to 30 carbon atoms; a biphenyl group that is unsubstituted or substituted with an alkyl group having 1 to 10 carbon atoms or an aryl group having 6 to 30 carbon atoms; a terphenyl group that is unsubstituted or substituted with an alkyl group having 1 to 10 carbon atoms or an aryl group having 6 to 30 carbon atoms; a naphthyl group that is unsubstituted or substituted with an alkyl group having 1 to 10 carbon atoms or an aryl group having 6 to 30 carbon atoms; a fluorenyl group that is unsubstituted or substituted with an alkyl group having 1 to 10 carbon atoms or an aryl group having 6 to 30 carbon atoms; a phenanthrenyl group that is unsubstituted or substituted with an alkyl group having 1 to 10 carbon atoms or an aryl group having 6 to 30 carbon atoms; a triphenylenyl group that is unsubstituted or substituted with an alkyl group having 1 to 10 carbon atoms or an aryl group having 6 to 30 carbon atoms; a dibenzofuran group that is unsubstituted or substituted with an alkyl group having 1 to 10 carbon atoms or an aryl group having 6 to 30 carbon atoms; or a dibenzothiophene group that is unsubstituted or substituted with an alkyl group having 1 to 10 carbon atoms or an aryl group having 6 to 30 carbon atoms.

In one embodiment of the present specification, Ar1 and Ar2 are the same as or different from each other, and each independently is a phenyl group, a biphenyl group, a terphenyl group, a naphthyl group, a dimethylfluorenyl group, a diphenylfluorenyl group, a phenanthrenyl group, a triphenylenyl group, a dibenzofuran group, or a dibenzothiophene group.

In one embodiment of the present specification, Ar1 and Ar2 are the same as or different from each other, and each independently is a phenyl group that is unsubstituted or substituted with a naphthyl group; a biphenyl group; a terphenyl group; a naphthyl group that is unsubstituted or substituted with a phenyl group; a dimethylfluorenyl group; a diphenylfluorenyl group; a phenanthrenyl group; a triphenylenyl group; or a dibenzofuran group.

In one embodiment of the present specification, Ar1 and Ar2 are the same as or different from each other, and each independently is a phenyl group, a biphenyl group, a terphenyl group, a naphthyl group, a dimethylfluorenyl group, a diphenylfluorenyl group, a phenanthrenyl group, a triphenylenyl group, or a dibenzofuran group.

In one embodiment of the present specification, at least one of Ar1 and Ar2 is a substituted or unsubstituted dibenzofuran group.

In one embodiment of the present specification, at least one of Ar1 and Ar2 is a dibenzofuran group.

In one embodiment of the present specification, Ar1 and Ar2 are the same as or different from each other, and each independently is a phenyl group, a biphenyl group, a terphenyl group, a naphthyl group, a dibenzofuran group, or a dibenzothiophene group.

In one embodiment of the present specification, Ar1 and Ar2 are the same as or different from each other, and each independently is a phenyl group that is unsubstituted or substituted with a naphthyl group; a biphenyl group; a terphenyl group; a naphthyl group; or a dibenzofuran group.

In one embodiment of the present specification, Ar1 and Ar2 are the same as or different from each other, and each independently is a phenyl group, a biphenyl group, a terphenyl group, a naphthyl group, or a dibenzofuran group.

In one embodiment of the present specification, Ar1 and Ar2 are the same as or different from each other, and each independently is a substituted or unsubstituted aryl group having 6 to 60 carbon atoms.

In one embodiment of the present specification, Ar1 and Ar2 are the same as or different from each other, and each independently is a substituted or unsubstituted heterocyclic group having 2 to 30 carbon atoms.

In one embodiment of the present specification, Ar1 and Ar2 are the same as or different from each other, and each independently is a substituted or unsubstituted phenyl group, a substituted or unsubstituted biphenyl group, a substituted or unsubstituted terphenyl group, a substituted or unsubstituted naphthyl group, a substituted or unsubstituted fluorenyl group, a substituted or unsubstituted phenanthrenyl group, or a substituted or unsubstituted triphenylenyl group.

In one embodiment of the present specification, Ar1 and Ar2 are the same as or different from each other, and each independently is a phenyl group, a biphenyl group, or a naphthyl group.

In one embodiment of the present specification, R1 is hydrogen, deuterium, a halogen group, a cyano group, a substituted or unsubstituted silyl group, a substituted or unsubstituted alkyl group having 1 to 30 carbon atoms, a substituted or unsubstituted cycloalkyl group having 3 to 60 carbon atoms, a substituted or unsubstituted alkoxy group having 1 to 30 carbon atoms, a substituted or unsubstituted aryloxy group having 6 to 60 carbon atoms, a substituted or unsubstituted aryl group having 6 to 60 carbon atoms, or a substituted or unsubstituted heterocyclic group having 2 to 60 carbon atoms.

In one embodiment of the present specification, R1 is hydrogen, deuterium, a halogen group, a cyano group, a substituted or unsubstituted silyl group, a substituted or unsubstituted alkyl group having 1 to 10 carbon atoms, a substituted or unsubstituted cycloalkyl group having 3 to 30 carbon atoms, a substituted or unsubstituted alkoxy group having 1 to 10 carbon atoms, a substituted or unsubstituted aryloxy group having 6 to 30 carbon atoms, a substituted or unsubstituted aryl group having 6 to 30 carbon atoms, or a substituted or unsubstituted heterocyclic group having 2 to 30 carbon atoms.

In one embodiment of the present specification, R1 is hydrogen, deuterium; a substituted or unsubstituted aryl group having 6 to 30 carbon atoms, or a substituted or unsubstituted heterocyclic group having 2 to 30 carbon atoms.

In one embodiment of the present specification, R1 is hydrogen or deuterium.

In one embodiment of the present specification, R1 is hydrogen.

In one embodiment of the present specification, a is 0 or 1.

In one embodiment of the present specification, a is 0.

In one embodiment of the present specification, a is 1.

In one embodiment of the present specification, a is 8.

In one embodiment of the present specification, Chemical Formula 1 is the following Chemical Formula 1-1:

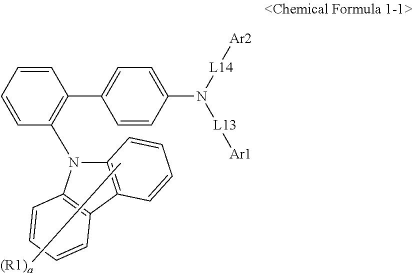

wherein in Chemical Formula 1-1, L13, L14, Ar1, Ar2, R1 and a have the same definitions as in Chemical Formula 1.

In one embodiment of the present specification, Chemical Formula 1 is the following Chemical Formula 1-2:

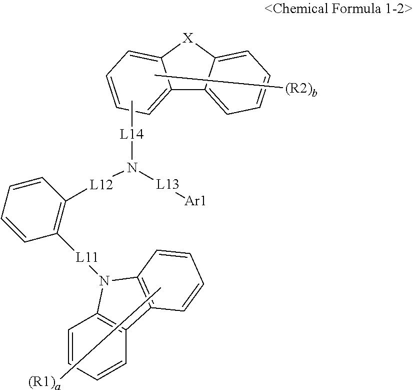

wherein in Chemical Formula 1-2, L11 to L14, Ar1, R1 and a have the same definitions as in Chemical Formula 1;

X is O or S,

R2 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group; and

b is an integer of 0 to 7, and when b is 2 or greater, the two or more R2s are the same as or different from each other.

In one embodiment of the present specification, X is 0.

In one embodiment of the present specification, R2 is hydrogen or deuterium.

In one embodiment of the present specification, R2 is hydrogen.

In one embodiment of the present specification, b is 0 or 1.

In one embodiment of the present specification, b is 0.

In one embodiment of the present specification, b is 1.

In one embodiment of the present specification, b is 7.

In one embodiment of the present specification, Chemical Formula 1-2 is the following Chemical Formula 1-2-1:

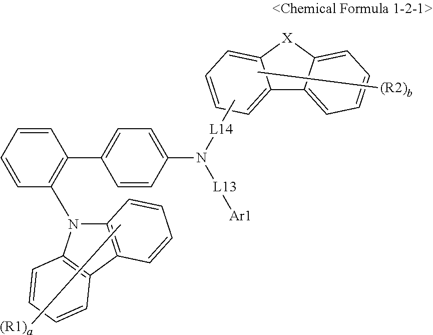

wherein in Chemical Formula 1-2-1, L13, L14, Ar1, R1, R2, X, a and b have the same definitions as in Chemical Formula 1-2.

Hereinafter, Chemical Formula 2 will be described in detail.

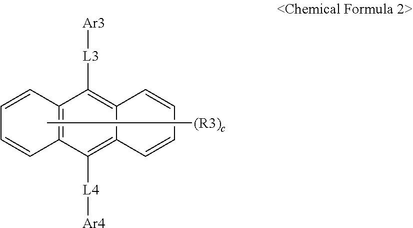

In Chemical Formula 2:

L3 and L4 are the same as or different from each other, and each independently is a direct bond or a substituted or unsubstituted arylene group;

Ar3 and Ar4 are the same as or different from each other, and each independently is a substituted or unsubstituted aryl group or a substituted or unsubstituted heterocyclic group;

R3 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group;

c is an integer of 0 to 8, and when c is 2 or greater, the two or more R3s are the same as or different from each other; and

the compound of Chemical Formula 2 is substituted by deuterium by at least 40%.

In one embodiment of the present specification, L3 and L4 are the same as or different from each other, and each independently is a direct bond or a substituted or unsubstituted arylene group having 6 to 60 carbon atoms.

In one embodiment of the present specification, L3 and L4 are the same as or different from each other, and each independently is a direct bond or a substituted or unsubstituted arylene group having 6 to 30 carbon atoms.

In one embodiment of the present specification, L3 and L4 are the same as or different from each other, and each independently is a direct bond or a substituted or unsubstituted arylene group having 6 to 20 carbon atoms.

In one embodiment of the present specification, L3 and L4 are the same as or different from each other, and each independently is a direct bond or a substituted or unsubstituted monocyclic to hexacyclic arylene group.

In one embodiment of the present specification, L3 and L4 are the same as or different from each other, and each independently is a direct bond or a substituted or unsubstituted monocyclic to tetracyclic arylene group.

In one embodiment of the present specification, L3 and L4 are the same as or different from each other, and each independently is a direct bond or a substituted or unsubstituted dicyclic to tetracyclic arylene group.

In one embodiment of the present specification, L3 and L4 are the same as or different from each other, and each independently is a direct bond or an arylene group having 6 to 30 carbon atoms that are unsubstituted or substituted with deuterium.

In one embodiment of the present specification, L3 and L4 are the same as or different from each other, and each independently is a direct bond, a substituted or unsubstituted phenylene group; a substituted or unsubstituted biphenylene group, a substituted or unsubstituted terphenylene group, or a substituted or unsubstituted naphthylene group.

In one embodiment of the present specification, L3 and L4 are the same as or different from each other, and each independently is a direct bond; a phenylene group that is unsubstituted or substituted with deuterium; a biphenylene group that is unsubstituted or substituted with deuterium; a terphenylene group that is unsubstituted or substituted with deuterium; or a naphthylene group that is unsubstituted or substituted with deuterium.

In one embodiment of the present specification, L3 and L4 are the same as or different from each other, and each independently is a direct bond, a substituted or unsubstituted phenylene group, or a substituted or unsubstituted naphthylene group.

In one embodiment of the present specification, L3 and L4 are the same as or different from each other, and each independently is a direct bond; a phenylene group that is unsubstituted or substituted with deuterium; or a naphthylene group that is unsubstituted or substituted with deuterium.

In one embodiment of the present specification, L3 and L4 are the same as or different from each other, and each independently is a direct bond, or a phenylene group that is unsubstituted or substituted with deuterium.

In one embodiment of the present specification, L3 and L4 are the same as or different from each other, and each independently is a direct bond or a phenylene group.

In one embodiment of the present specification, L3 and L4 are a direct bond.

In one embodiment of the present specification, L3 and L4 are the same as or different from each other, and each independently is a direct bond or any one of the following structural formulae:

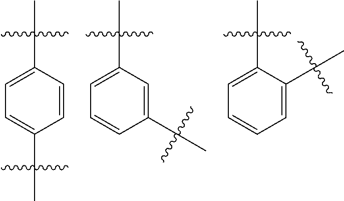

wherein the structural formulae are unsubstituted or substituted with deuterium.

In one embodiment of the present specification, L3 and L4 are the same as or different from each other, and each independently is a direct bond or any one of the following structural formulae:

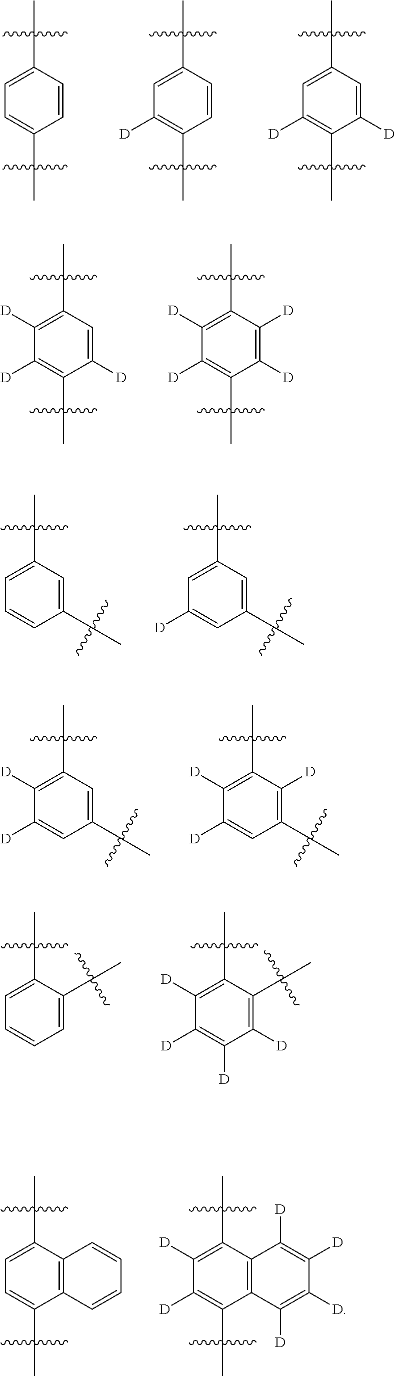

In one embodiment of the present specification, Ar3 and Ar4 are the same as or different from each other, and each independently is a substituted or unsubstituted aryl group having 6 to 60 carbon atoms, or a substituted or unsubstituted heterocyclic group having 2 to 60 carbon atoms.

In one embodiment of the present specification, Ar3 and Ar4 are the same as or different from each other, and each independently is a substituted or unsubstituted aryl group having 6 to 30 carbon atoms, or a substituted or unsubstituted heterocyclic group having 2 to 30 carbon atoms.

In one embodiment of the present specification, Ar3 and Ar4 are the same as or different from each other, and each independently is a substituted or unsubstituted aryl group having 6 to 20 carbon atoms, or a substituted or unsubstituted heterocyclic group having 2 to 20 carbon atoms.

In one embodiment of the present specification, Ar3 and Ar4 are the same as or different from each other, and each independently is a substituted or unsubstituted monocyclic to hexacyclic aryl group, or a substituted or unsubstituted monocyclic to hexacyclic heterocyclic group.

In one embodiment of the present specification, Ar3 and Ar4 are the same as or different from each other, and each independently is a substituted or unsubstituted monocyclic to tetracyclic aryl group, or a substituted or unsubstituted monocyclic to tetracyclic heterocyclic group.

In one embodiment of the present specification, Ar3 and Ar4 are the same as or different from each other, and each independently is a substituted or unsubstituted dicyclic to tetracyclic aryl group, or a substituted or unsubstituted dicyclic to tetracyclic heterocyclic group.

In one embodiment of the present specification, Ar3 and Ar4 are the same as or different from each other, and each independently is an aryl group having 6 to 30 carbon atoms that are unsubstituted or substituted with deuterium; or a heterocyclic group having 2 to 30 carbon atoms that are unsubstituted or substituted with deuterium.

In one embodiment of the present specification, Ar3 and Ar4 are the same as or different from each other, and each independently is a substituted or unsubstituted phenyl group, a substituted or unsubstituted biphenyl group, a substituted or unsubstituted naphthyl group, a substituted or unsubstituted phenanthrenyl group, a substituted or unsubstituted dibenzofuran group, a substituted or unsubstituted dibenzothiophene group, a substituted or unsubstituted naphthobenzofuran group, or a substituted or unsubstituted naphthobenzothiophene group.

In one embodiment of the present specification, Ar3 and Ar4 are the same as or different from each other, and each independently is a substituted or unsubstituted phenyl group, a substituted or unsubstituted biphenyl group, a substituted or unsubstituted naphthyl group, a substituted or unsubstituted phenanthrenyl group, a substituted or unsubstituted dibenzofuran group, or a substituted or unsubstituted naphthobenzofuran group.

In one embodiment of the present specification, Ar3 and Ar4 are the same as or different from each other, and each independently is a substituted or unsubstituted phenyl group, a substituted or unsubstituted biphenyl group, a substituted or unsubstituted naphthyl group, a substituted or unsubstituted dibenzofuran group, or a substituted or unsubstituted naphthobenzofuran group.

In one embodiment of the present specification, Ar3 and Ar4 are the same as or different from each other, and each independently is a phenyl group that is unsubstituted or substituted with deuterium or a naphthyl group; a biphenyl group that is unsubstituted or substituted with deuterium; a naphthyl group that is unsubstituted or substituted with deuterium or a phenyl group; a phenanthrenyl group that is unsubstituted or substituted with deuterium; a dibenzofuran group that is unsubstituted or substituted with deuterium; or a naphthobenzofuran group that is unsubstituted or substituted with deuterium.

In one embodiment of the present specification, Ar3 and Ar4 are the same as or different from each other, and each independently is a phenyl group that is unsubstituted or substituted with deuterium; a biphenyl group that is unsubstituted or substituted with deuterium; a naphthyl group that is unsubstituted or substituted with deuterium; a phenanthrenyl group that is unsubstituted or substituted with deuterium; a dibenzofuran group that is unsubstituted or substituted with deuterium; or a naphthobenzofuran group that is unsubstituted or substituted with deuterium.

In one embodiment of the present specification, Ar3 and Ar4 are the same as or different from each other, and each independently is any one of the following structural formulae:

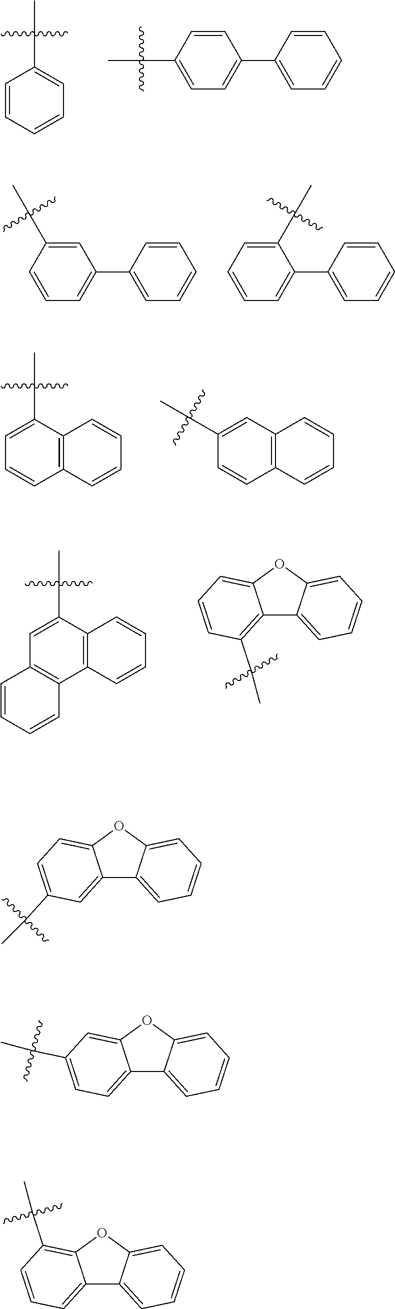

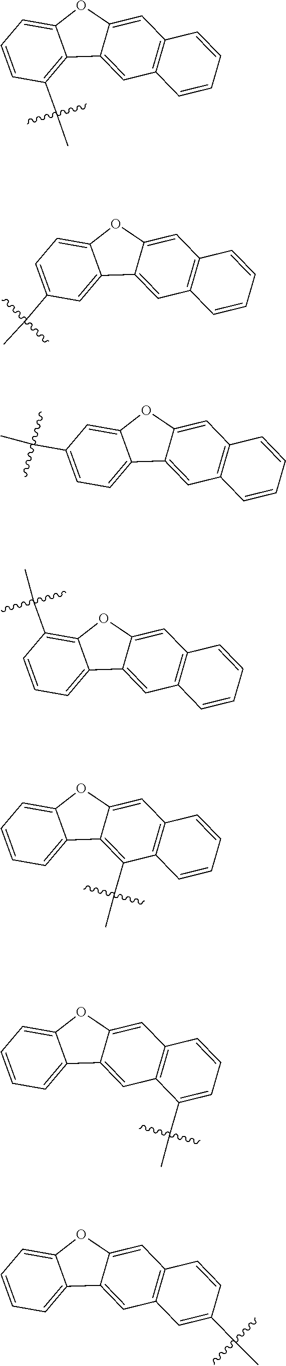

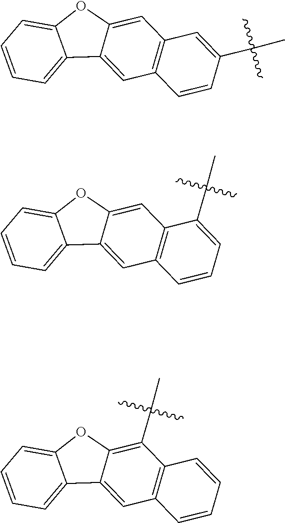 [SMILES: *c1ccc2cc3c(cc2c1)oc1ccccc13 ; *c1cccc2cc3c(cc12)oc1ccccc13 ; *c1c2ccccc2cc2c1oc1ccccc12]

wherein the structural formulae are unsubstituted or substituted with deuterium.

In one embodiment of the present specification, Ar3 and Ar4 are the same as or different from each other, and each independently is a phenyl group that is unsubstituted or substituted with deuterium; a naphthyl group that is unsubstituted or substituted with deuterium; or a dibenzofuran group that is unsubstituted or substituted with deuterium.

In one embodiment of the present specification, at least one of Ar3 and Ar4 is a substituted or unsubstituted naphthyl group, a substituted or unsubstituted phenanthrenyl group, a substituted or unsubstituted dibenzofuran group, or a substituted or unsubstituted naphthobenzofuran group.

In one embodiment of the present specification, at least one of Ar3 and Ar4 is a naphthyl group that is unsubstituted or substituted with deuterium; a phenanthrenyl group that is unsubstituted or substituted with deuterium; a dibenzofuran group that is unsubstituted or substituted with deuterium; or a naphthobenzofuran group that is unsubstituted or substituted with deuterium.

In one embodiment of the present specification, at least one of Ar3 and Ar4 is a substituted or unsubstituted naphthyl group, a substituted or unsubstituted dibenzofuran group, or a substituted or unsubstituted naphthobenzofuran group.

In one embodiment of the present specification, at least one of Ar3 and Ar4 is a naphthyl group that is unsubstituted or substituted with deuterium; a dibenzofuran group that is unsubstituted or substituted with deuterium; or a naphthobenzofuran group that is unsubstituted or substituted with deuterium.

In one embodiment of the present specification, at least one of Ar3 and Ar4 is a substituted or unsubstituted naphthyl group.

In one embodiment of the present specification, at least one of Ar3 and Ar4 is a naphthyl group that is unsubstituted or substituted with deuterium.

In one embodiment of the present specification, at least one of Ar3 and Ar4 is a substituted or unsubstituted dibenzofuran group, or a substituted or unsubstituted naphthobenzofuran group.

In one embodiment of the present specification, at least one of Ar3 and Ar4 is a dibenzofuran group that is unsubstituted or substituted with deuterium; or a naphthobenzofuran group that is unsubstituted or substituted with deuterium.

In one embodiment of the present specification, Ar3 and Ar4 are the same as or different from each other, and each independently is a substituted or unsubstituted aryl group.

In one embodiment of the present specification, Ar3 and Ar4 are the same as or different from each other, and each independently is a substituted or unsubstituted aryl group having 6 to 30 carbon atoms.

In one embodiment of the present specification, Ar3 and Ar4 are the same as or different from each other, and each independently is an aryl group having 6 to 30 carbon atoms unsubstituted or substituted with deuterium.

In one embodiment of the present specification, Ar3 and Ar4 are the same as or different from each other, and each independently is a substituted or unsubstituted phenyl group, a substituted or unsubstituted biphenyl group, a substituted or unsubstituted naphthyl group, or a substituted or unsubstituted phenanthrenyl group.

In one embodiment of the present specification, Ar3 and Ar4 are the same as or different from each other, and each independently is a phenyl group that is unsubstituted or substituted with deuterium; a biphenyl group that is unsubstituted or substituted with deuterium; a naphthyl group that is unsubstituted or substituted with deuterium; or a phenanthrenyl group that is unsubstituted or substituted with deuterium.

In one embodiment of the present specification, Ar3 and Ar4 are the same as or different from each other, and each independently is any one of the following structural formulae:

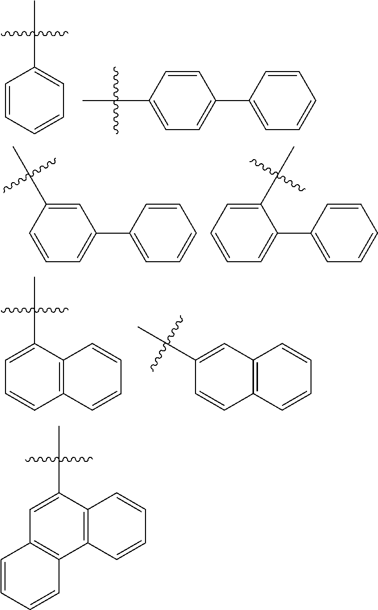

wherein the structural formulae are unsubstituted or substituted with deuterium.

In one embodiment of the present specification, Ar3 and Ar4 are the same as or different from each other, and each independently is a phenyl group substituted with deuterium; a biphenyl group substituted with deuterium; a naphthyl group substituted with deuterium; or a phenanthrenyl group substituted with deuterium.

In one embodiment of the present specification, Ar3 and Ar4 are the same as or different from each other, and each independently is a phenyl group substituted with deuterium; or a naphthyl group substituted with deuterium.

In one embodiment of the present specification, Ar3 is a substituted or unsubstituted naphthyl group; a substituted or unsubstituted dibenzofuran group; or a substituted or unsubstituted naphthobenzofuran group.

In one embodiment of the present specification, Ar3 is a naphthyl group that is unsubstituted or substituted with deuterium; a dibenzofuran group that is unsubstituted or substituted with deuterium; or a naphthobenzofuran group that is unsubstituted or substituted with deuterium.

In one embodiment of the present specification, Ar3 is any one of the following structural formulae:

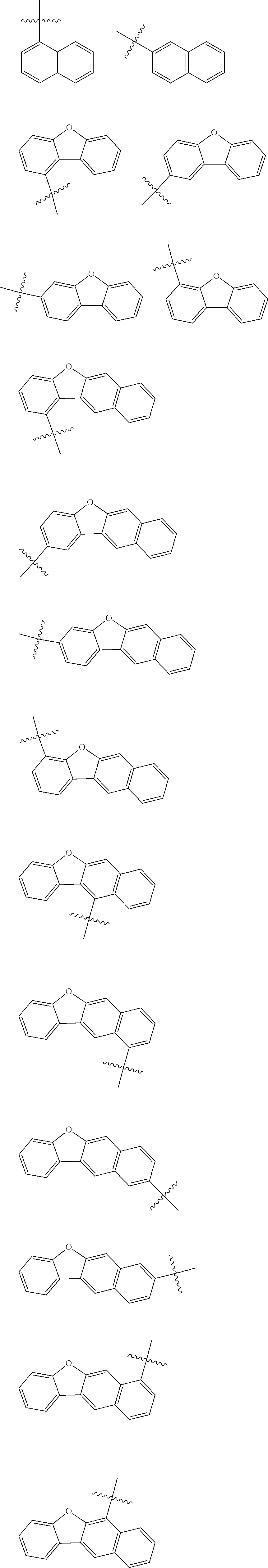

wherein the structural formulae are unsubstituted or substituted with deuterium.

In one embodiment of the present specification, Ar3 is any one of the following structural formulae:

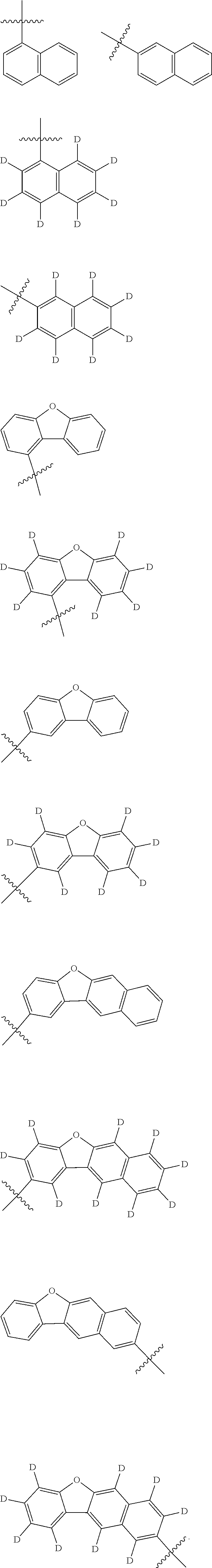

In one embodiment of the present specification, Ar3 is a substituted or unsubstituted naphthyl group, or a substituted or unsubstituted dibenzofuran group.

In one embodiment of the present specification, Ar3 is a naphthyl group that is unsubstituted or substituted with deuterium; or a dibenzofuran group that is unsubstituted or substituted with deuterium.

In one embodiment of the present specification, Ar3 is a naphthyl group that is unsubstituted or substituted with deuterium; or a dibenzofuran group.

In one embodiment of the present specification, Ar3 is a substituted or unsubstituted naphthyl group.

In one embodiment of the present specification, Ar3 is a naphthyl group that is unsubstituted or substituted with deuterium.

In one embodiment of the present specification, Ar3 is any one of the following structural formulae:

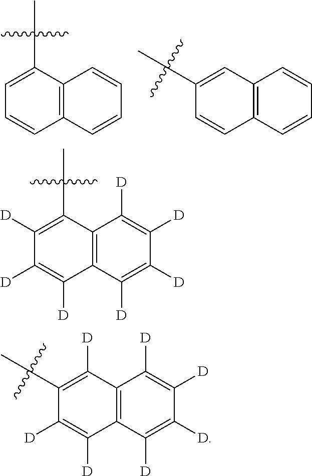

In one embodiment of the present specification, Ar4 is a substituted or unsubstituted aryl group.

In one embodiment of the present specification, Ar4 is an aryl group that is unsubstituted or substituted with deuterium.

In one embodiment of the present specification, Ar4 is a substituted or unsubstituted phenyl group, a substituted or unsubstituted naphthyl group, or a substituted or unsubstituted phenanthrenyl group.

In one embodiment of the present specification, Ar4 is a phenyl group that is unsubstituted or substituted with deuterium; a naphthyl group that is unsubstituted or substituted with deuterium; or a phenanthrenyl group that is unsubstituted or substituted with deuterium.

In one embodiment of the present specification, Ar4 is a substituted or unsubstituted phenyl group, or a substituted or unsubstituted naphthyl group.

In one embodiment of the present specification, Ar4 is a phenyl group that is unsubstituted or substituted with deuterium; or a naphthyl group that is unsubstituted or substituted with deuterium.

In one embodiment of the present specification, R3 is hydrogen; deuterium; a substituted or unsubstituted aryl group, or a substituted or unsubstituted heterocyclic group.

In one embodiment of the present specification, R3 is hydrogen, deuterium, a substituted or unsubstituted aryl group having 6 to 60 carbon atoms; or a substituted or unsubstituted heterocyclic group having 2 to 60 carbon atoms.

In one embodiment of the present specification, R3 is hydrogen, deuterium, a substituted or unsubstituted aryl group having 6 to 30 carbon atoms, or a substituted or unsubstituted heterocyclic group having 2 to 30 carbon atoms.

In one embodiment of the present specification, R3 is hydrogen; deuterium, or a substituted or unsubstituted aryl group having 6 to 30 carbon atoms.

In one embodiment of the present specification, R3 is hydrogen, deuterium, or an aryl group having 6 to 30 carbon atoms that are unsubstituted or substituted with deuterium.

In one embodiment of the present specification, R3 is hydrogen, deuterium, a substituted or unsubstituted phenyl group, or a substituted or unsubstituted naphthyl group.

In one embodiment of the present specification, R3 is hydrogen, deuterium, a phenyl group that is unsubstituted or substituted with deuterium, or a naphthyl group that is unsubstituted or substituted with deuterium.

In one embodiment of the present specification, R3 is hydrogen or deuterium.

In one embodiment of the present specification, R3 is deuterium.

In one embodiment of the present specification, R3 is deuterium, a phenyl group that is unsubstituted or substituted with deuterium, or a naphthyl group that is unsubstituted or substituted with deuterium.

In one embodiment of the present specification, R3 is a phenyl group that is unsubstituted or substituted with deuterium, or a naphthyl group that is unsubstituted or substituted with deuterium.

In one embodiment of the present specification, c is an integer of 0 to 8.

In one embodiment of the present specification, c is 8.

In one embodiment of the present specification, R3 is deuterium, and c is 8.

In descriptions to provide below, only a specific substituent being substituted with deuterium means that substituents other than the specific substituent do not include deuterium in a chemical formula.

In one embodiment of the present specification, Ar3 is substituted with at least one deuterium.

In one embodiment of the present specification, Ar4 is substituted with at least one deuterium.

In one embodiment of the present specification, L3 is substituted with at least one deuterium.

In one embodiment of the present specification, L4 is substituted with at least one deuterium.

In one embodiment of the present specification, R3 is substituted with at least one deuterium.

In one embodiment of the present specification, when c is 2 or greater, at least one of the two or more R3s is deuterium.

In one embodiment of the present specification, R3 is deuterium, and Ar3, Ar4, L3 and L4 are unsubstituted with deuterium.

In one embodiment of the present specification, only L3 and L4 are substituted with deuterium.

In one embodiment of the present specification, only Ar3 and Ar4 are substituted with deuterium.

In one embodiment of the present specification, only R3 and Ar3 are substituted with deuterium.

In one embodiment of the present specification, R3 is deuterium, and only L3 is substituted with deuterium.

In one embodiment of the present specification, when R3 is selected from among the remaining substituents other than hydrogen and deuterium, only R3 and L3 are substituted with deuterium.

In one embodiment of the present specification, R3 is deuterium, and only Ar3 is substituted with deuterium.

In one embodiment of the present specification, when R3 is selected from among the remaining substituents other than hydrogen and deuterium, only R3 and Ar3 are substituted with deuterium.

In one embodiment of the present specification, R3 is deuterium, and only L3 and L4 are substituted with deuterium.

In one embodiment of the present specification, when R3 is selected from among the remaining substituents other than hydrogen and deuterium, only R3, L3 and L4 are substituted with deuterium.

In one embodiment of the present specification, R3 is deuterium, and only Ar3 and Ar4 are substituted with deuterium.

In one embodiment of the present specification, when R3 is selected from among the remaining substituents other than hydrogen and deuterium, only R3, Ar3 and Ar4 are substituted with deuterium.

In one embodiment of the present specification, R3 is deuterium, and only L3 and Ar3 are substituted with deuterium.

In one embodiment of the present specification, when R3 is selected from among the remaining substituents other than hydrogen and deuterium, only R3, L3 and Ar3 are substituted with deuterium.

In one embodiment of the present specification, R3 is deuterium, and only L3 and Ar4 are substituted with deuterium.

In one embodiment of the present specification, when R3 is selected from among the remaining substituents other than hydrogen and deuterium, only R3, L3 and Ar4 are substituted with deuterium.

In one embodiment of the present specification, R3 is deuterium, and only L3, L4 and Ar3 are substituted with deuterium.

In one embodiment of the present specification, when R3 is selected from among the remaining substituents other than hydrogen and deuterium, only R3, L3, L4 and Ar3 are substituted with deuterium.

In one embodiment of the present specification, R3 is deuterium, and only L3, Ar3 and Ar4 are substituted with deuterium.

In one embodiment of the present specification, when R3 is selected from among the remaining substituents other than hydrogen and deuterium, only R3, L3, Ar3 and Ar4 are substituted with deuterium.

In one embodiment of the present specification, R3 is deuterium, and only L3, L4 Ar3 and Ar4 are substituted with deuterium.

In one embodiment of the present specification, when R3 is selected from among the remaining substituents other than hydrogen and deuterium, only R3, L3, L4, Ar3 and Ar4 are substituted with deuterium.

In one embodiment of the present specification, Ar3 is substituted with deuterium by 25% or greater.

In one embodiment of the present specification, Ar3 is substituted with deuterium by 50% or greater.

In one embodiment of the present specification, Ar3 is substituted with deuterium by 75% or greater.

In one embodiment of the present specification, Ar3 is substituted with deuterium by 100%.

In one embodiment of the present specification, Ar4 is substituted with deuterium by 25% or greater.

In one embodiment of the present specification, Ar4 is substituted with deuterium by 50% or greater.

In one embodiment of the present specification, Ar4 is substituted with deuterium by 75% or greater.

In one embodiment of the present specification, Ar4 is substituted with deuterium by 100%.

In one embodiment of the present specification, L3 is substituted with deuterium by 25% or greater.

In one embodiment of the present specification, L3 is substituted with deuterium by 50% or greater.

In one embodiment of the present specification, L3 is substituted with deuterium by 75% or greater.

In one embodiment of the present specification, L3 is substituted with deuterium by 100%.

In one embodiment of the present specification, L4 is substituted with deuterium by 25% or greater.

In one embodiment of the present specification, L4 is substituted with deuterium by 50% or greater.

In one embodiment of the present specification, L4 is substituted with deuterium by 75% or greater.

In one embodiment of the present specification, L4 is substituted with deuterium by 100%.

In one embodiment of the present specification, R3 is substituted with deuterium by 25% or greater.

In one embodiment of the present specification, R3 is substituted with deuterium by 50% or greater.

In one embodiment of the present specification, R3 is substituted with deuterium by 75% or greater.

In one embodiment of the present specification, R3 is substituted with deuterium by 100%.

In one embodiment of the present specification, when c is 2 or greater, at least two of the two or more R3s are deuterium. In another embodiment, at least four of the two or more R3s are deuterium. In another embodiment, at least six of the two or more R3s are deuterium. In another embodiment, the two or more R3s are all deuterium.

In one embodiment of the present specification, Chemical Formula 2 is any one of the following Chemical Formulae 2-1 to 2-3:

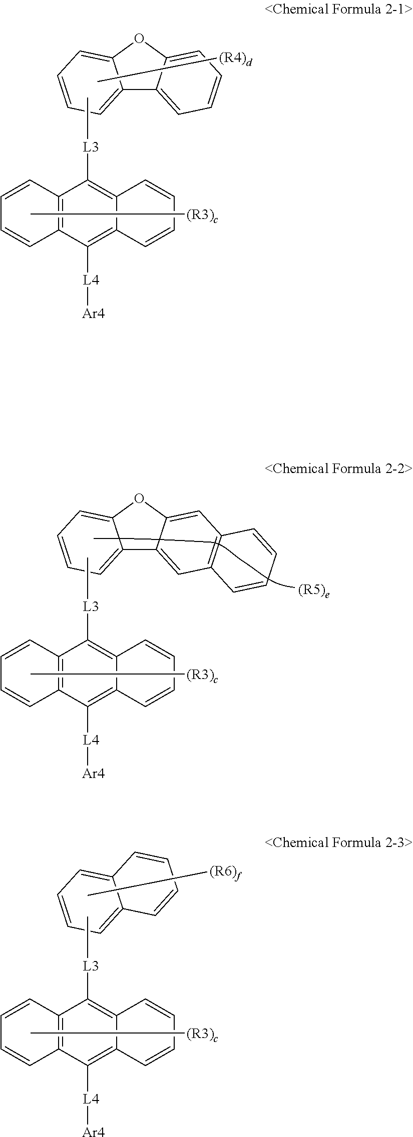

wherein in Chemical Formulae 2-1 to 2-3, L3, L4, Ar4, R3 and c have the same definitions as in Chemical Formula 2;

R4 to R6 are the same as or different from each other, and each independently is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group; a substituted or unsubstituted aryloxy group, a substituted or unsubstituted aryl group, or a substituted or unsubstituted heterocyclic group;

d is an integer of 0 to 7, and when d is 2 or greater, the two or more R4s are the same as or different from each other;

e is an integer of 0 to 9, and when e is 2 or greater, the two or more R5s are the same as or different from each other; and

f is an integer of 0 to 7, and when f is 2 or greater, the two or more R6s are the same as or different from each other.

In one embodiment of the present specification, R4 to R6 are the same as or different from each other, and each independently is hydrogen or deuterium.

In one embodiment of the present specification, R4 to R6 are hydrogen.

In one embodiment of the present specification, R4 to R6 are deuterium.

In one embodiment of the present specification, d is an integer of 0 to 7.

In one embodiment of the present specification, d is 0.

In one embodiment of the present specification, d is 7.

In one embodiment of the present specification, e is an integer of 0 to 9.

In one embodiment of the present specification, e is 0.

In one embodiment of the present specification, e is 9.

In one embodiment of the present specification, f is an integer of 0 to 7.

In one embodiment of the present specification, f is 0.

In one embodiment of the present specification, f is 7.

In one embodiment of the present specification, Chemical Formula 2 is any one of the following Chemical Formulae 2-1-1 to 2-1-4, 2-2-1 to 2-2-5 and 2-3-1 to 2-3-2:

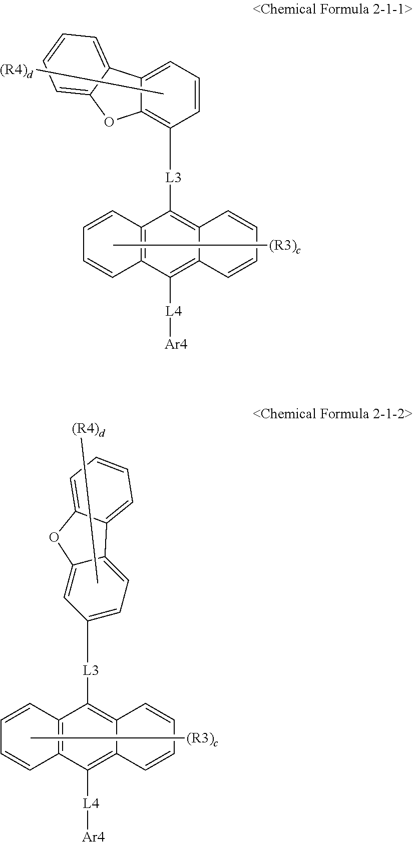

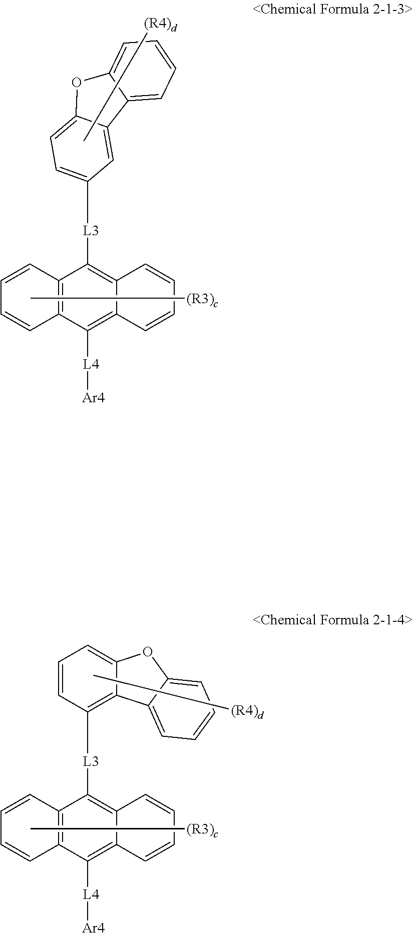

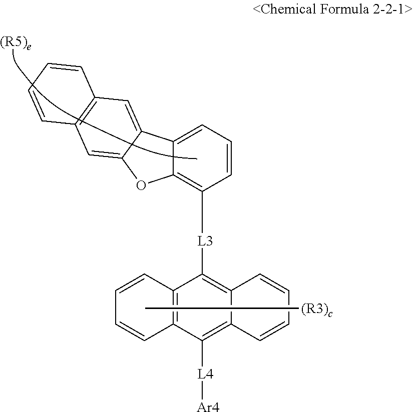

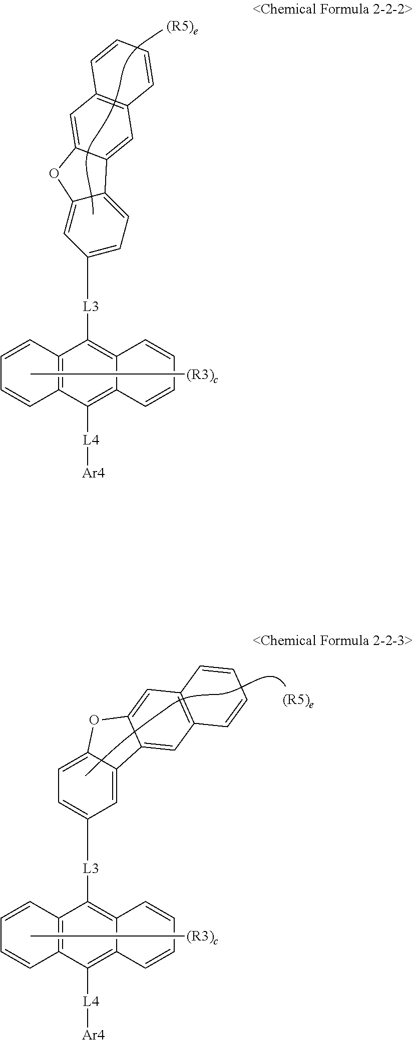

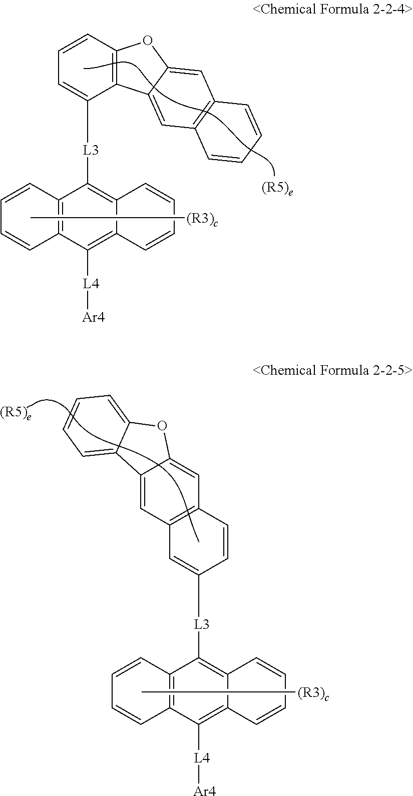

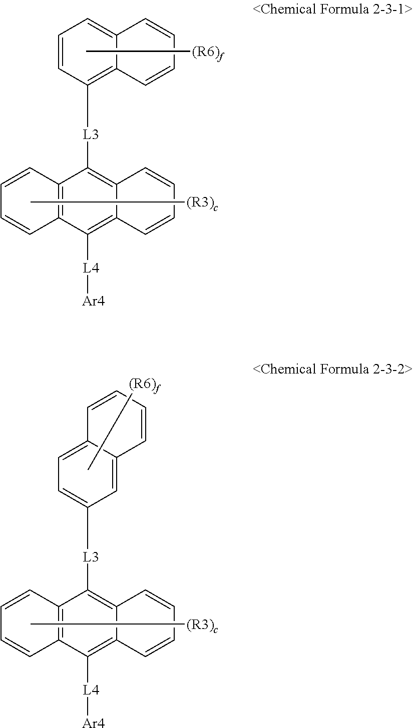

wherein in Chemical Formulae 2-1-1 to 2-1-4, 2-2-1 to 2-2-5 and 2-3-1 to 2-3-2:

L3, L4, Ar4, R3 to R6 and c to f have the same definitions as in Chemical Formulae 2-1 to 2-3.

In one embodiment of the present specification, Chemical Formula 2 is the following Chemical Formula 2-A:

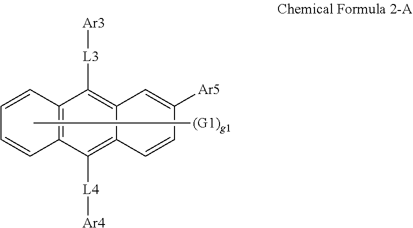

wherein in Chemical Formula 2-A, L3, L4, Ar3 and Ar4 have the same definitions as in Chemical Formula 2;

Ar5 is a substituted or unsubstituted aryl group;

G1 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group; a substituted or unsubstituted aryl group, or a substituted or unsubstituted heterocyclic group; and

g1 is an integer of 0 to 7, and when g1 is 2 or greater, the two or more G1s are the same as or different from each other.

In one embodiment of the present specification, Chemical Formula 2 is the following Chemical Formula 2-4 or 2-5:

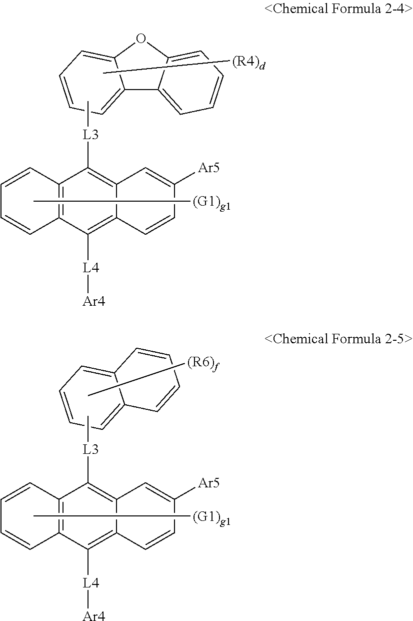

wherein in Chemical Formulae 2-4 and 2-5, L3, L4 and Ar4 have the same definitions as in Chemical Formula 2;

Ar5 is a substituted or unsubstituted aryl group;

R4 and R6 are the same as or different from each other, and each independently is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group; a substituted or unsubstituted aryloxy group, a substituted or unsubstituted aryl group, or a substituted or unsubstituted heterocyclic group;

G1 is hydrogen, deuterium, a halogen group, a cyano group, a substituted or unsubstituted silyl group, a substituted or unsubstituted alkyl group; a substituted or unsubstituted cycloalkyl group; a substituted or unsubstituted alkoxy group, a substituted or unsubstituted aryloxy group, a substituted or unsubstituted aryl group, or a substituted or unsubstituted heterocyclic group;

d is an integer of 0 to 7, and when d is 2 or greater, the two or more R4s are the same as or different from each other;

f is an integer of 0 to 7, and when f is 2 or greater, the two or more R6s are the same as or different from each other; and

g1 is an integer of 0 to 7, and when g1 is 2 or greater, the two or more G1s are the same as or different from each other.

In one embodiment of the present specification, Ar5 is a substituted or unsubstituted aryl group having 6 to 60 carbon atoms.

In one embodiment of the present specification, Ar5 is a substituted or unsubstituted aryl group having 6 to 30 carbon atoms.

In one embodiment of the present specification, Ar5 is an aryl group having 6 to 30 carbon atoms that are unsubstituted or substituted with deuterium.

In one embodiment of the present specification, Ar5 is a substituted or unsubstituted phenyl group, or a substituted or unsubstituted naphthyl group.

In one embodiment of the present specification, Ar5 is a phenyl group that is unsubstituted or substituted with deuterium; or a naphthyl group that is unsubstituted or substituted with deuterium.

In one embodiment of the present specification, Ar5 is a naphthyl group that is unsubstituted or substituted with deuterium.

In one embodiment of the present specification, R4 and R6 are the same as or different from each other, and each independently is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group.

In one embodiment of the present specification, R4 and R6 are the same as or different from each other, and each independently is hydrogen, deuterium, a substituted or unsubstituted aryl group, or a substituted or unsubstituted heterocyclic group.

In one embodiment of the present specification, R4 and R6 are the same as or different from each other, and each independently is hydrogen, deuterium, a substituted or unsubstituted aryl group having 6 to 60 carbon atoms, or a substituted or unsubstituted heterocyclic group having 2 to 60 carbon atoms.

In one embodiment of the present specification, R4 and R6 are the same as or different from each other, and each independently is hydrogen, deuterium, a substituted or unsubstituted aryl group having 6 to 30 carbon atoms, or a substituted or unsubstituted heterocyclic group having 2 to 30 carbon atoms.

In one embodiment of the present specification, R4 and R6 are the same as or different from each other, and each independently is hydrogen or deuterium.

In one embodiment of the present specification, R4 and R6 are hydrogen.

In one embodiment of the present specification, R4 and R6 are deuterium.

In one embodiment of the present specification, G1 is hydrogen, deuterium, a substituted or unsubstituted aryl group, or a substituted or unsubstituted heterocyclic group.

In one embodiment of the present specification, G1 is hydrogen, deuterium, a substituted or unsubstituted aryl group having 6 to 60 carbon atoms, or a substituted or unsubstituted heterocyclic group having 2 to 60 carbon atoms.

In one embodiment of the present specification, G1 is hydrogen, deuterium, a substituted or unsubstituted aryl group having 6 to 30 carbon atoms, or a substituted or unsubstituted heterocyclic group having 2 to 30 carbon atoms.

In one embodiment of the present specification, G1 is hydrogen or deuterium.

In one embodiment of the present specification, G1 is deuterium.

In one embodiment of the present specification, g1 is an integer of 0 to 7.

In one embodiment of the present specification, g1 is 7.

In one embodiment of the present specification, Chemical Formula 2-4 or 2-5 is any one of the following Chemical Formulae 2-4-1 to 2-4-4 and 2-5-1 to 2-5-2:

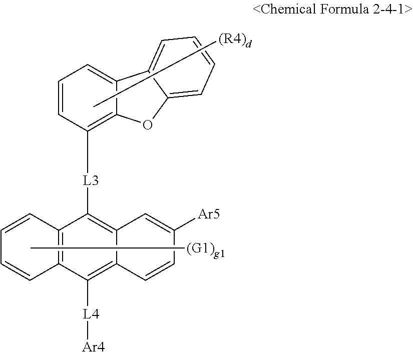

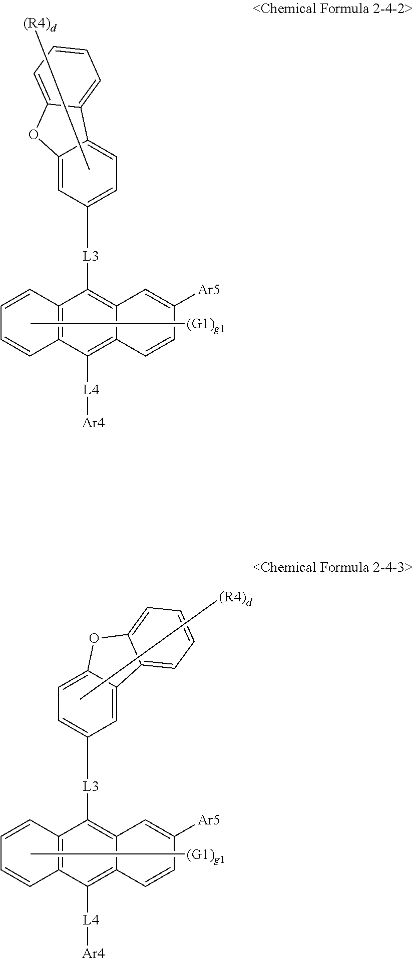

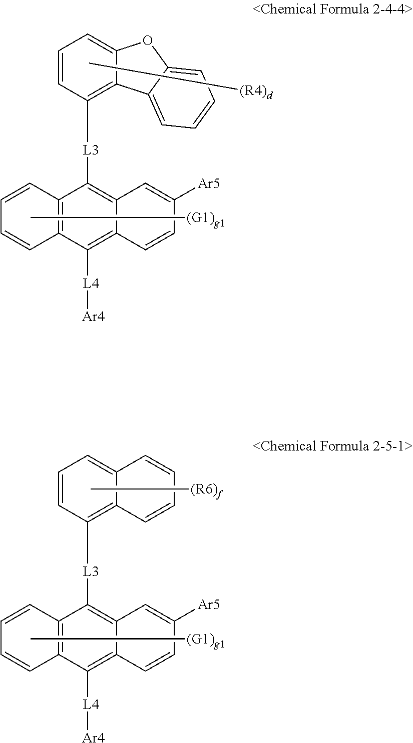

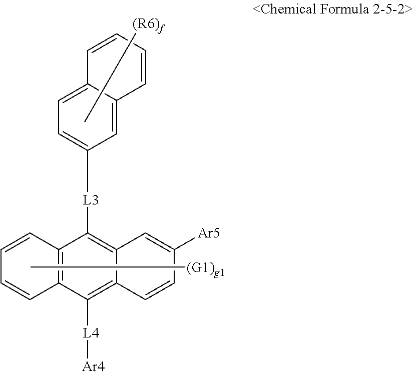

wherein in Chemical Formulae 2-4-1 to 2-4-4 and 2-5-1 to 2-5-2, L3, L4, Ar4, Ar5, G1, R4, R6, g1, d and f have the same definitions as in Chemical Formulae 2-4 and 2-5.

In one embodiment of the present specification, Ar5 is substituted with at least one deuterium.

In one embodiment of the present specification, when g1 is 2 or greater, at least one of the two or more G1s is deuterium. In another embodiment, at least two of the two or more G1s are deuterium. In another embodiment, at least four of the two or more G1s are deuterium. In another embodiment, at least six of the two or more G1s are deuterium. In another embodiment, the two or more G1s are all deuterium.

In one embodiment of the present specification, G1 is deuterium, and only L3 is substituted with deuterium.

In one embodiment of the present specification, G1 is deuterium, and only L4 is substituted with deuterium.

In one embodiment of the present specification, G1 is deuterium, and only Ar4 is substituted with deuterium.

In one embodiment of the present specification, G1 is deuterium, and only Ar5 is substituted with deuterium.

In one embodiment of the present specification, G1 is deuterium, and only L3 and L4 are substituted with deuterium.

In one embodiment of the present specification, G1 is deuterium, and only L3 and Ar4 are substituted with deuterium.

In one embodiment of the present specification, G1 is deuterium, and only L3 and Ar5 are substituted with deuterium.

In one embodiment of the present specification, G1 is deuterium, and only L4 and Ar4 are substituted with deuterium.

In one embodiment of the present specification, G1 is deuterium, and only L4 and Ar5 are substituted with deuterium.

In one embodiment of the present specification, G1 is deuterium, and only Ar4 and Ar5 are substituted with deuterium.

In one embodiment of the present specification, G1 is deuterium, and only L3, L4 and Ar4 are substituted with deuterium.

In one embodiment of the present specification, G1 is deuterium, and only L3, L4 and Ar5 are substituted with deuterium.

In one embodiment of the present specification, G1 is deuterium, and only L3, Ar4 and Ar5 are substituted with deuterium.

In one embodiment of the present specification, G1 is deuterium, and only L4, Ar4 and Ar5 are substituted with deuterium.

In one embodiment of the present specification, G1 is deuterium, and only L3, L4, Ar4 and Ar5 are substituted with deuterium.

In one embodiment of the present specification, Chemical Formula 2 is the following Chemical Formula A-1 or A-2:

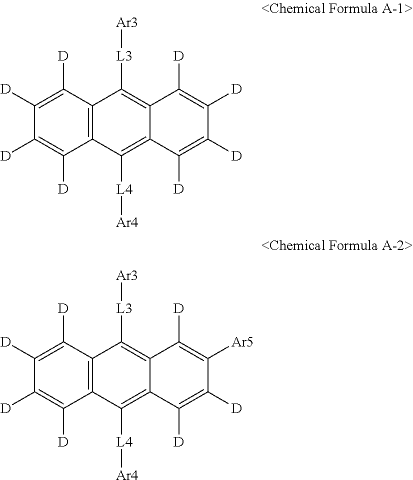

wherein in Chemical Formulae A-1 and A-2:

D means deuterium, and L3, L4, Ar3 and Ar4 have the same definitions as in Chemical Formula 2; and

Ar5 is a substituted or unsubstituted aryl group.

In one embodiment of the present specification, Ar5 has the same definition as in Chemical Formulae 2-4 and 2-5.

In one embodiment of the present specification, the compound of Chemical Formula 2 is substituted with deuterium by at least 40%. In another embodiment, the compound of Chemical Formula 2 is substituted with deuterium by 50% or greater. In another embodiment, the compound of Chemical Formula 2 is substituted with deuterium by 60% or greater. In another embodiment, the compound of Chemical Formula 2 is substituted with deuterium by 70% or greater. In another embodiment, the compound of Chemical Formula 2 is substituted with deuterium by 80% or greater. In another embodiment, the compound of Chemical Formula 2 is substituted with deuterium by 90% or greater. In another embodiment, the compound of Chemical Formula 2 is substituted with deuterium by 100%.

In one embodiment of the present specification, the compound of Chemical Formula 2 includes deuterium in 40% to 60%. In another embodiment, the compound of Chemical Formula 2 includes deuterium in 40% to 80%. In another embodiment, the compound of Chemical Formula 2 includes deuterium in 60% to 80%.

In one embodiment of the present specification, the compound of Chemical Formula 1 is any one of the following compounds:

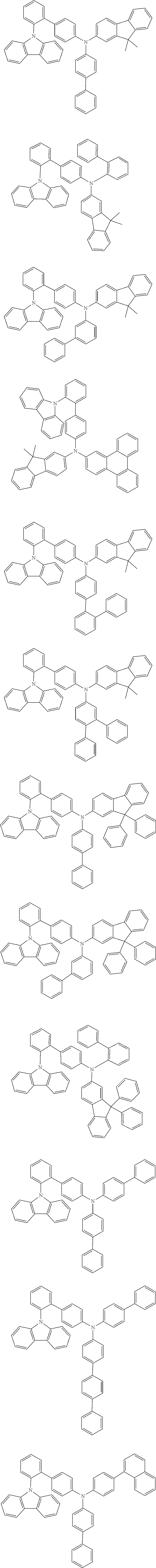

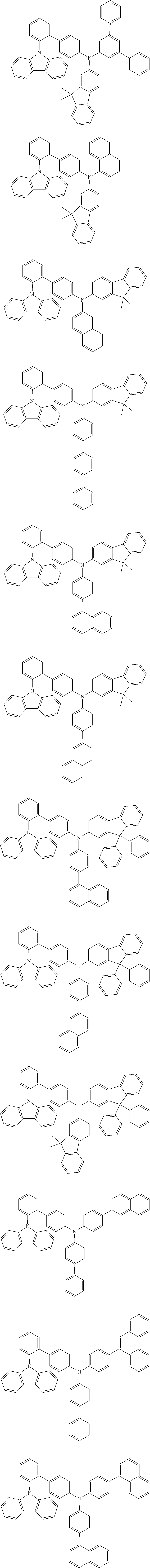

[chemical structure]

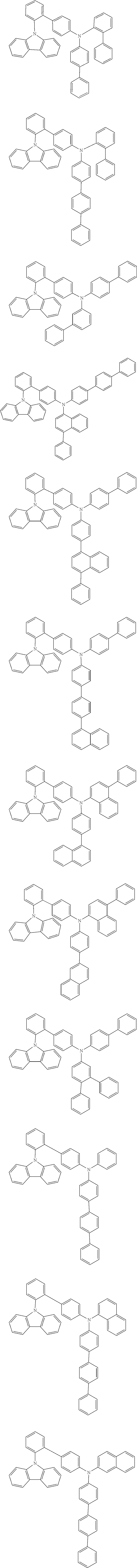

[chemical structure]

[chemical structure]

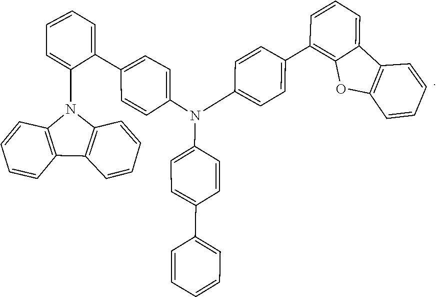 [SMILES: c1ccc(-c2ccc(N(c3ccc(-c4ccccc4-n4c5ccccc5c5ccccc54)cc3)c3ccc(-c4cccc5c4oc4ccccc45)cc3)cc2)cc1]

In one embodiment of the present specification, the compound of Chemical Formula 2 is any one of the following compounds:

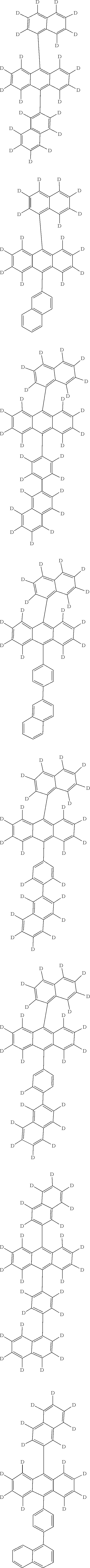

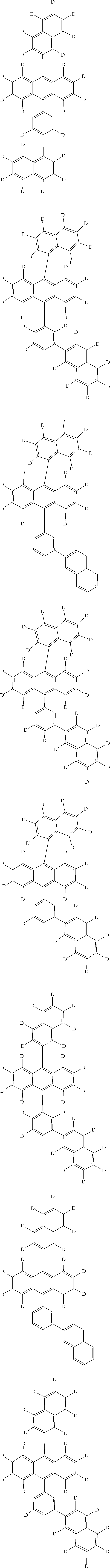

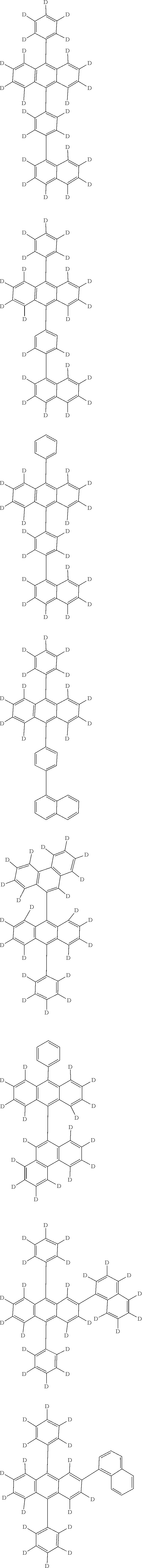

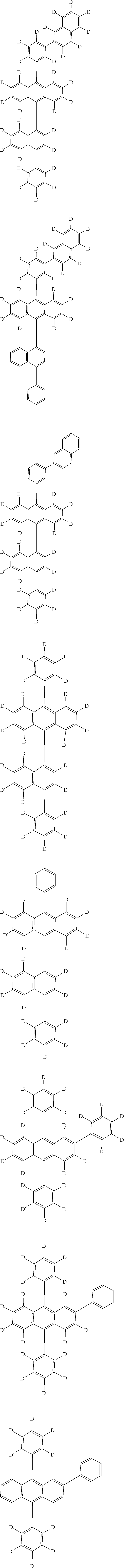

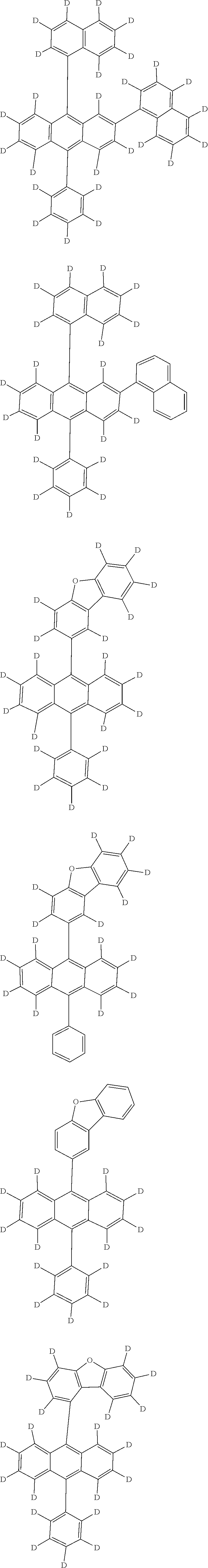

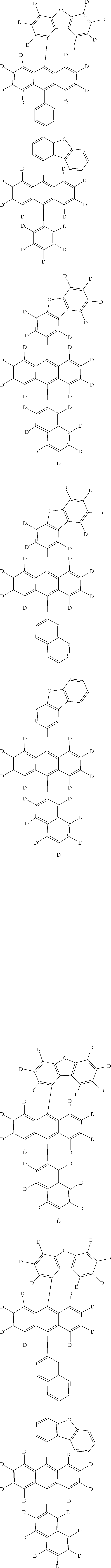

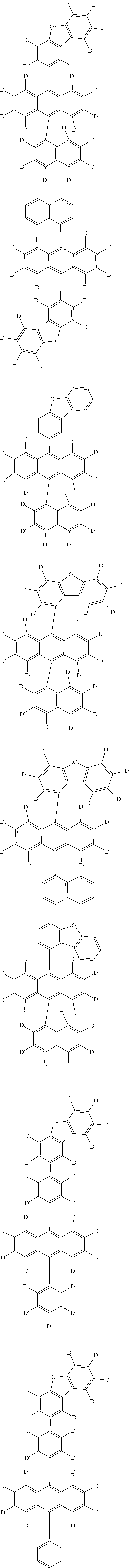

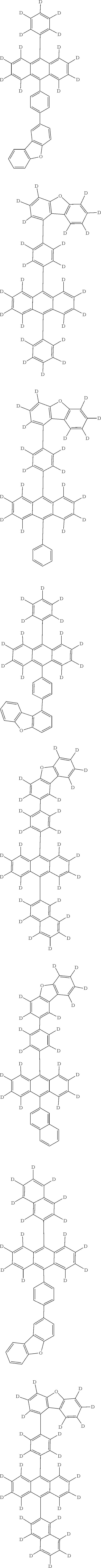

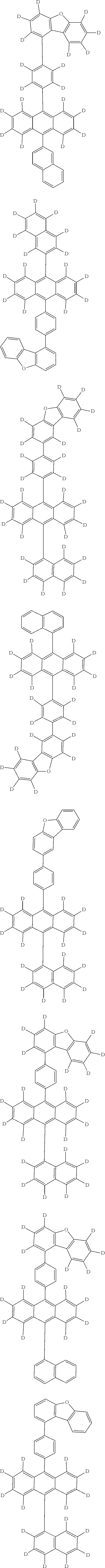

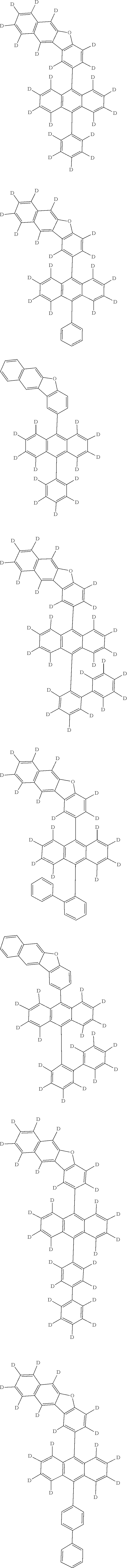

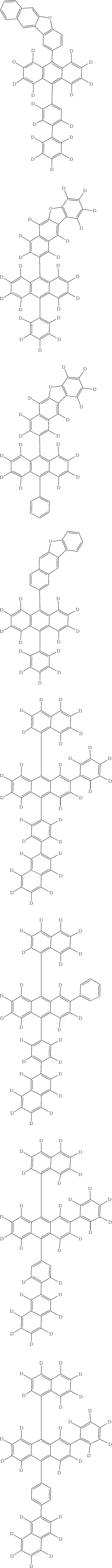

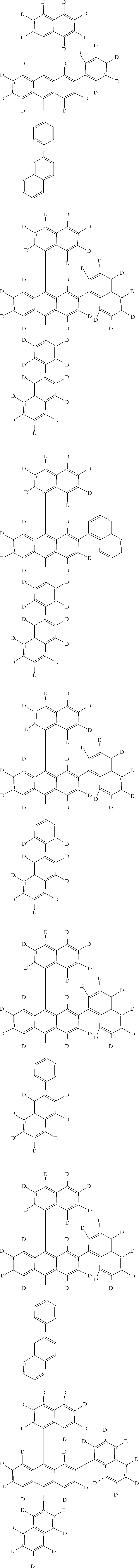

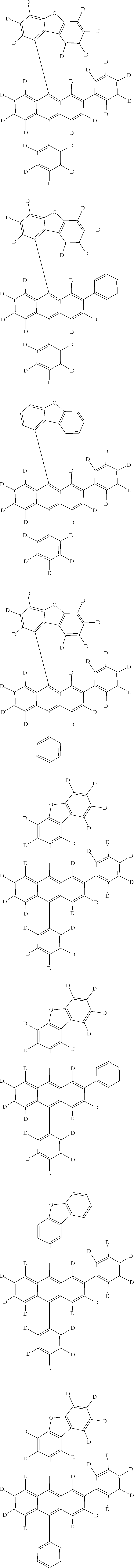

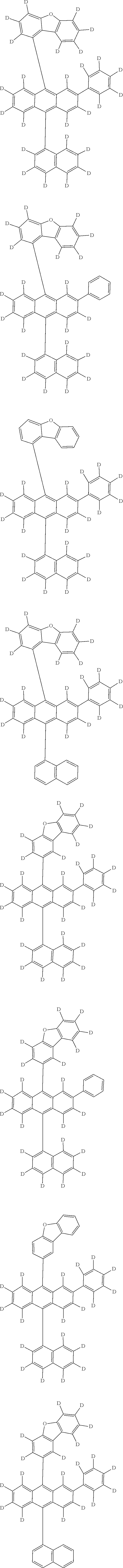

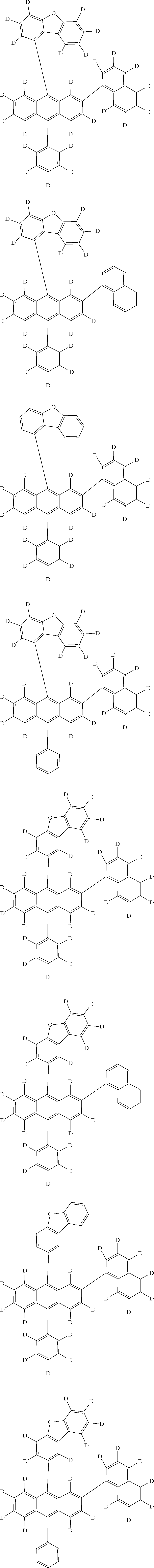

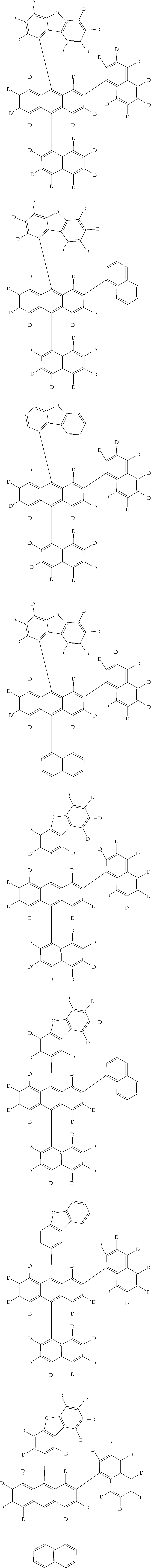

According to one embodiment of the present specification, the compound of Chemical Formula 1 can be prepared using a preparation method such as the following Reaction Formula 1 as one example, and other remaining compounds can be prepared in a similar manner.

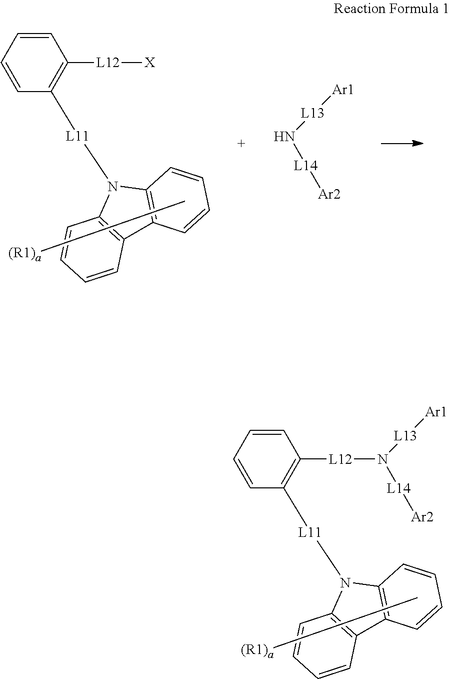

In Reaction Formula 1, L11 to L14, Ar1, Ar2, R1 and a have the same definitions as in Chemical Formula 1, X is a halogen group, and X is preferably chloro (—Cl) or bromo (—Br).

Reaction Formula 1 is an amine substitution reaction, and is preferably conducted under the presence of a palladium catalyst and a base, and reaction groups for the amine substitution reaction can vary as known in the art. The preparation method can be more specified in preparation examples to describe later.

According to one embodiment of the present specification, the compound of Chemical Formula 2 can be prepared according to the following Reaction Formula 2 to Reaction Formula 4, however, the preparation method is not limited thereto. In addition, the compounds prepared according to the following Reaction Formulae 2 and 3 can be substituted with deuterium through a process such as Reaction Formula 4. Herein, the deuterium substitution rate is from 40% to 100% in Reaction Formula 4. In the following Reaction Formulae 2 to 4, the types and the number of the substituents can be determined by those skilled in the art properly selecting known starting materials. As for the reaction type and the reaction condition, those known in the art can be used.

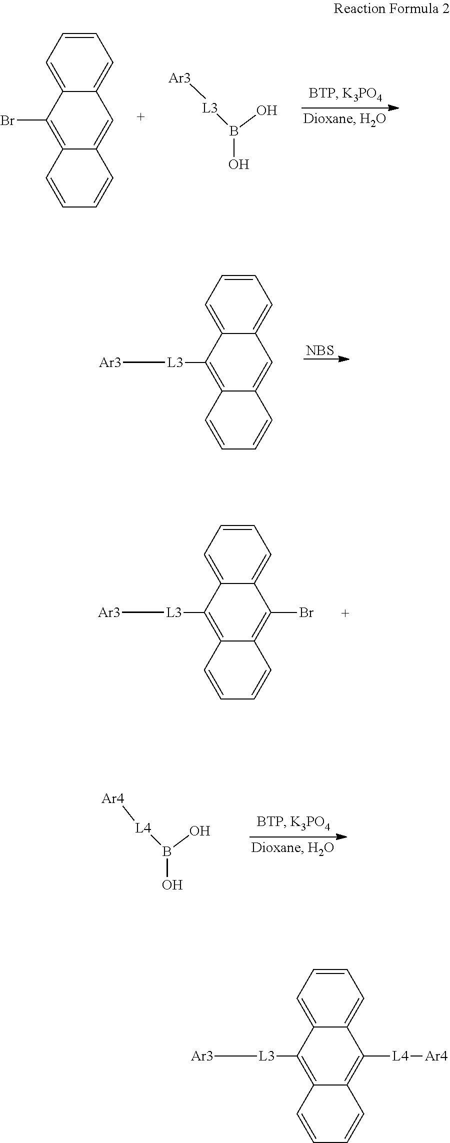

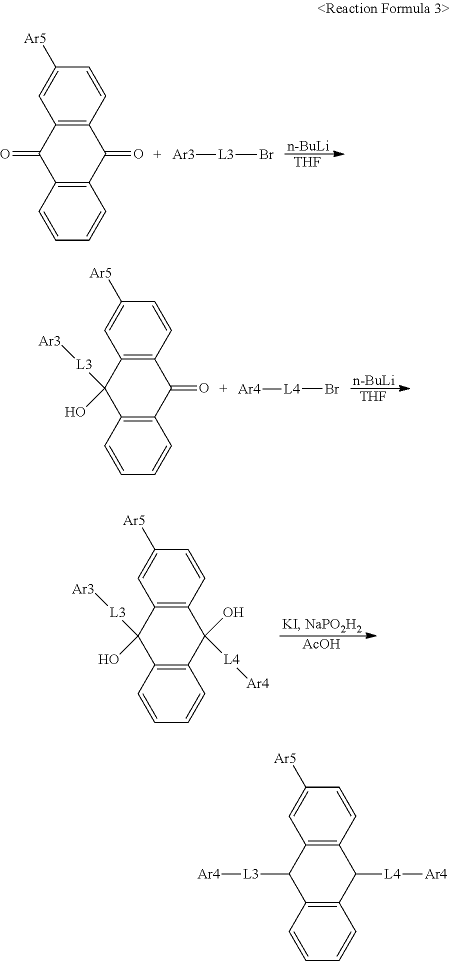

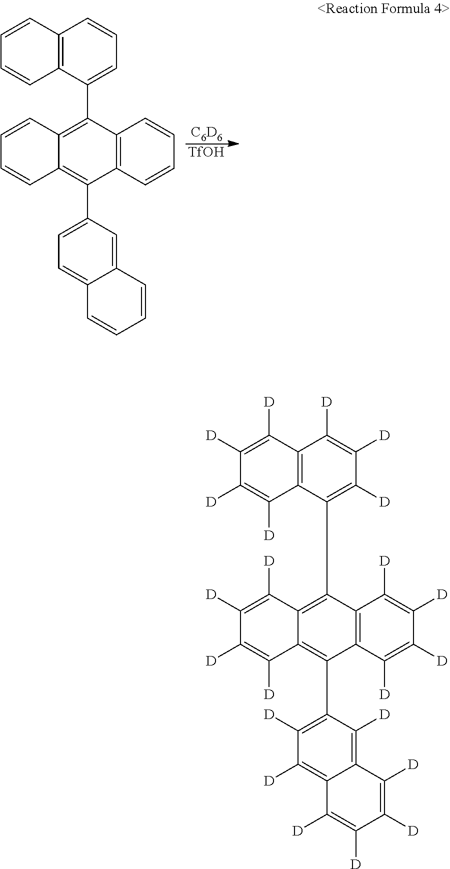

In the compound according to one embodiment of the present specification, the level of deuteration can be determined using an NMR analysis and a mass analysis method (mass spectrometry).

In the present specification, compounds having various energy band gaps can be synthesized by introducing various substituents to the core structures of the compounds of Chemical Formula 1 and Chemical Formula 2. In addition, HOMO and LUMO energy levels of the compounds can also be adjusted in the present specification by introducing various substituents to the core structures having structures as above.

Hereinafter, the organic light emitting device will be described.

The organic light emitting device according to the present specification includes an anode; a cathode; and a first organic material layer and a second organic material layer provided between the anode and the cathode, wherein the first organic material layer includes the compound of Chemical Formula 1 described above, and the second organic material layer includes the compound of Chemical Formula 2 described above.

The organic light emitting device of the present specification can be manufactured using common organic light emitting device manufacturing methods and materials except that the first organic material layer is formed using the compound of Chemical Formula 1 described above and the second organic material layer is formed using the compound of Chemical Formula 2 described above.

The compound can be formed to the organic material layer using a solution coating method as well as a vacuum deposition method when manufacturing the organic light emitting device. Herein, the solution coating method means spin coating, dip coating, inkjet printing, screen printing, a spray method, roll coating and the like, but is not limited thereto.

The organic material layer of the organic light emitting device of the present specification can be formed in a single layer structure, but can be formed in a multilayer structure in which two or more organic material layers are laminated. For example, the organic light emitting device of the present disclosure can have a structure including one or more of a hole transfer layer, a hole injection layer, an electron blocking layer, a hole transfer and injection layer, an electron transfer layer, an electron injection layer, a hole blocking layer, and an electron transfer and injection layer as the organic material layer. However, the structure of the organic light emitting device of the present specification is not limited thereto, and can include a smaller number or a larger number of organic material layers.

In the organic light emitting device of the present specification, the second organic material layer is a light emitting layer, and the first organic material layer is provided between the light emitting layer and the anode.

In the organic light emitting device of the present specification, the first organic material layer includes a hole injection layer, a hole transfer layer, a hole injection and transfer layer, or an electron blocking layer, and the hole injection layer, the hole transfer layer, the hole injection and transfer layer, or the electron blocking layer can include the compound of Chemical Formula 1 described above.

In the organic light emitting device of the present specification, the second organic material layer includes a hole injection layer, a hole transfer layer, a hole injection and transfer layer, or an electron blocking layer, and the hole injection layer, the hole transfer layer, the hole injection and transfer layer, or the electron blocking layer can include the compound of Chemical Formula 2 described above.

In another organic light emitting device of the present specification, the second organic material layer includes an electron transfer layer or an electron injection layer, and the electron transfer layer or the electron injection layer can include the compound of Chemical Formula 2 described above.

In another organic light emitting device of the present specification, the first organic material layer includes an electron blocking layer, and the electron blocking layer can include the compound of Chemical Formula 1 described above.

In another organic light emitting device of the present specification, the second organic material layer includes an electron blocking layer, and the electron blocking layer can include the compound of Chemical Formula 2 described above.

According to one example, the first organic material layer including the compound of Chemical Formula 1 has a thickness of 10 Å to 200 Å, and preferably 20 Å to 100 Å.

According to one example, the second organic material layer including the compound of Chemical Formula 2 has a thickness of 100 Å to 500 Å, and preferably 150 Å to 300 Å.

In the organic light emitting device of the present specification, the first organic material layer is an electron blocking layer, and the electron blocking layer can include the compound of Chemical Formula 1 described above.

In the organic light emitting device of the present specification, the second organic material layer is a light emitting layer, and the light emitting layer can include the compound of Chemical Formula 2 described above.

According to another embodiment, the second organic material layer is a light emitting layer, and the light emitting layer can include the compound of Chemical Formula 2 as a host of the light emitting layer.

According to another embodiment, the second organic material layer is a light emitting layer, and the light emitting layer can include the compound of Chemical Formula 2 as a dopant of the light emitting layer.

In one embodiment of the present specification, the second organic material layer is a light emitting layer, and the light emitting layer includes the compound of Chemical Formula 2 as a host of the light emitting layer, and can further include a dopant. Herein, a content of the dopant can be from 1 parts by weight to 60 parts by weight and preferably from 1 parts by weight to 10 parts by weight based on 100 parts by weight of the host.

Herein, as the dopant, phosphorescent materials such as (4,6-F2ppy)₂Irpic, or fluorescent materials such as spiro-DPVBi, spiro-6P, distyrylbenzene (DSB), distyrylarylene (DSA), PFO-based polymers, PPV-based polymers, anthracene-based compounds, pyrene-based compounds and boron-based compounds can be used, however, the dopant is not limited thereto.

In one embodiment of the present specification, the second organic material layer can further include a compound of the following Chemical Formula D-1.

In one embodiment of the present specification, the second organic material layer further includes a compound of the following Chemical Formula D-1, and a content of the compound of the following Chemical Formula D-1 can be, based on 100 parts by weight of the compound of Chemical Formula 2, from 1 parts by weight to 60 parts by weight, preferably from 1 parts by weight to 10 parts by weight and more preferably from 1 parts by weight to 5 parts by weight.

In one embodiment of the present specification, the second organic material layer is a light emitting layer, and the light emitting layer can further include the compound of the following Chemical Formula D-1 as a dopant.

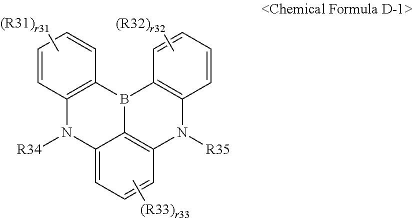

wherein in Chemical Formula D-1:

R31 to R35 are the same as or different from each other, and each independently is hydrogen, deuterium, a halogen group, a cyano group, a substituted or unsubstituted alkyl group, a substituted or unsubstituted cycloalkyl group, a substituted or unsubstituted arylalkyl group, a substituted or unsubstituted silyl group, a substituted or unsubstituted alkenyl group, a substituted or unsubstituted aryl group, a substituted or unsubstituted heterocyclic group, a substituted or unsubstituted alkoxy group, a substituted or unsubstituted aryloxy group, a substituted or unsubstituted alkylthio group, a substituted or unsubstituted arylthio group, or a substituted or unsubstituted amine group, or bond to adjacent substituents to form a substituted or unsubstituted ring; and

r31 to r33 are an integer of 1 to 4, and when r31 to r33 are 2 or greater, substituents in the parentheses are the same as or different from each other.

In one embodiment of the present specification, R31 to R35 are the same as or different from each other, and each independently is hydrogen, deuterium, a halogen group, a cyano group, a substituted or unsubstituted alkyl group having 1 to 30 carbon atoms, a substituted or unsubstituted cycloalkyl group having 6 to 60 carbon atoms, a substituted or unsubstituted arylalkyl group having 6 to 60 carbon atoms, a substituted or unsubstituted silyl group, a substituted or unsubstituted alkenyl group having 2 to 30 carbon atoms, a substituted or unsubstituted aryl group having 6 to 60 carbon atoms, a substituted or unsubstituted heterocyclic group having 2 to 60 carbon atoms, a substituted or unsubstituted alkoxy group having 1 to 30 carbon atoms; a substituted or unsubstituted aryloxy group having 6 to 60 carbon atoms, a substituted or unsubstituted alkylthio group having 1 to 30 carbon atoms; a substituted or unsubstituted arylthio group having 6 to 60 carbon atoms, or a substituted or unsubstituted amine group, or bond to adjacent substituents to form a substituted or unsubstituted ring having 2 to 60 carbon atoms.

In one embodiment of the present specification, R31 to R35 are the same as or different from each other, and each independently is hydrogen; deuterium, a halogen group; a cyano group, a substituted or unsubstituted alkyl group having 1 to 20 carbon atoms, a substituted or unsubstituted cycloalkyl group having 6 to 30 carbon atoms, a substituted or unsubstituted arylalkyl group having 6 to 30 carbon atoms, a substituted or unsubstituted silyl group, a substituted or unsubstituted alkenyl group having 2 to 20 carbon atoms, a substituted or unsubstituted aryl group having 6 to 30 carbon atoms, a substituted or unsubstituted heterocyclic group having 2 to 30 carbon atoms, a substituted or unsubstituted alkoxy group having 1 to 20 carbon atoms; a substituted or unsubstituted aryloxy group having 6 to 30 carbon atoms, a substituted or unsubstituted alkylthio group having 1 to 20 carbon atoms, a substituted or unsubstituted arylthio group having 6 to 30 carbon atoms, or a substituted or unsubstituted amine group, or bond to adjacent substituents to form a substituted or unsubstituted ring having 2 to 30 carbon atoms.

In one embodiment of the present specification, R31 to R35 are the same as or different from each other, and each independently is hydrogen, deuterium, a halogen group, a substituted or unsubstituted alkyl group, a substituted or unsubstituted aryl group, a substituted or unsubstituted heterocyclic group, or a substituted or unsubstituted amine group, or bond to adjacent substituents to form a substituted or unsubstituted aromatic hydrocarbon ring or a substituted or unsubstituted aliphatic hydrocarbon ring.

In one embodiment of the present specification, R31 to R35 are the same as or different from each other, and each independently is hydrogen, deuterium, a halogen group, a substituted or unsubstituted alkyl group, a substituted or unsubstituted aryl group, a substituted or unsubstituted heterocyclic group, or a substituted or unsubstituted amine group, or bond to adjacent substituents to form a substituted or unsubstituted aromatic hydrocarbon ring or a substituted or unsubstituted aliphatic hydrocarbon ring.

In one embodiment of the present specification, R31 to R35 are the same as or different from each other, and each independently is hydrogen; deuterium; a halogen group; an alkyl group that is unsubstituted or substituted with deuterium; an aryl group that is unsubstituted or substituted with one or more groups selected from the group consisting of deuterium, a halogen group, an alkyl group having 1 to 10 carbon atoms and an aryl group having 6 to 20 carbon atoms, or with a group linking two or more groups selected from the above-mentioned group; a heterocyclic group that is unsubstituted or substituted with one or more groups selected from the group consisting of deuterium, a halogen group, an alkyl group having 1 to 10 carbon atoms and an aryl group having 6 to 20 carbon atoms, or with a group linking two or more groups selected from the above-mentioned group; or an amine group that is unsubstituted or substituted with one or more groups selected from the group consisting of deuterium, a halogen group, an alkyl group having 1 to 10 carbon atoms and an aryl group having 6 to 20 carbon atoms, or with a group linking two or more groups selected from the above-mentioned group, or can bond to adjacent groups to form an aliphatic hydrocarbon ring that is unsubstituted or substituted with an alkyl group having 1 to 10 carbon atoms; or an aromatic hydrocarbon ring that is unsubstituted or substituted with deuterium or an alkyl group having 1 to 10 carbon atoms.

In the present specification, when a substituent bonds to adjacent groups to form a cycloalkane ring, the cycloalkane ring can include a double bond.

In one embodiment of the present specification, R31 to R35 are the same as or different from each other, and each independently is hydrogen; deuterium; a fluoro group; a methyl group; CD₃; an i-propyl group; a t-butyl group; a phenyl group that is unsubstituted or substituted with one or more groups selected from the group consisting of deuterium, a fluoro group, an alkyl group having 1 to 10 carbon atoms and an aryl group having 6 to 20 carbon atoms, or with a group linking two or more groups selected from the above-mentioned group; a biphenyl group that is unsubstituted or substituted with one or more groups selected from the group consisting of deuterium, a fluoro group, an alkyl group having 1 to 10 carbon atoms and an aryl group having 6 to 20 carbon atoms, or with a group linking two or more groups selected from the above-mentioned group; a naphthyl group that is unsubstituted or substituted with one or more groups selected from the group consisting of deuterium, a fluoro group, an alkyl group having 1 to 10 carbon atoms and an aryl group having 6 to 20 carbon atoms, or with a group linking two or more groups selected from the above-mentioned group; a carbazole group that is unsubstituted or substituted with one or more groups selected from the group consisting of deuterium, a fluoro group, an alkyl group having 1 to 10 carbon atoms and an aryl group having 6 to 20 carbon atoms, or with a group linking two or more groups selected from the above-mentioned group; a dibenzofuran group that is unsubstituted or substituted with one or more groups selected from the group consisting of deuterium, a fluoro group, an alkyl group having 1 to 10 carbon atoms and an aryl group having 6 to 20 carbon atoms, or with a group linking two or more groups selected from the above-mentioned group; or an amine group that is unsubstituted or substituted with one or more groups selected from the group consisting of deuterium, a fluoro group, an alkyl group having 1 to 10 carbon atoms, an aryl group having 6 to 20 carbon atoms and a heterocyclic group having 2 to 20 carbon atoms, or with a group linking two or more groups selected from the above-mentioned group, or can bond to adjacent groups to form a cyclopentane ring that is unsubstituted or substituted with a methyl group; a cyclohexane ring that is unsubstituted or substituted with a methyl group; a benzene ring; or a benzofuran ring, or to form structures as shown below:

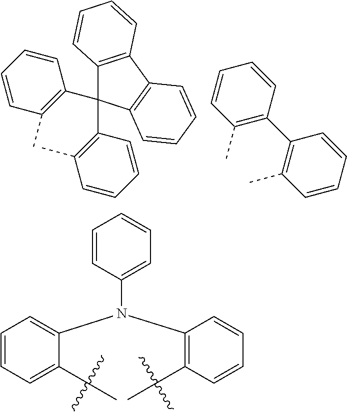

wherein the structures are unsubstituted or substituted with deuterium, the dotted line means a position bonding to N of Chemical Formula D-1, and

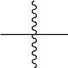

means a position bonding to B of Chemical Formula D-1.

In one embodiment of the present specification, r31 and r32 are an integer of 1 to 4.

In one embodiment of the present specification, r31 and r32 are 1 or 2.

In one embodiment of the present specification, r33 is an integer of 1 to 3.

In one embodiment of the present specification, R34 and R35 are the same as or different from each other, and each independently is a substituted or unsubstituted alkyl group, a substituted or unsubstituted aryl group, or a substituted or unsubstituted heterocyclic group, or bond to adjacent substituents to form a substituted or unsubstituted ring.

In one embodiment of the present specification, R34 and R35 are the same as or different from each other, and each independently is a substituted or unsubstituted alkyl group having 1 to 30 carbon atoms, a substituted or unsubstituted aryl group having 6 to 30 carbon atoms, or a substituted or unsubstituted heterocyclic group having 2 to 30 carbon atoms, or bond to adjacent substituents to form a substituted or unsubstituted ring having 2 to 30 carbon atoms.

In one embodiment of the present specification, R34 and R35 are the same as or different from each other, and each independently is a substituted or unsubstituted alkyl group having 1 to 20 carbon atoms, a substituted or unsubstituted aryl group having 6 to 20 carbon atoms, or a substituted or unsubstituted heterocyclic group having 2 to 20 carbon atoms, or bond to adjacent substituents to form a substituted or unsubstituted ring having 2 to 30 carbon atoms.

In one embodiment of the present specification, R34 and R35 are the same as or different from each other, and each independently is a methyl group, a substituted or unsubstituted phenyl group, a substituted or unsubstituted biphenyl group, or a substituted or unsubstituted dibenzofuran group, or bond to adjacent substituents to form a substituted or unsubstituted ring having 2 to 30 carbon atoms.

In one embodiment of the present specification, R34 and R35 are the same as or different from each other, and each independently is a methyl group; a phenyl group that is unsubstituted or substituted with one or more groups selected from the group consisting of deuterium, a halogen group, an alkyl group having 1 to 10 carbon atoms and an aryl group having 6 to 20 carbon atoms, or with a group linking two or more groups selected from the above-mentioned group; a biphenyl group that is unsubstituted or substituted with one or more groups selected from the group consisting of deuterium, a halogen group, an alkyl group having 1 to 10 carbon atoms and an aryl group having 6 to 20 carbon atoms, or with a group linking two or more groups selected from the above-mentioned group; or a dibenzofuran group, or bond to adjacent substituents to form a ring having 2 to 30 carbon atoms unsubstituted or substituted with deuterium.

In one embodiment of the present specification, R34 and R35 are the same as or different from each other, and each independently is a methyl group; a phenyl group that is unsubstituted or substituted with one or more groups selected from the group consisting of deuterium, a fluoro group, a methyl group, an i-propyl group, a t-butyl group and a phenyl group, or with a group linking two or more groups selected from the above-mentioned group; a biphenyl group that is unsubstituted or substituted with one or more groups selected from the group consisting of deuterium, a fluoro group, a methyl group, an i-propyl group, a t-butyl group and a phenyl group, or with a group linking two or more groups selected from the above-mentioned group; a naphthyl group that is unsubstituted or substituted with one or more groups selected from the group consisting of deuterium, a fluoro group, a methyl group, an i-propyl group, a t-butyl group and a phenyl group, or with a group linking two or more groups selected from the above-mentioned group; or a dibenzofuran group, or bond to adjacent substituents to form structures of

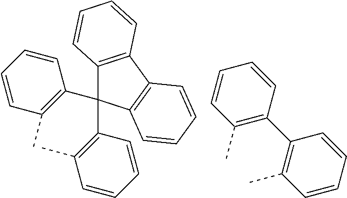

that are unsubstituted or substituted with deuterium.

In one embodiment of the present specification, R34 and R35 are the same as or different from each other, and each independently is a methyl group; a phenyl group that is unsubstituted or substituted with one or more groups selected from the group consisting of deuterium, a fluoro group, a methyl group, an i-propyl group, a t-butyl group and a phenyl group, or with a group linking two or more groups selected from the above-mentioned group; a biphenyl group that is unsubstituted or substituted with one or more groups selected from the group consisting of deuterium, a fluoro group, a methyl group, a t-butyl group and a phenyl group, or with a group linking two or more groups selected from the above-mentioned group; a naphthyl group; or a dibenzofuran group.

In one embodiment of the present specification, R34 and R35 are a phenyl group that is unsubstituted or substituted with a t-butyl group.

In one embodiment of the present specification, Chemical Formula D-1 is the following Chemical Formula D-2:

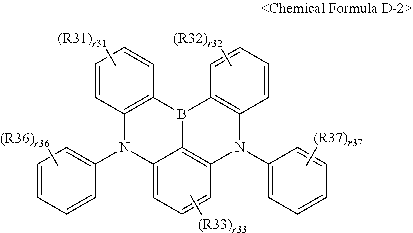

wherein in Chemical Formula D-2:

R31 to R33 and r31 to r33 have the same definitions as in Chemical Formula D-1;

R36 and R37 are the same as or different from each other, and each independently is hydrogen, deuterium, a halogen group, a cyano group, a substituted or unsubstituted alkyl group, a substituted or unsubstituted cycloalkyl group, a substituted or unsubstituted silyl group, a substituted or unsubstituted alkenyl group, a substituted or unsubstituted aryl group, a substituted or unsubstituted heterocyclic group, a substituted or unsubstituted alkoxy group, a substituted or unsubstituted aryloxy group, a substituted or unsubstituted alkylthio group; a substituted or unsubstituted arylthio group, or a substituted or unsubstituted amine group, or bond to adjacent substituents to form a substituted or unsubstituted ring; and

r36 and r37 are an integer of 0 to 5, and when r36 and r37 are 2 or greater, substituents in the parentheses are the same as or different from each other.

In one embodiment of the present specification, R31 and R32 are the same as or different from each other, and each independently is hydrogen, deuterium, a substituted or unsubstituted alkyl group, a substituted or unsubstituted aryl group, a substituted or unsubstituted heterocyclic group, or a substituted or unsubstituted amine group, or bond to adjacent substituents to form a substituted or unsubstituted ring.

In one embodiment of the present specification, R31 and R32 are the same as or different from each other, and each independently is hydrogen, deuterium, a substituted or unsubstituted alkyl group, a substituted or unsubstituted aryl group, a substituted or unsubstituted heterocyclic group, or a substituted or unsubstituted amine group, or bond to adjacent substituents to form a substituted or unsubstituted aliphatic hydrocarbon ring or a substituted or unsubstituted aromatic hydrocarbon ring.

In one embodiment of the present specification, R31 and R32 are the same as or different from each other, and each independently is hydrogen, deuterium, a substituted or unsubstituted alkyl group having 1 to 30 carbon atoms, a substituted or unsubstituted aryl group having 6 to 30 carbon atoms, a substituted or unsubstituted heterocyclic group having 2 to 30 carbon atoms, or a substituted or unsubstituted amine group, or bond to adjacent substituents to form a substituted or unsubstituted aliphatic hydrocarbon ring having 3 to 30 carbon atoms or a substituted or unsubstituted aromatic hydrocarbon ring having 6 to 30 carbon atoms.

In one embodiment of the present specification, R31 and R32 are the same as or different from each other, and each independently is hydrogen, deuterium, a substituted or unsubstituted alkyl group having 1 to 20 carbon atoms, a substituted or unsubstituted aryl group having 6 to 20 carbon atoms, a substituted or unsubstituted heterocyclic group having 2 to 20 carbon atoms, or a substituted or unsubstituted amine group, or bond to adjacent substituents to form a substituted or unsubstituted aliphatic hydrocarbon ring having 3 to 20 carbon atoms or a substituted or unsubstituted aromatic hydrocarbon ring having 6 to 20 carbon atoms.

In one embodiment of the present specification, R31 and R32 are the same as or different from each other, and each independently is hydrogen; deuterium; a methyl group; a propyl group; a butyl group; a phenyl group that is unsubstituted or substituted with an alkyl group having 1 to 10 carbon atoms; a carbazole group; or an amine group that is unsubstituted or substituted with one or more groups selected from the group consisting of deuterium, a halogen group, an alkyl group having 1 to 10 carbon atoms, an aryl group having 6 to 20 carbon atoms and a heterocyclic group having 2 to 20 carbon atoms, or with a group linking two or more groups selected from the above-mentioned group.

In one embodiment of the present specification, R31 and R32 are the same as or different from each other, and each independently is hydrogen; deuterium; a methyl group; an i-propyl group; a t-butyl group; a phenyl group that is unsubstituted or substituted with a methyl group; a carbazole group; or an amine group that is unsubstituted or substituted with one or more groups selected from the group consisting of deuterium, a fluoro group, a methyl group, a t-butyl group, a phenyl group and a dibenzofuran group, or with a group linking two or more groups selected from the above-mentioned group.

In one embodiment of the present specification, R31 and R32 can bond to adjacent groups to form a substituted or unsubstituted ring.

In one embodiment of the present specification, R31 and R32 can bond to adjacent groups to form a substituted or unsubstituted aliphatic hydrocarbon ring or a substituted or unsubstituted aromatic hydrocarbon ring.

In one embodiment of the present specification, R31 and R32 can bond to adjacent groups to form a substituted or unsubstituted cyclopentane ring, a substituted or unsubstituted cyclohexane ring, a substituted or unsubstituted benzene ring, or a substituted or unsubstituted fluorene ring, or to form structures as shown below:

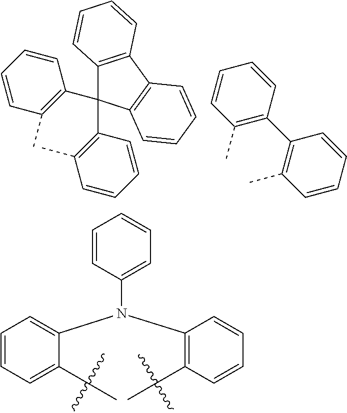

wherein the structures are substituted or unsubstituted, the dotted line means a position bonding to N of Chemical Formula D-1, and

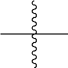

means a position bonding to B of Chemical Formula D-1.

In one embodiment of the present specification, R31 and R32 can bond to adjacent groups to form a cyclopentane ring that is unsubstituted or substituted with a methyl group; a cyclohexane ring that is unsubstituted or substituted with a methyl group; or a benzene ring, or to form structures as shown below:

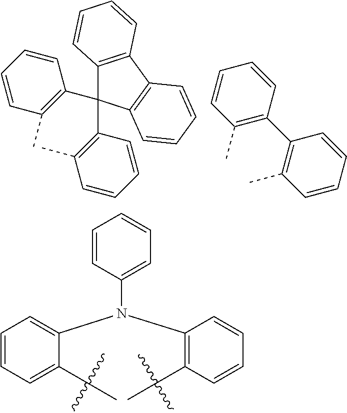

wherein the structures are unsubstituted or substituted with deuterium, the dotted line means a position bonding to N of Chemical Formula D-1, and

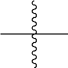

means a position bonding to B of Chemical Formula D-1.

In one embodiment of the present specification, when r31 is 2 or greater, R31 can bond to another R31, bond to R32 or bond to R36 to form a ring structure.

In one embodiment of the present specification, when r32 is 2 or greater, R32 can bond to another R32, bond to R31 or bond to R37 to form a ring structure.

In one embodiment of the present specification, when r31 and r32 are 2 or greater, R31 can bond to another R31, or R32 can bond to another R32 to form a cyclopentane ring that is unsubstituted or substituted with a methyl group; a cyclohexane ring that is unsubstituted or substituted with a methyl group; or a benzene ring.

In one embodiment of the present specification, R31 can bond to R32 to form.

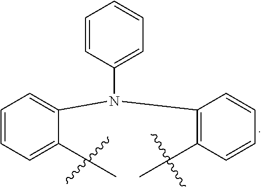 [SMILES: *c1ccccc1N(c1ccccc1)c1ccccc1*]

### Herein,

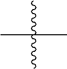

means a position bonding to B of Chemical Formula D-1.

In one embodiment of the present specification, R31 can bond to R36, and R32 can bond to R37 to form structures of

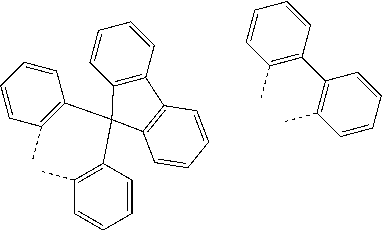

that are unsubstituted or substituted with deuterium. Herein, in the structures, the dotted line means a position bonding to N of Chemical Formula D-2.

In one embodiment of the present specification, R31 and R32 are the same as or different from each other, and each independently is a substituted or unsubstituted alkyl group, or can bond to adjacent groups to form a substituted or unsubstituted aliphatic hydrocarbon ring.

In one embodiment of the present specification, R31 and R32 are a t-butyl group, or can bond to adjacent groups to form a substituted or unsubstituted cyclohexane ring.

In one embodiment of the present specification, R31 and R32 are a t-butyl group, or can bond to adjacent groups to form a cyclohexane ring that is unsubstituted or substituted with a methyl group.

In one embodiment of the present specification, R36 and R37 are the same as or different from each other, and each independently is hydrogen, deuterium, a halogen group, a substituted or unsubstituted alkyl group, a substituted or unsubstituted cycloalkyl group, a substituted or unsubstituted aryl group, or a substituted or unsubstituted heterocyclic group, or bond to adjacent substituents to form a substituted or unsubstituted aromatic hydrocarbon ring; or aliphatic hydrocarbon ring.

In one embodiment of the present specification, R36 and R37 are the same as or different from each other, and each independently is hydrogen, deuterium, a halogen group, a substituted or unsubstituted alkyl group having 1 to 30 carbon atoms, a substituted or unsubstituted aryl group having 6 to 30 carbon atoms, or a substituted or unsubstituted heterocyclic group having 2 to 30 carbon atoms, or bond to adjacent substituents to form a substituted or unsubstituted aromatic hydrocarbon ring having 6 to 30 carbon atoms.

In one embodiment of the present specification, R36 and R37 are the same as or different from each other, and each independently is hydrogen, deuterium, a halogen group, a substituted or unsubstituted alkyl group having 1 to 20 carbon atoms; a substituted or unsubstituted aryl group having 6 to 20 carbon atoms, or a substituted or unsubstituted heterocyclic group having 2 to 20 carbon atoms, or bond to adjacent substituents to form a substituted or unsubstituted aromatic hydrocarbon ring having 6 to 20 carbon atoms.

In one embodiment of the present specification, R36 and R37 are the same as or different from each other, and each independently is hydrogen; deuterium; a methyl group; a propyl group; a butyl group; a phenyl group that is unsubstituted or substituted with one or more groups selected from the group consisting of deuterium, a halogen group and an alkyl group having 1 to 10 carbon atoms, or with a group linking two or more groups selected from the above-mentioned group, or bond to adjacent substituents to form a benzene ring, a benzofuran ring, or structures as shown below:

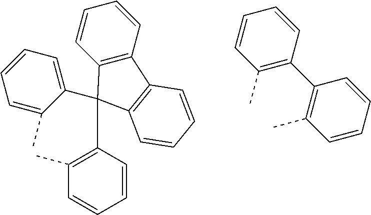

wherein the structures are unsubstituted or substituted with deuterium, and the dotted line means a position bonding to N of Chemical Formula D-2.

In one embodiment of the present specification, R36 and R37 are the same as or different from each other, and each independently is hydrogen; deuterium; a methyl group; an i-propyl group; a t-butyl group; a phenyl group that is unsubstituted or substituted with one or more groups selected from the group consisting of deuterium, a fluoro group, a methyl group and a t-butyl group, or with a group linking two or more groups selected from the above-mentioned group, or bond to adjacent substituents to form a benzene ring, a benzofuran ring, or structures as shown below:

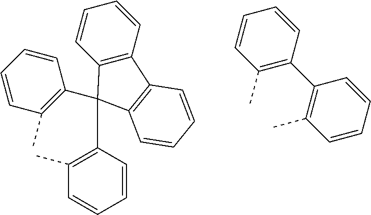

wherein the structures are unsubstituted or substituted with deuterium, and the dotted line means a position bonding to N of Chemical Formula D-2.

In one embodiment of the present specification, R36 and R37 are the same as or different from each other, and each independently is hydrogen; deuterium; a methyl group; an i-propyl group; a t-butyl group; a phenyl group that is unsubstituted or substituted with deuterium, a fluoro group, a methyl group, CD₃ or a t-butyl group, or bond to R31 or R32 to form a benzene ring, a benzofuran ring, or structures as shown below:

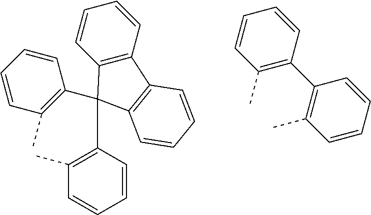

wherein the structures are unsubstituted or substituted with deuterium, and the dotted line means a position bonding to N of Chemical Formula D-2.

In one embodiment of the present specification, R36 and R37 are the same as or different from each other, and each independently is a substituted or unsubstituted alkyl group.

In one embodiment of the present specification, R36 and R37 are a t-butyl group.

In one embodiment of the present specification, R33 is hydrogen, deuterium, a substituted or unsubstituted alkyl group, a substituted or unsubstituted aryl group, a substituted or unsubstituted heterocyclic group, or a substituted or unsubstituted amine group, or bonds to adjacent substituents to form a substituted or unsubstituted ring.

In one embodiment of the present specification, R33 is hydrogen, deuterium, a substituted or unsubstituted alkyl group; a substituted or unsubstituted aryl group, a substituted or unsubstituted heterocyclic group, or a substituted or unsubstituted amine group, or bonds to adjacent substituents to form a substituted or unsubstituted aliphatic hydrocarbon ring or a substituted or unsubstituted aromatic hydrocarbon ring.

In one embodiment of the present specification, R33 is hydrogen, deuterium, a substituted or unsubstituted alkyl group having 1 to 30 carbon atoms, a substituted or unsubstituted aryl group having 6 to 30 carbon atoms, a substituted or unsubstituted heterocyclic group having 2 to 30 carbon atoms, or a substituted or unsubstituted amine group, or bonds to adjacent substituents to form a substituted or unsubstituted aliphatic hydrocarbon ring having 3 to 30 carbon atoms or a substituted or unsubstituted aromatic hydrocarbon ring having 6 to 30 carbon atoms.

In one embodiment of the present specification, R33 is hydrogen, deuterium, a substituted or unsubstituted alkyl group having 1 to 20 carbon atoms, a substituted or unsubstituted aryl group having 6 to 20 carbon atoms, a substituted or unsubstituted heterocyclic group having 2 to 20 carbon atoms, or a substituted or unsubstituted amine group, or bonds to adjacent substituents to form a substituted or unsubstituted aliphatic hydrocarbon ring having 3 to 20 carbon atoms or a substituted or unsubstituted aromatic hydrocarbon ring having 6 to 20 carbon atoms.

In one embodiment of the present specification, R33 is hydrogen; deuterium; an alkyl group having 1 to 20 carbon atoms that are unsubstituted or substituted with deuterium; a heterocyclic group having 2 to 20 carbon atoms that are unsubstituted or substituted with an alkyl group having 1 to 20 carbon atoms; or an amine group that is unsubstituted or substituted with one or more groups selected from the group consisting of deuterium, an alkyl group having 1 to 20 carbon atoms and an aryl group having 6 to 20 carbon atoms, or with a group linking two or more groups selected from the above-mentioned group, or bonds to adjacent substituents to form a substituted or unsubstituted aromatic hydrocarbon ring having 6 to 20 carbon atoms.

In one embodiment of the present specification, R33 is hydrogen; deuterium; a methyl group; CD₃; a butyl group; an amine group that is unsubstituted or substituted with one or more groups selected from the group consisting of deuterium, an alkyl group having 1 to 10 carbon atoms and an aryl group having 6 to 20 carbon atoms, or with a group linking two or more groups selected from the above-mentioned group; or a carbazole group that is unsubstituted or substituted with an alkyl group having 1 to 10 carbon atoms, or bonds to adjacent substituents to form a benzene ring; or a benzofuran ring.

In one embodiment of the present specification, R33 is hydrogen; deuterium; a methyl group; CD₃; a t-butyl group; an amine group that is unsubstituted or substituted with one or more groups selected from the group consisting of deuterium, a methyl group, a t-butyl group and a phenyl group, or with a group linking two or more groups selected from the above-mentioned group; or a carbazole group that is unsubstituted or substituted with a t-butyl group, or bonds to adjacent substituents to form a benzene ring; or a benzofuran ring.

In one embodiment of the present specification, R33 is a substituted or unsubstituted alkyl group.

In one embodiment of the present specification, R33 is a substituted or unsubstituted methyl group.

In one embodiment of the present specification, R33 is a methyl group.

In one embodiment of the present specification, r36 and r37 are an integer of 0 to 5.

In one embodiment of the present specification, r36 and r37 are an integer of 1 to 5.

In one embodiment of the present specification, the compound of Chemical Formula D-1 is any one of the following compounds:

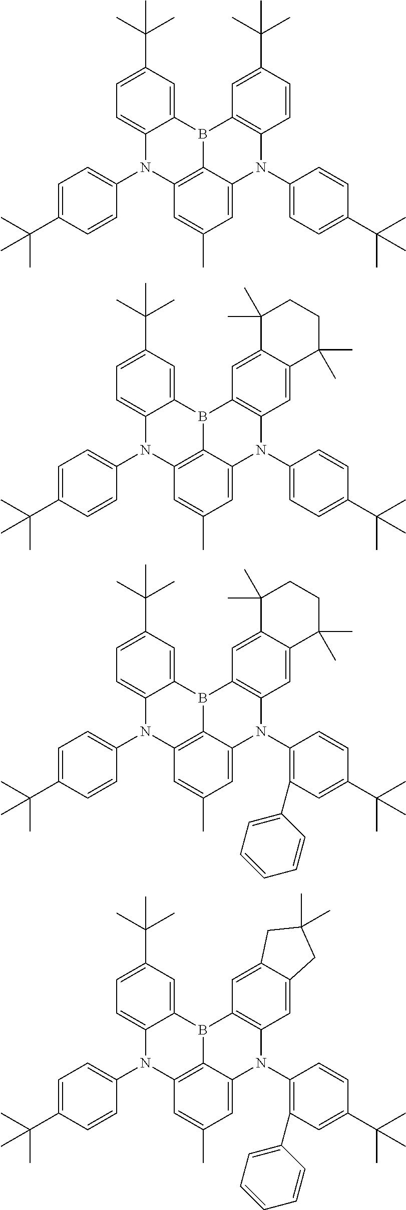

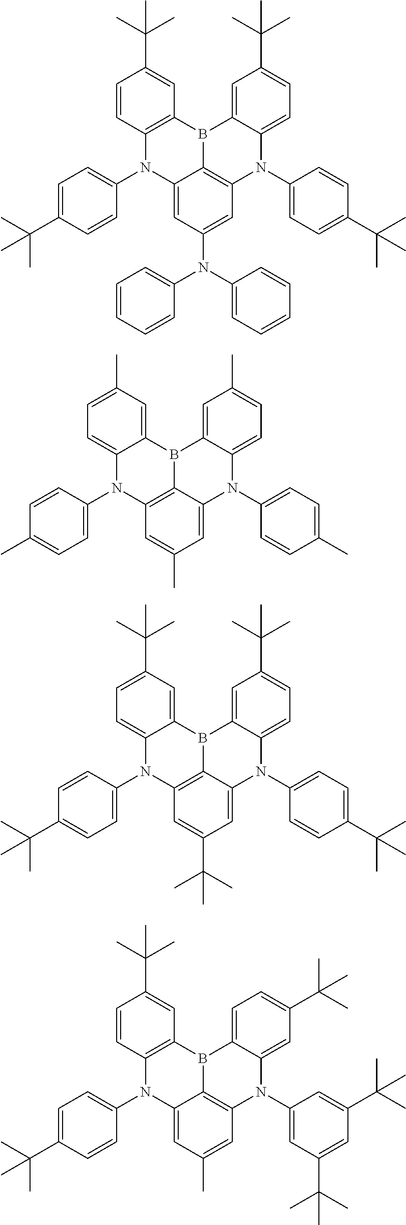

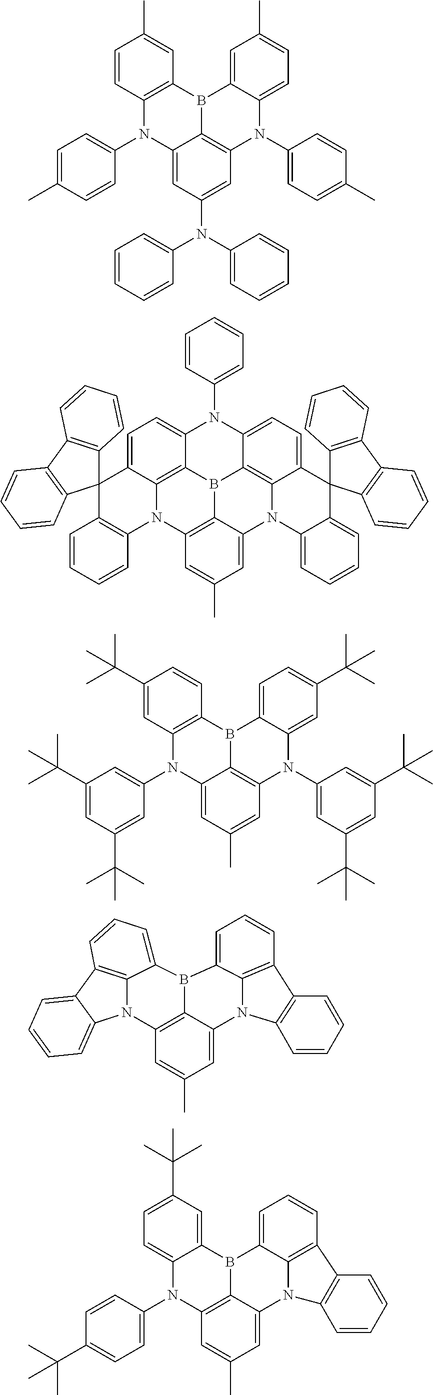

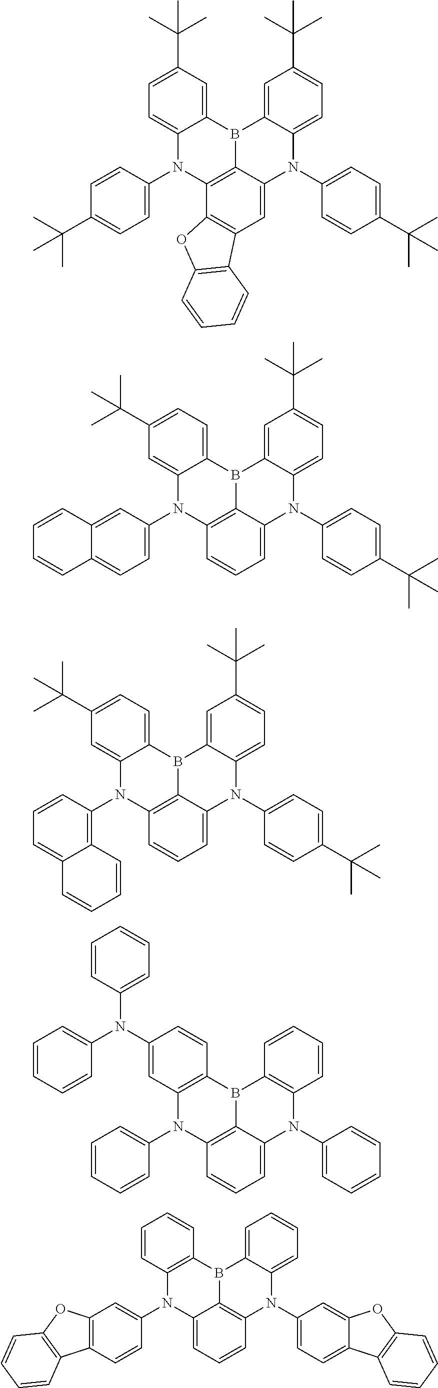

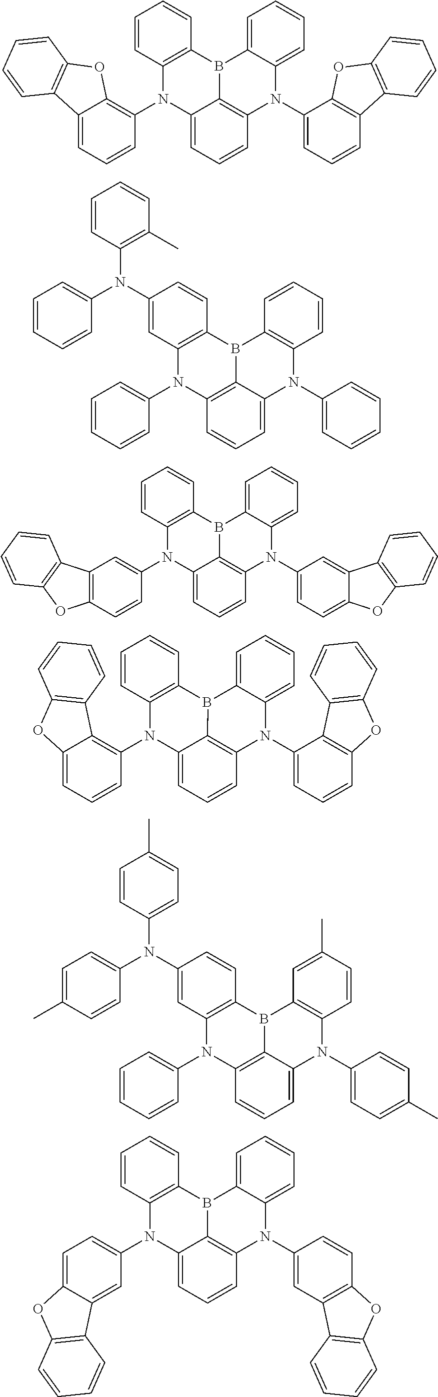

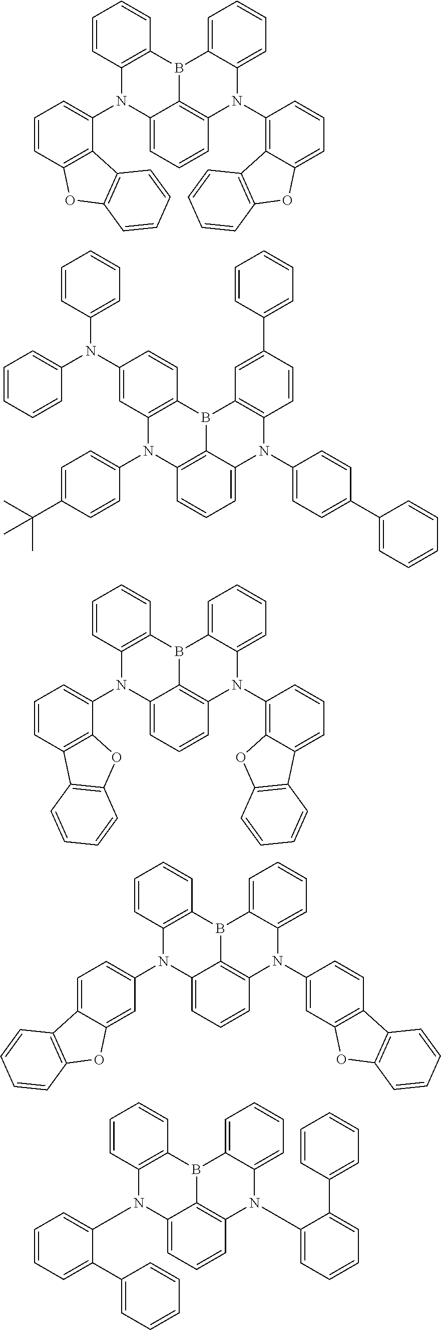

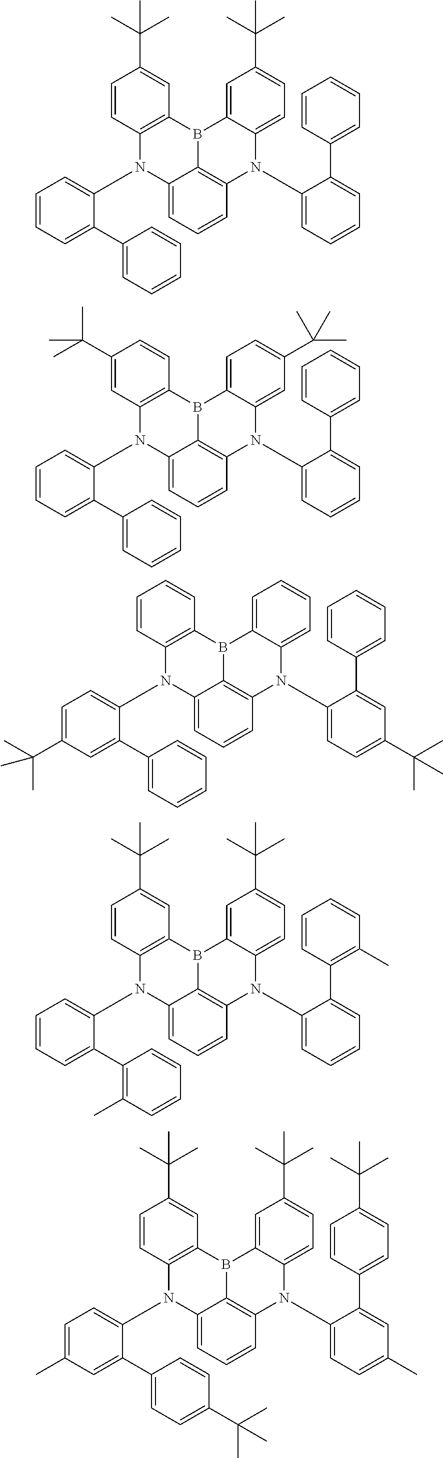

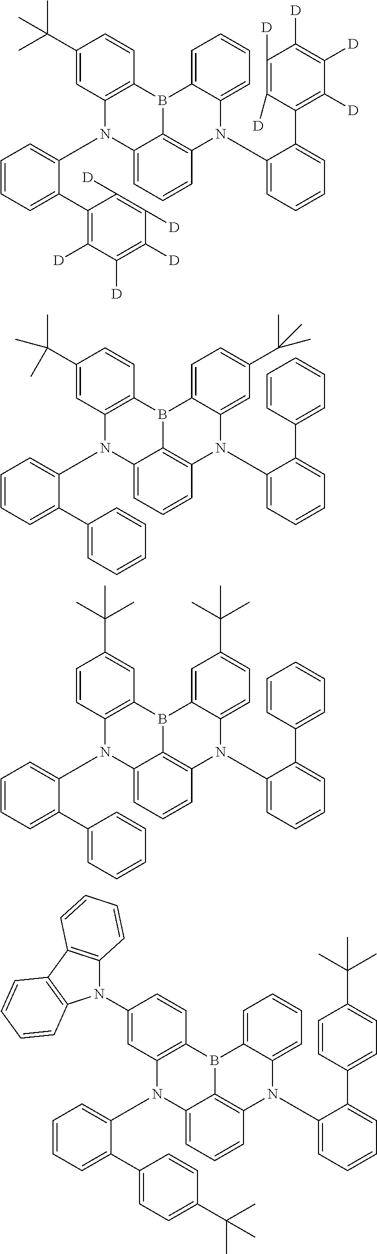

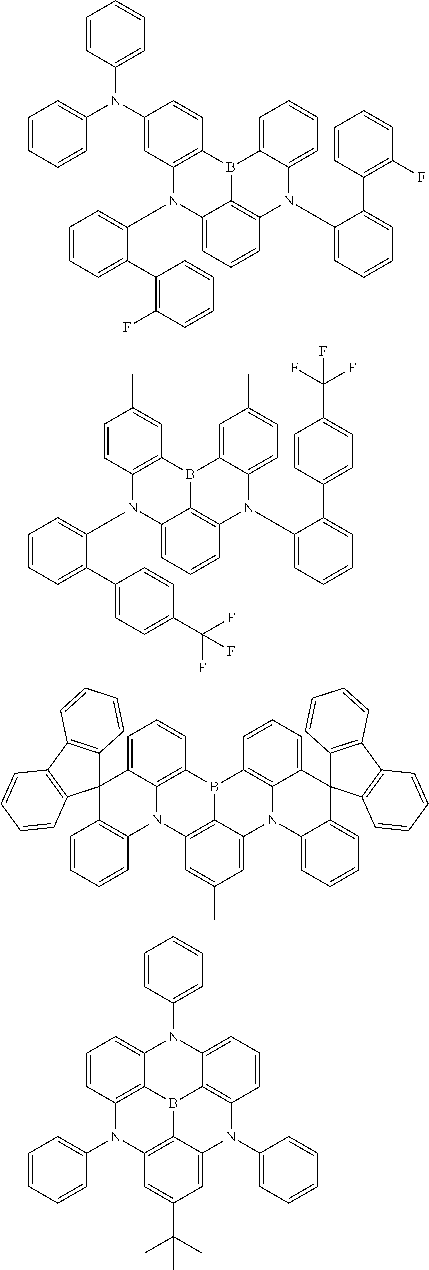

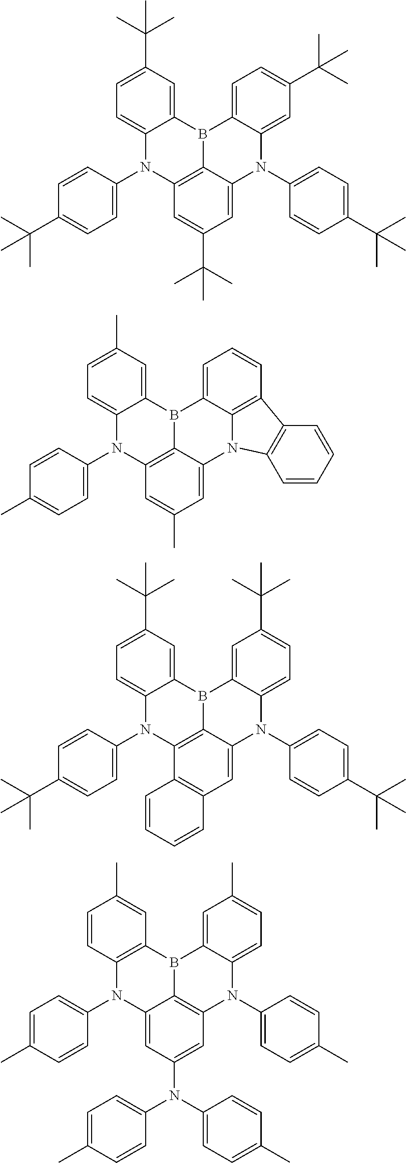

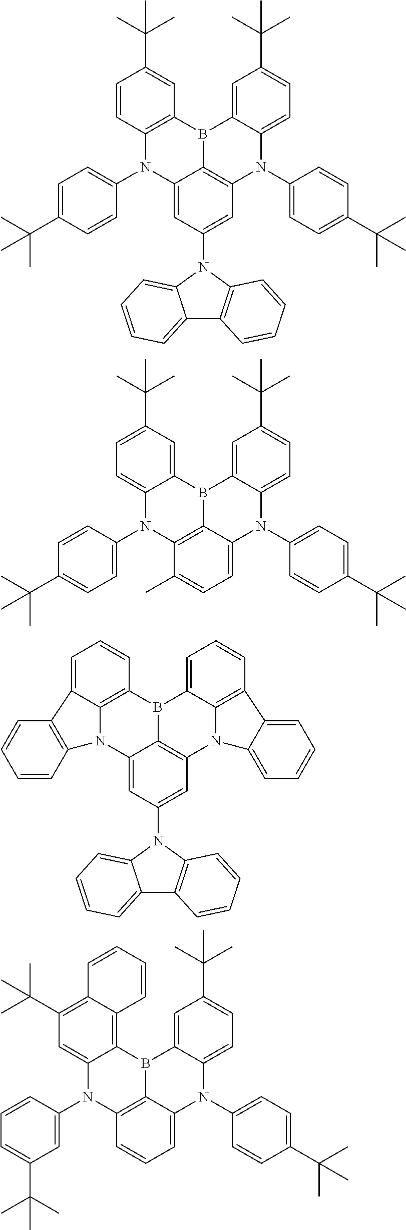

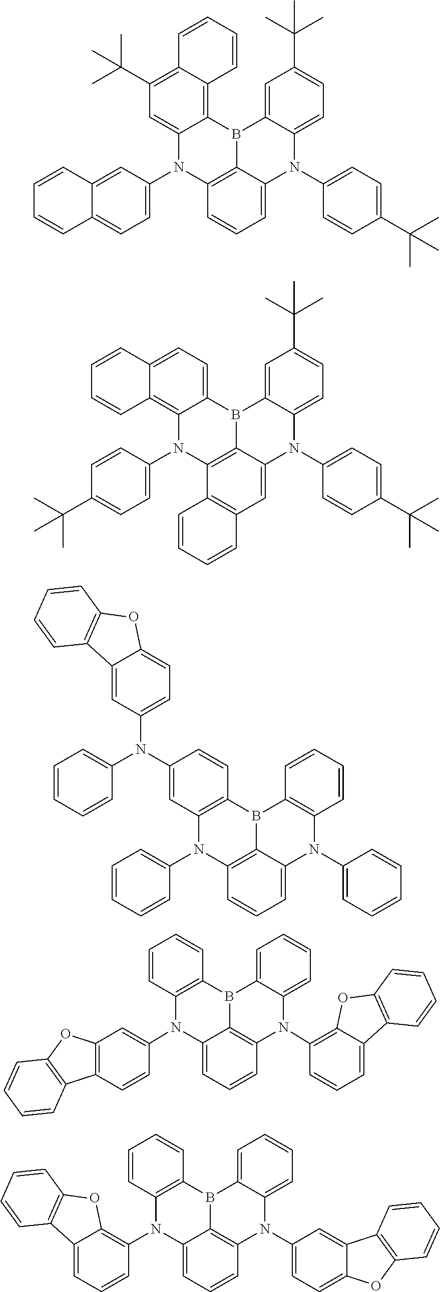

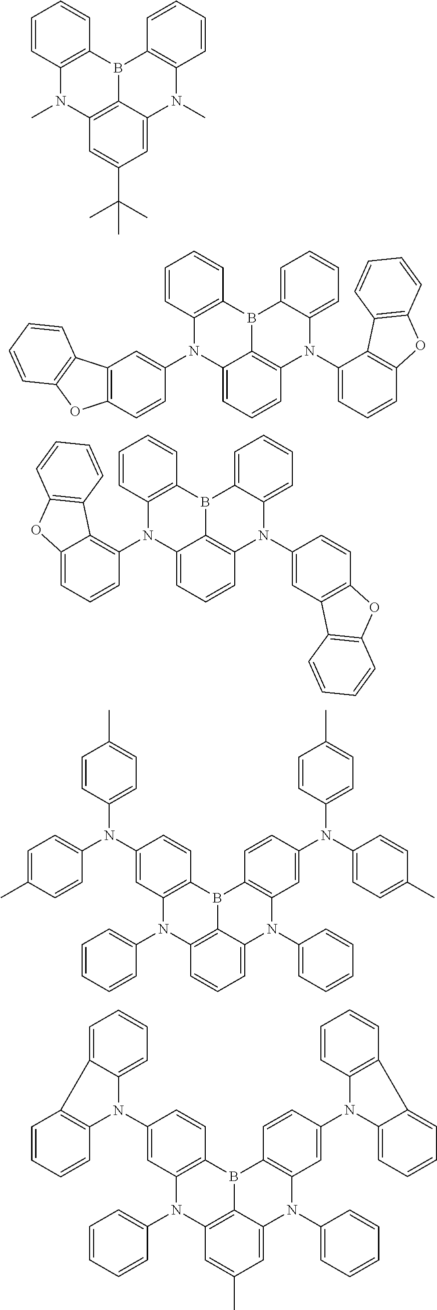

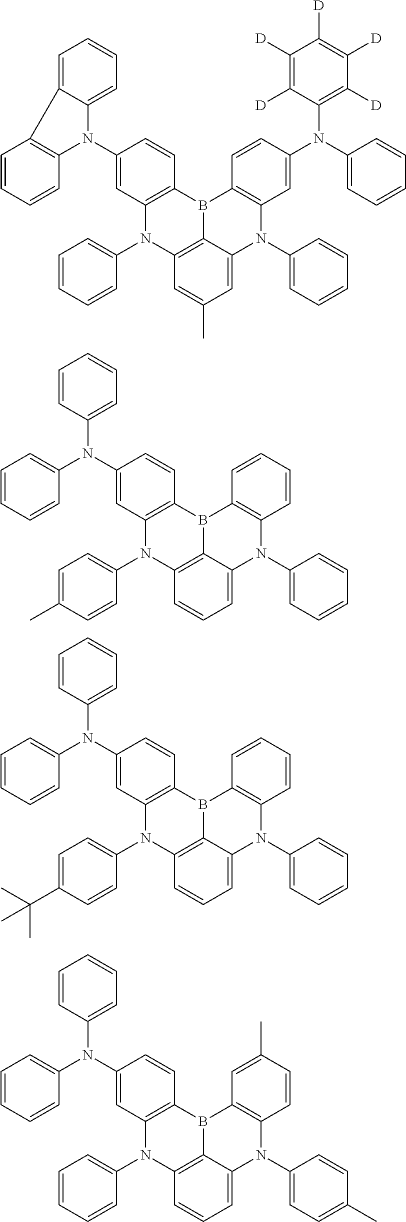

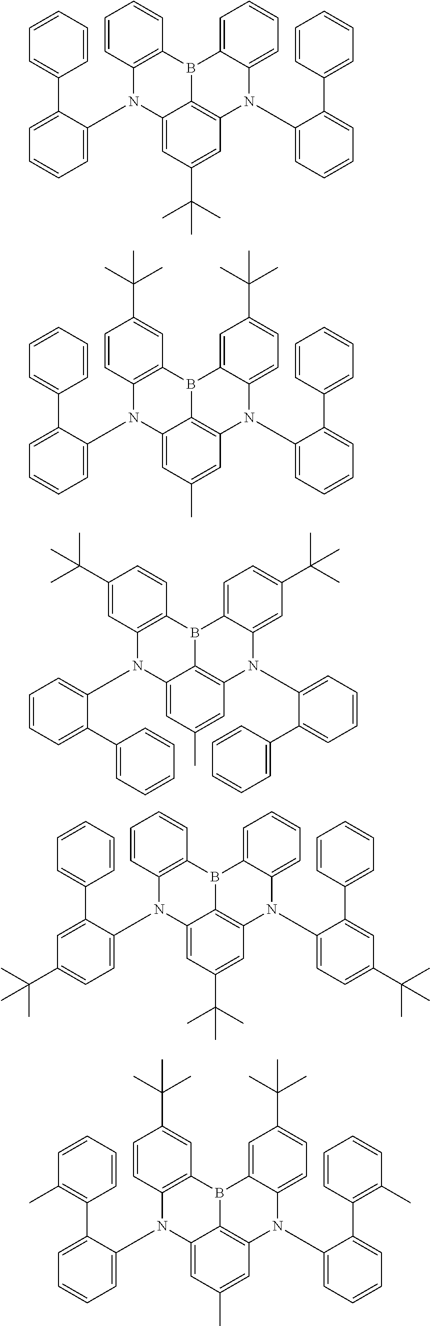

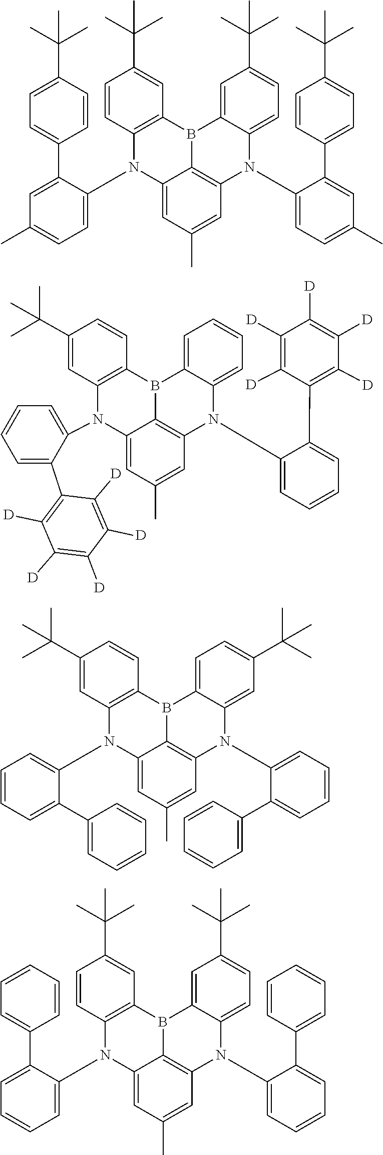

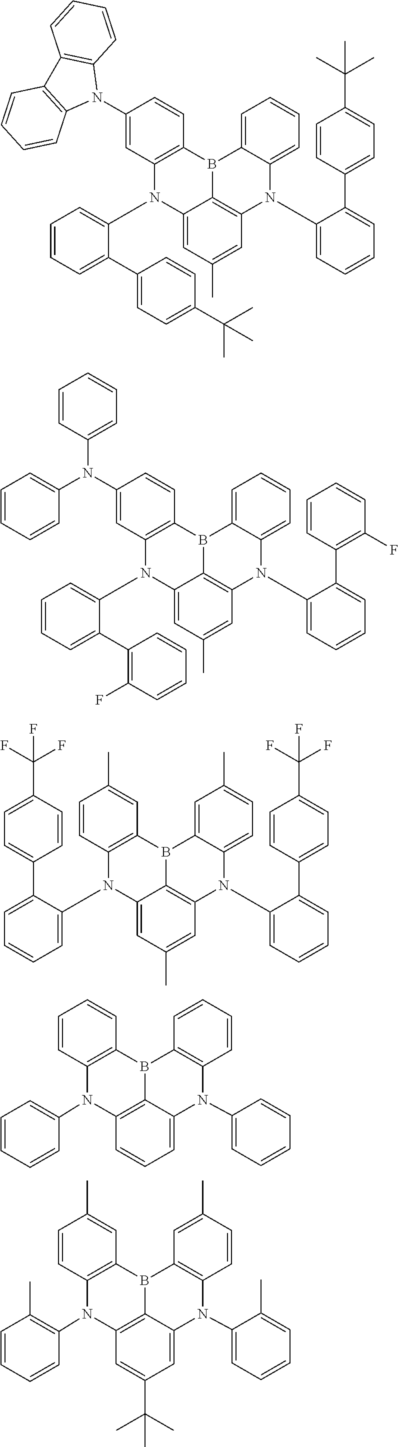

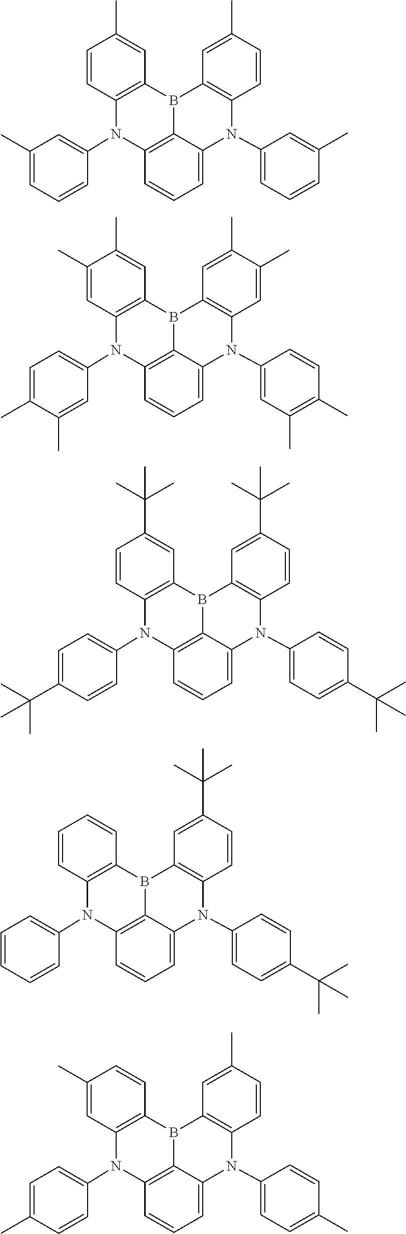

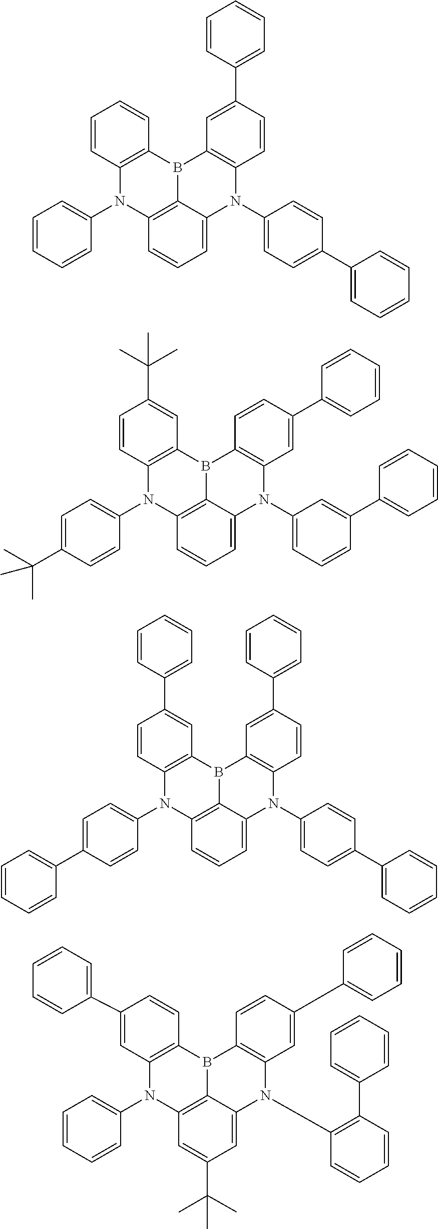

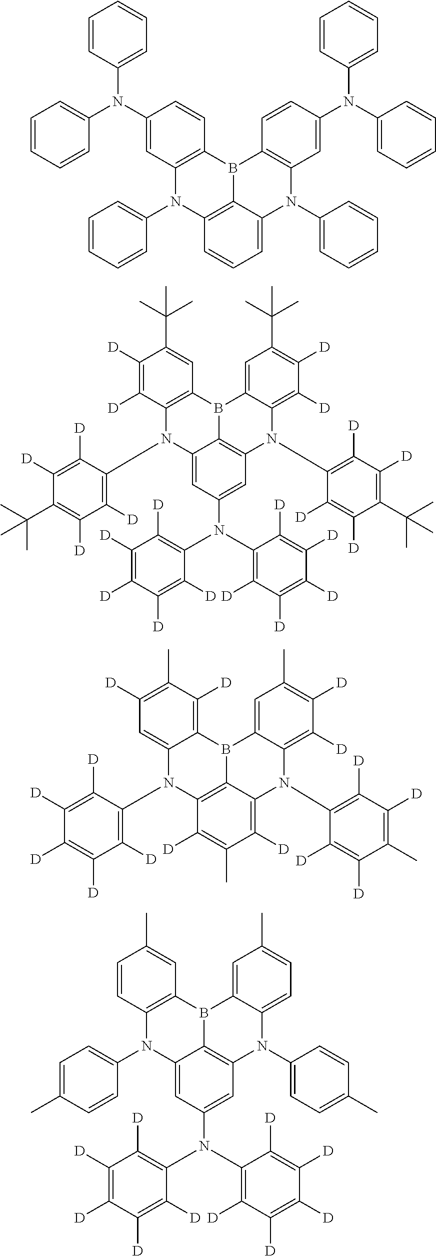

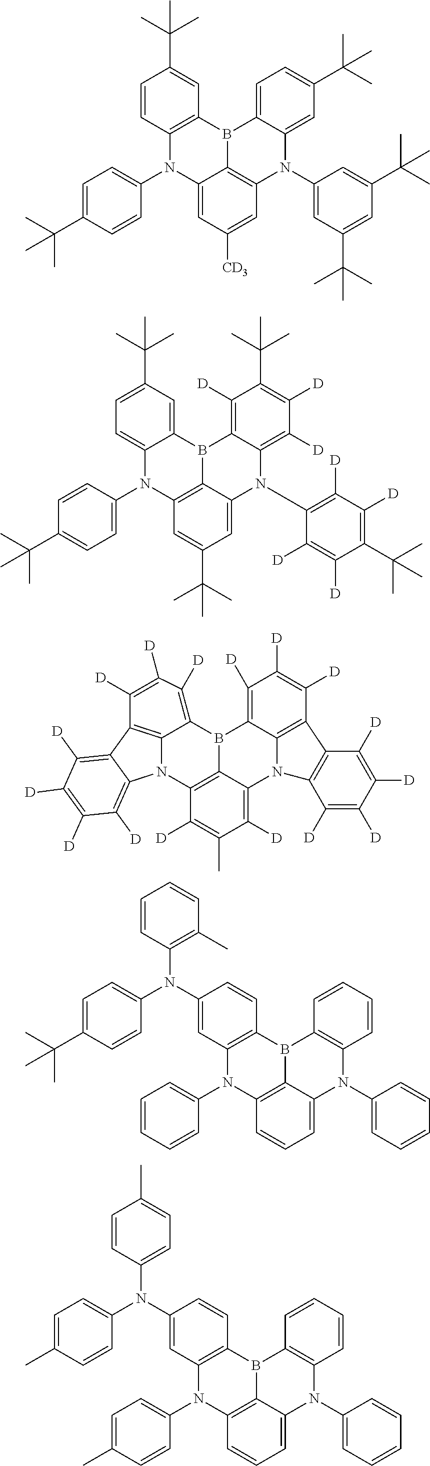

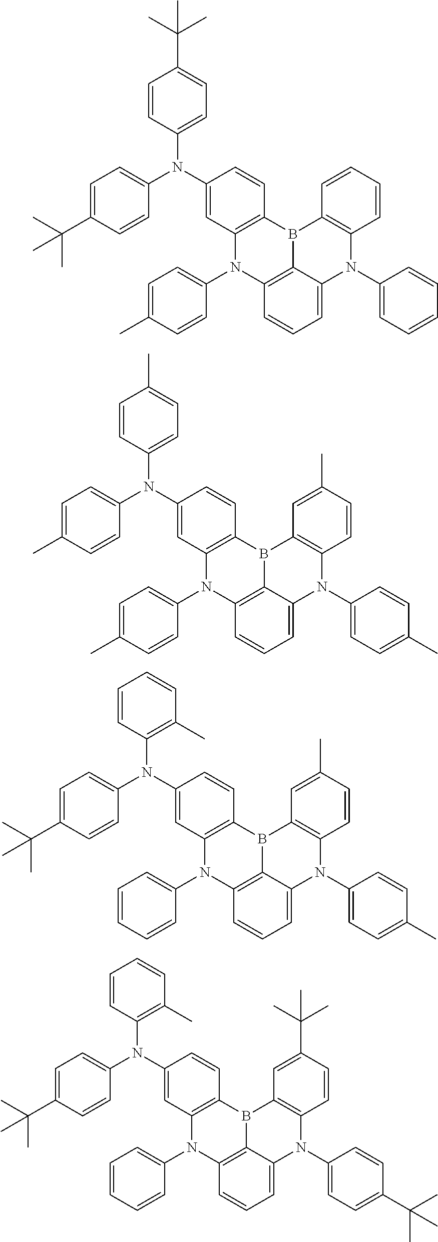

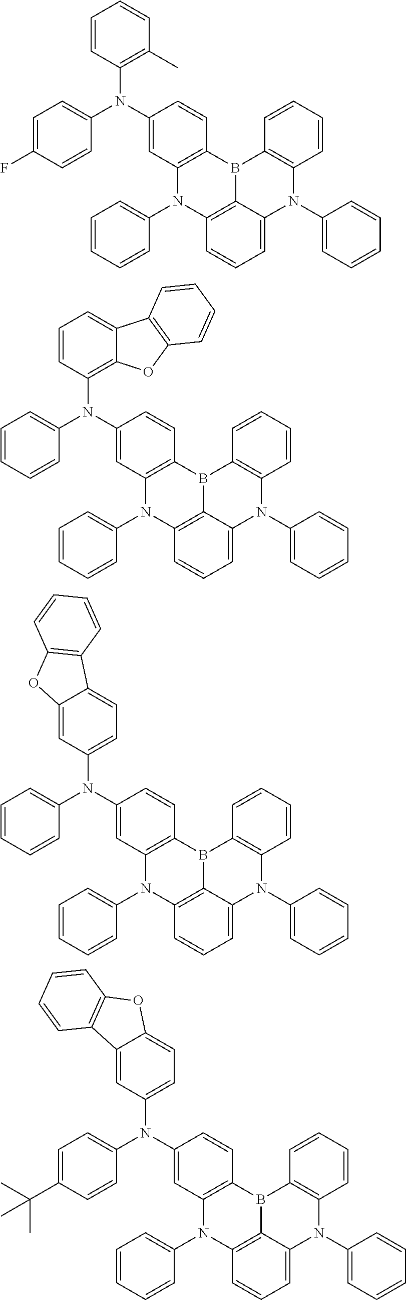

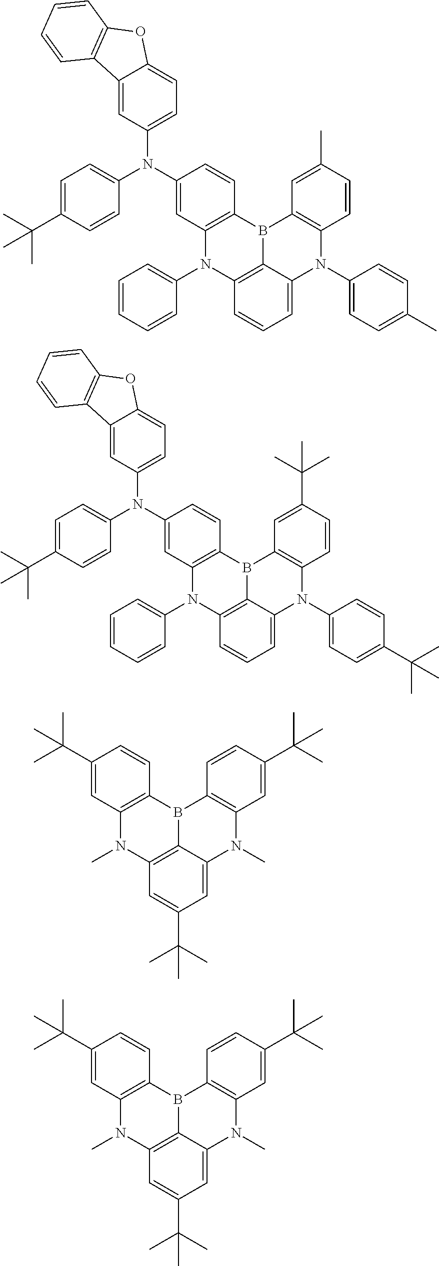

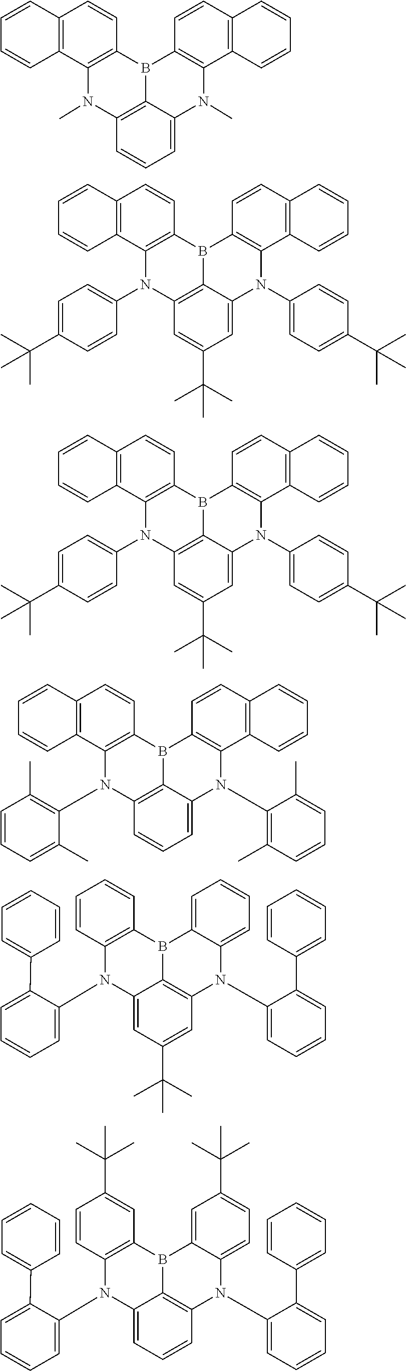

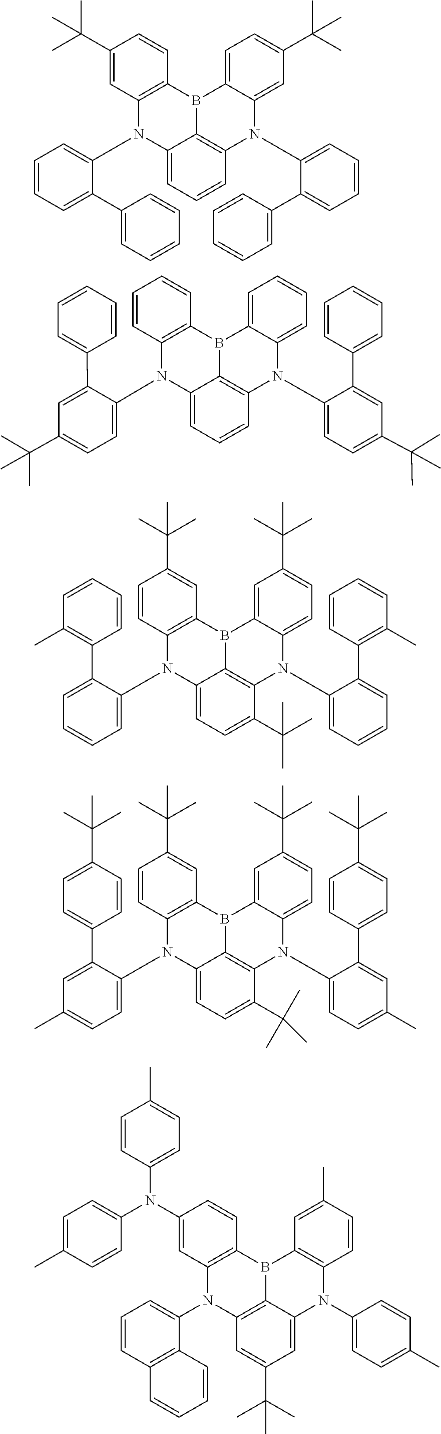

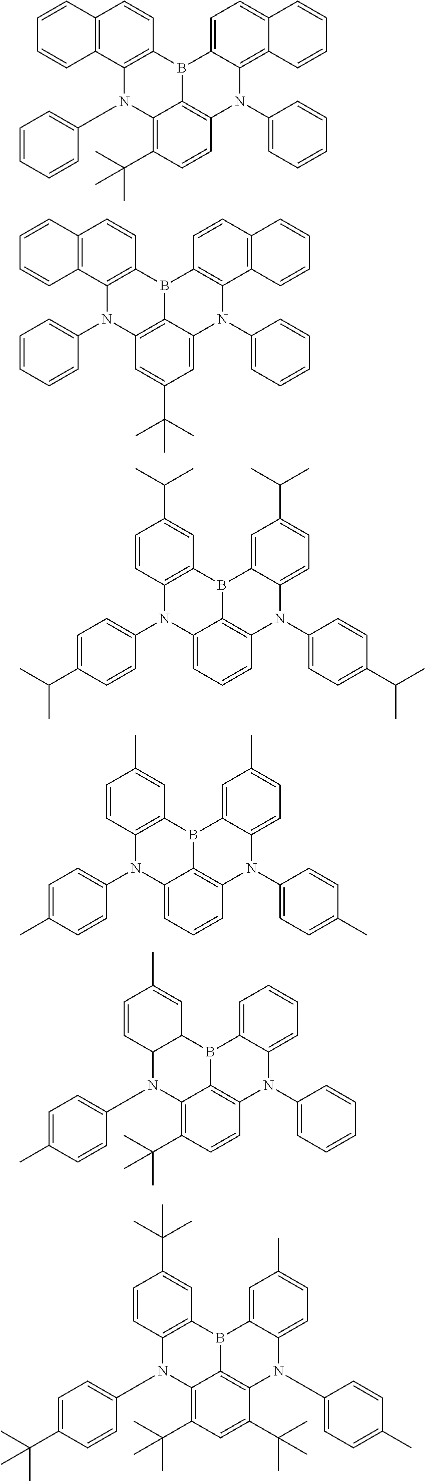

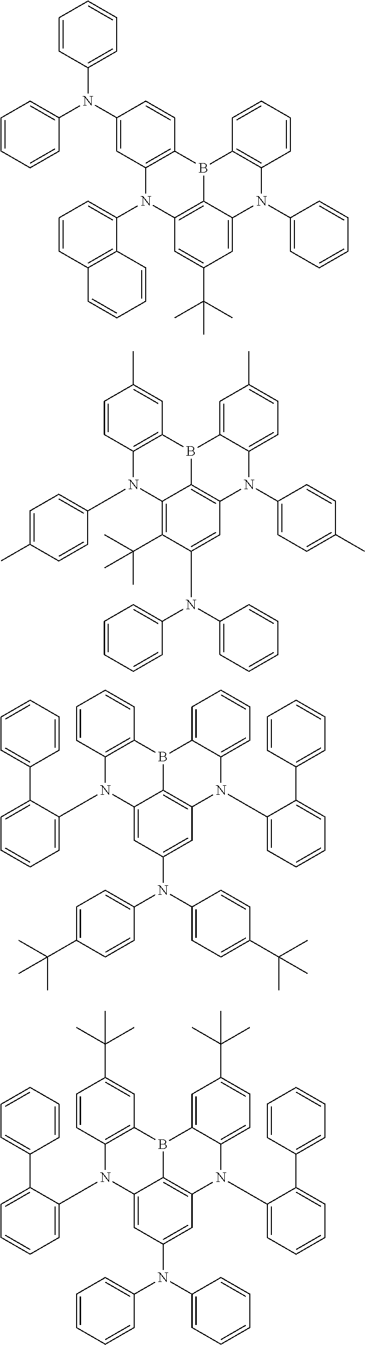

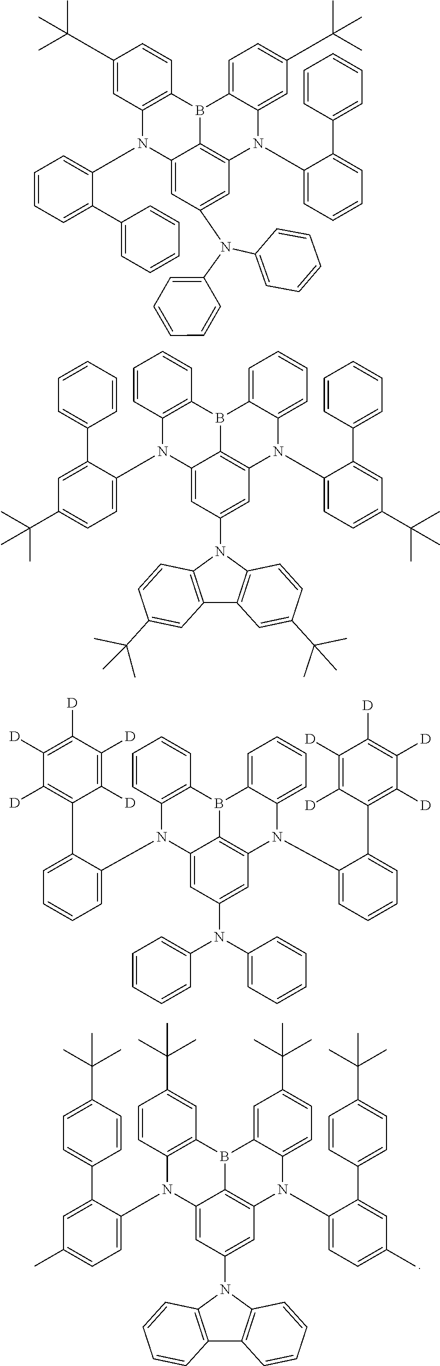

In another embodiment, the first organic material layer can further include other organic compounds, metals or metal compounds in addition to the compound of Chemical Formula 1.

In another embodiment, the second organic material layer can further include other organic compounds, metals or metal compounds in addition to the compound of Chemical Formula 2.

In the organic light emitting device according to one embodiment of the present specification, the light emitting layer further includes a fluorescent dopant or a phosphorescent dopant. Herein, the dopant in the light emitting layer is included in 1 parts by weight to 50 parts by weight with respect to 100 parts by weight of the host.

In the organic light emitting device according to one embodiment of the present specification, the second organic material layer has a maximum light emission peak at 400 nm to 500 nm.

The organic light emitting device of the present specification can further include one or more organic material layers among a hole transfer layer, a hole injection layer, an electron blocking layer, an electron transfer and injection layer, an electron transfer layer, an electron injection layer, a hole blocking layer, and a hole transfer and injection layer.

According to one example, the second organic material layer is provided in contact with the first organic material layer. Herein, being in contact means that no other organic material layers are present between the first organic material layer and the second organic material layer.

In the organic light emitting device of the present disclosure, the organic material layer can include an electron blocking layer, and as the electron blocking layer, materials known in the art can be used.

The organic light emitting device can have, for example, lamination structures as below, however, the structure is not limited thereto.

(1) an anode/a hole transfer layer/a light emitting layer/a cathode

(2) an anode/a hole injection layer/a hole transfer layer/a light emitting layer/a cathode

(3) an anode/a hole injection layer/a hole buffer layer/a hole transfer layer/a light emitting layer/a cathode

(4) an anode/a hole transfer layer/a light emitting layer/an electron transfer layer/a cathode

(5) an anode/a hole transfer layer/a light emitting layer/an electron transfer layer/an electron injection layer/a cathode

(6) an anode/a hole injection layer/a hole transfer layer/a light emitting layer/an electron transfer layer/a cathode

(7) an anode/a hole injection layer/a hole transfer layer/a light emitting layer/an electron transfer layer/an electron injection layer/a cathode

(8) an anode/a hole injection layer/a hole buffer layer/a hole transfer layer/a light emitting layer/an electron transfer layer/a cathode

(9) an anode/a hole injection layer/a hole buffer layer/a hole transfer layer/a light emitting layer/an electron transfer layer/an electron injection layer/a cathode

(10) an anode/a hole transfer layer/an electron blocking layer/a light emitting layer/an electron transfer layer/a cathode

(11) an anode/a hole transfer layer/an electron blocking layer/a light emitting layer/an electron transfer layer/an electron injection layer/a cathode

(12) an anode/a hole injection layer/a hole transfer layer/an electron blocking layer/a light emitting layer/an electron transfer layer/a cathode

(13) an anode/a hole injection layer/a hole transfer layer/an electron blocking layer/a light emitting layer/an electron transfer layer/an electron injection layer/a cathode

(14) an anode/a hole transfer layer/a light emitting layer/a hole blocking layer/an electron transfer layer/a cathode

(15) an anode/a hole transfer layer/a light emitting layer/a hole blocking layer/an electron transfer layer/an electron injection layer/a cathode

(16) an anode/a hole injection layer/a hole transfer layer/a light emitting layer/a hole blocking layer/an electron transfer layer/a cathode

(17) an anode/a hole injection layer/a hole transfer layer/a light emitting layer/a hole blocking layer/an electron transfer layer/an electron injection layer/a cathode

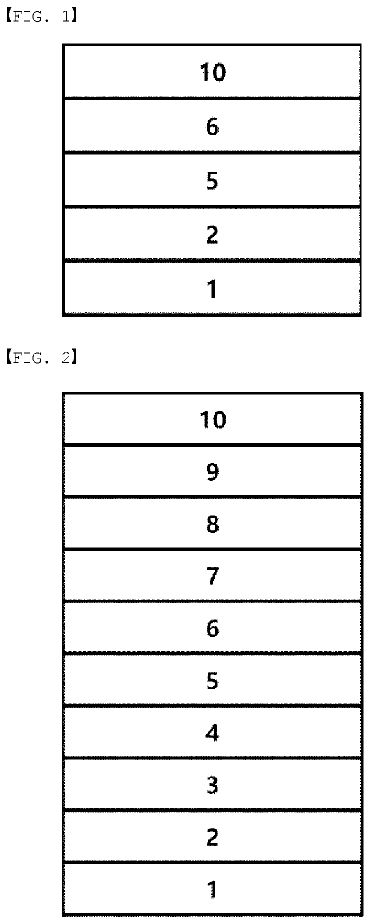

The organic light emitting device of the present specification can have structures as illustrated in FIG. 1 and FIG. 2, however, the structure is not limited thereto.

FIG. 1 illustrates a structure of the organic light emitting device in which a substrate (1), an anode (2), an electron blocking layer (5), a light emitting layer (6) and a cathode (10) are consecutively laminated. In such a structure, the compound of Chemical Formula 1 and the compound of Chemical Formula 2 can be included in the electron blocking layer (5) or the light emitting layer (6).

FIG. 2 illustrates a structure of the organic light emitting device in which a substrate (1), an anode (2), a hole injection layer (3), a hole transfer layer (4), an electron blocking layer (5), a light emitting layer (6), a hole blocking layer (7), an electron transfer layer (8), an electron injection layer (9) and a cathode (10) are consecutively laminated. In such a structure, the compound of Chemical Formula 1 and the compound of Chemical Formula 2 can be included in the hole injection layer (3), the hole transfer layer (4), the electron blocking layer (5), the light emitting layer (6), the hole blocking layer (7), the electron transfer layer (8) or the electron injection layer (9).

For example, the organic light emitting device according to the present specification can be manufactured by forming an anode on a substrate by depositing a metal, a metal oxide having conductivity, or an alloy thereof using a physical vapor deposition (PVD) method such as sputtering or e-beam evaporation, forming an organic material layer including a hole injection layer, a hole transfer layer, a light emitting layer, an electron blocking layer, an electron transfer layer and an electron injection layer, and then depositing a material usable as a cathode thereon. In addition to such a method, the organic light emitting device can also be manufactured by consecutively depositing a cathode material, an organic material layer and an anode material on a substrate.

The organic material layer can further include one or more of a hole transfer layer, a hole injection layer, an electron blocking layer, an electron transfer and injection layer, an electron transfer layer, an electron injection layer, a hole blocking layer, and a hole transfer and injection layer.

The organic material layer can have a multilayer structure including a hole injection layer, a hole transfer layer, a hole injection and transfer layer, an electron blocking layer, a light emitting layer, an electron transfer layer, an electron injection layer, an electron transfer and injection layer and the like, but is not limited thereto, and can have a single layer structure. In addition, using various polymer materials, the organic material layer can be prepared to a smaller number of layers using a solvent process instead of a deposition method, for example, spin coating, dip coating, doctor blading, screen printing, inkjet printing, a thermal transfer method or the like.

The anode is an electrode injecting holes, and as the anode material, materials having large work function are normally preferred so that hole injection to an organic material layer is smooth. Specific examples of the anode material usable in the present disclosure include metals such as vanadium, chromium, copper, zinc and gold, or alloys thereof; metal oxides such as zinc oxide, indium oxide, indium tin oxide (ITO) and indium zinc oxide (IZO); combinations of metals and oxides such as ZnO:Al or SnO₂:Sb; conductive polymers such as poly(3-methylthiophene), poly[3, 4-(ethylene-1,2-dioxy)thiophene] (PEDOT), polypyrrole and polyaniline, but are not limited thereto.

The cathode is an electrode injecting electrons, and as the cathode material, materials having small work function are normally preferred so that electron injection to an organic material layer is smooth. Specific examples of the cathode material include metals such as magnesium, calcium, sodium, potassium, titanium, indium, yttrium, lithium, gadolinium, aluminum, silver, tin and lead, or alloys thereof; multilayer structure materials such as LiF/Al or LiO₂/Al, and the like, but are not limited thereto.

The hole injection layer is a layer performing a role of smoothly injecting holes from an anode to a light emitting layer, and the hole injection material is a material capable of favorably receiving holes from an anode at a low voltage. The highest occupied molecular orbital (HOMO) of the hole injection material is preferably in between the work function of an anode material and the HOMO of surrounding organic material layers. Specific examples of the hole injection material include metal porphyrins, oligothiophene, arylamine-based organic materials, hexanitrile hexaazatriphenylene-based organic materials, quinacridone-based organic materials, perylene-based organic materials, anthraquinone, and polyaniline- and polythiophene-based conductive polymers, and the like, but are not limited thereto. The hole injection layer can have a thickness of 1 nm to 150 nm. The hole injection layer having a thickness of 1 nm or greater has an advantage of preventing hole injection properties from declining, and the thickness being 150 nm or less has an advantage of preventing a driving voltage from increasing to enhance hole migration caused by the hole injection layer being too thick.

The hole transfer layer can perform a role of smoothly transferring holes. As the hole transfer material, materials capable of receiving holes from an anode or a hole injection layer, moving the holes to a light emitting layer, and having high mobility for the holes are suited. Specific examples thereof include arylamine-based organic materials, conductive polymers, block copolymers having conjugated parts and non-conjugated parts together, and the like, but are not limited thereto.

Between the hole injection layer and the hole transfer layer, a hole buffer layer can be additionally provided, and hole injection or transfer materials known in the art can be included.

An electron blocking layer can be provided between the hole transfer layer and a light emitting layer. As the electron blocking layer, the above-described compounds or materials known in the art can be used.

The light emitting layer can emit red, green or blue, and can be formed with a phosphorescence material or a fluorescence material. The light emitting material is a material capable of emitting light in a visible region by receiving holes and electrons from a hole transfer layer and an electron transfer layer, respectively, and binding the holes and the electrons, and is preferably a material having favorable quantum efficiency for fluorescence or phosphorescence. Specific examples thereof include 8-hydroxy-quinoline aluminum complexes (Alq₃); carbazole-based compounds; dimerized styryl compounds; BAlq; 10-hydroxybenzoquinoline-metal compounds; benzoxazole-, benzothiazole- and benzimidazole-based compounds; poly(p-phenylenevinylene) (PPV)-based polymers; spiro compounds; polyfluorene, rubrene, and the like, but are not limited thereto.

A host material of the light emitting layer can include fused aromatic ring derivatives, heteroring-containing compounds or the like. Specifically, as the fused aromatic ring derivative, anthracene derivatives, pyrene derivatives, naphthalene derivatives, pentacene derivatives, phenanthrene compounds, fluoranthene compounds and the like can be included, and as the heteroring-containing compound, carbazole derivatives, dibenzofuran derivatives, ladder-type furan compounds, pyrimidine derivatives and the like can be included, however, the host material is not limited thereto.

When the light emitting layer emits red light, phosphorescence materials such as bis(1-phenylisoquinoline) acetylacetonate iridium (PIQIr (acac)), bis(1-phenylquinoline) acetylacetonate iridium (PQIr (acac)), tris(1-phenylquinoline) iridium (PQIr) or octaethylporphyrin platinum (PtOEP), or fluorescence materials such as tris(8-hydroxyquinolino)aluminum (Alq₃) can be used as the light emitting dopant, however, the light emitting dopant is not limited thereto. When the light emitting layer emits green light, phosphorescence materials such as fac-tris(2-phenylpyridine)iridium (Ir(ppy)₃), or fluorescence materials such as tris(8-hydroxyquinolino)aluminum (Alq₃), anthracene-based compounds, pyrene-based compounds or boron-based compounds can be used as the light emitting dopant, however, the light emitting dopant is not limited thereto. When the light emitting layer emits blue light, phosphorescence materials such as (4,6-F₂ppy)₂Irpic, or fluorescence materials such as spiro-DPVBi, spiro-6P, distyrylbenzene (DSB), distyrylarylene (DSA), PFO-based polymers, PPV-based polymers, anthracene-based compounds, pyrene-based compounds or boron-based compounds can be used as the light emitting dopant, however, the light emitting dopant is not limited thereto.

A hole blocking layer can be provided between an electron transfer layer and the light emitting layer, and materials known in the art can be used.

The electron transfer layer can perform a role of smoothly transferring electrons. As the electron transfer material, materials capable of favorably receiving electrons from a cathode, moving the electrons to a light emitting layer, and having high mobility for the electrons are suited. Specific examples thereof include the above-described compounds or Al complexes of 8-hydroxyquinoline; complexes including Alq₃; organic radical compounds; hydroxyflavon-metal complexes, and the like, but are not limited thereto. The electron transfer layer can have a thickness of 1 nm to 50 nm. The electron transfer layer having a thickness of 1 nm or greater has an advantage of preventing electron transfer properties from declining, and the thickness being 50 nm or less has an advantage of preventing a driving voltage from increasing to enhance electron migration caused by the electron transfer layer being too thick.

The electron injection layer can perform a role of smoothly injecting electrons. As the electron injection material, compounds having an electron transferring ability, having an electron injection effect from a cathode, having an excellent electron injection effect for a light emitting layer or light emitting material, and preventing excitons generated in the light emitting layer from moving to a hole injection layer, and, in addition thereto, having an excellent thin film forming ability are preferred. Specific examples thereof can include fluorenone, anthraquinodimethane, diphenoquinone, thiopyran dioxide, oxazole, oxadiazole, triazole, imidazole, perylene tetracarboxylic acid, fluorenylidene methane, anthrone or the like, and derivatives thereof, metal complex compounds, nitrogen-containing 5-membered ring derivatives, and the like, but are not limited thereto.

The metal complex compound includes 8-hydroxyquinolinato lithium, bis(8-hydroxyquinolinato) zinc, bis(8-hydroxy-quinolinato)copper, bis(8-hydroxyquinolinato)-manganese, tris(8-hydroxyquinolinato)aluminum, tris(2-methyl-8-hydroxy-quinolinato)aluminum, tris(8-hydroxyquinolinato)-gallium, bis(10-hydroxybenzo[h]quinolinato)beryllium, bis(10-hydroxybenzo[h]-quinolinato)zinc, bis(2-methyl-8-quinolinato)chlorogallium, bis(2-methyl-8-quinolinato) (o-cresolato)gallium, bis(2-methyl-8-quinolinato) (1-naphtholato)aluminum, bis(2-methyl-8-quinolinato)-(2-naphtholato)gallium and the like, but is not limited thereto.

The hole blocking layer is a layer blocking holes from reaching a cathode, and can be generally formed under the same condition as the hole injection layer. Specific examples thereof can include oxadiazole derivatives, triazole derivatives, phenanthroline derivatives, BCP, aluminum complexes and the like, but are not limited thereto.

The organic light emitting device according to the present disclosure can be a top-emission type, a bottom-emission type or a dual-emission type depending on the materials used.

### EXAMPLES

Hereinafter, the present specification will be described in detail with reference to examples. However, the examples according to the present specification can be modified to various other forms, and the scope of the present application is not to be construed as being limited to the examples described below. Examples of the present application are provided in order to more fully describe the present specification to those having average knowledge in the art.

### Synthesis Example

### Preparation Example 1: Preparation of Compound BH-1

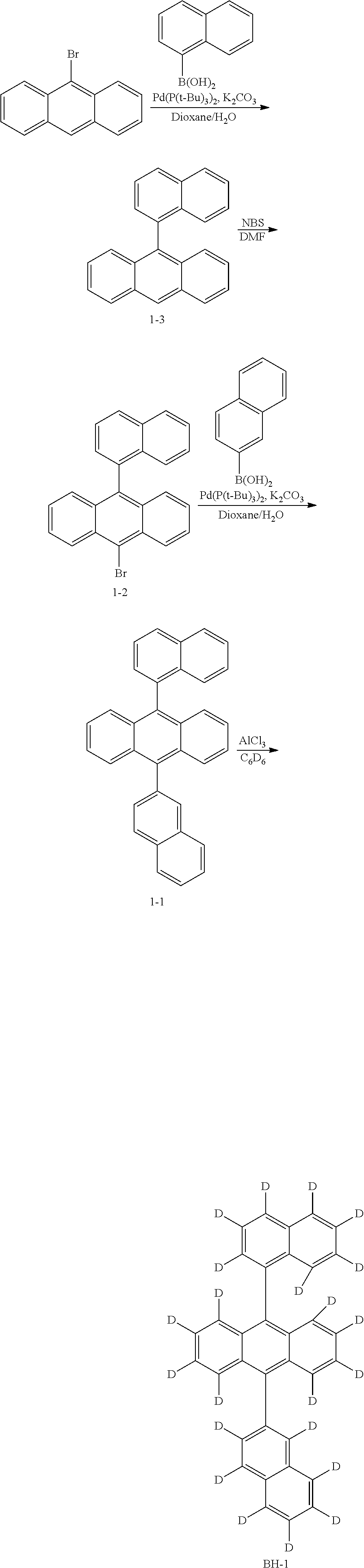

### (Preparation Example 1-1) Preparation of Compound 1-3

In a 3-neck flask, 9-bromoanthracene (50.0 g, 194 mmol) and naphthalene-1-boronic acid (36.79 g, 214 mmol) were dissolved in 1,4-dioxane (500 ml), and K₂CO₃ (80.6 g, 583 mmol) dissolved in H₂O (200 ml) was introduced thereto. Pd(P(t-Bu)₃)₂ (1.98 g, 3.9 mmol) was introduced thereto, and the result was stirred for 5 hours under an argon atmosphere reflux condition. When the reaction was finished, the reaction solution was cooled to room temperature, then transferred to a separatory funnel, and extracted with water and toluene. The extract was dried with MgSO₄, then filtered and concentrated, and the sample was purified by silica gel column chromatography to obtain Compound 1-3 (49.8 g). (Yield 84%, MS[M+H]+=305)

### (Preparation Example 1-2) Preparation of Compound 1-2

In a 2-neck flask, Compound 1-3 (20.0 g, 65.7 mmol), N-bromosuccinimide (NBS) (11.8 g, 65.7 nmol) and dimethylformamide (DMF) (300 ml) were introduced, and stirred for 10 hours at room temperature under the argon atmosphere. After the reaction was finished, the reaction solution was transferred to a separatory funnel, and the organic layer was extracted with water and ethyl acetate. The extract was dried with MgSO₄, then filtered and concentrated, and the sample was purified by silica gel column chromatography to obtain Compound 1-2 (18.5 g). (Yield 74%, MS[M+H]+=383)

### (Preparation Example 1-3) Preparation of Compound 1-1

In a 3-neck flask, Compound 1-2 (20.0 g, 52.2 mmol) and naphthalene-2-boronic acid (9.9 g, 57.4 mmol) were dissolved in 1,4-dioxane (300 ml), and K₂CO₃ (14.4 g, 104 mmol) dissolved in H₂O (100 ml) was introduced thereto. Pd(P(t-Bu)₃)₂ (0.27 g, 0.52 mmol) was introduced thereto, and the result was stirred for 5 hours under an argon atmosphere reflux condition. When the reaction was finished, the reaction solution was cooled to room temperature, then transferred to a separatory funnel, and extracted with water and toluene. The extract was dried with MgSO₄, then filtered and concentrated, and the sample was purified by silica gel column chromatography to obtain Compound 1-1 (11.9 g). (Yield 52%, MS[M+H]+=431)

### (Preparation Example 1-4) Synthesis of Compound BH-1

Compound 1-1 (20 g) and AlCl₃ (4 g) were introduced to C₆D₆ (300 ml), and the result was stirred for 2 hours. After the reaction was finished, D₂O (50 ml) was introduced thereto, and after stirring the result for 30 minutes, trimethylamine (6 ml) was added dropwise thereto. The reaction solution was transferred to a separatory funnel, and extracted with water and toluene. The extract was dried with MgSO₄, and then recrystallized with ethyl acetate to obtain Compound BH-1 (15.2 g). (Yield 72%, MS[M+H]+=452)

### Preparation Example 2: Preparation of Compound BH-2

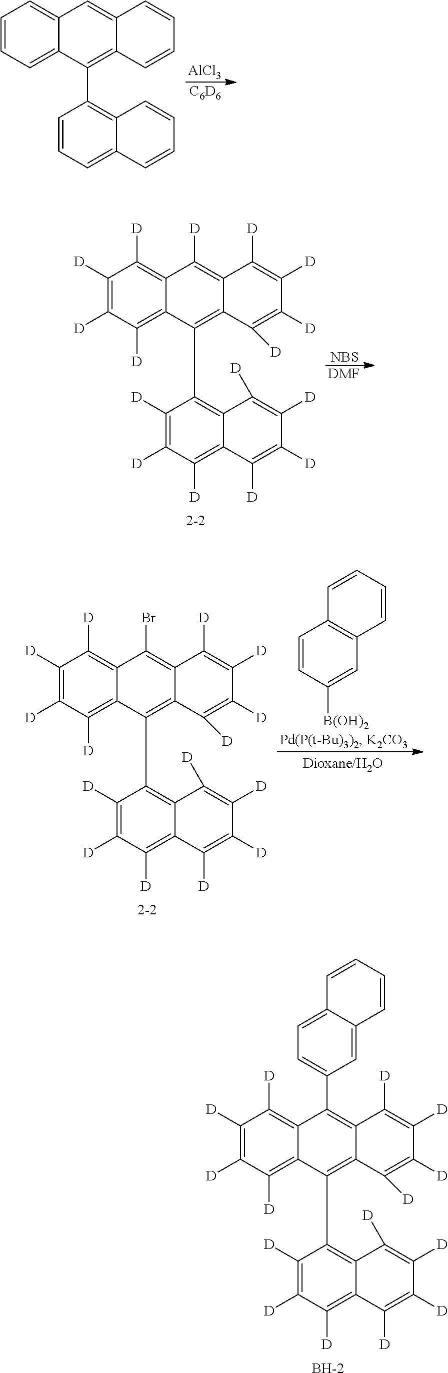

### (Preparation Example 2-1) Preparation of Compound 2-2

Compound 2-2 (13.3 g) was obtained by conducting synthesis in the same manner as in Preparation Example 1-4 except that 9-(naphthalen-1-yl)anthracene was used instead of Compound 1-1. (Yield 63%, MS[M+H]+=321)

### (Preparation Example 2-2) Preparation of Compound 2-1

Compound 2-1 (17.4 g) was obtained by conducting synthesis in the same manner as in Preparation Example 1-2 except that Compound 2-2 was used instead of Compound 1-3. (Yield 70%, MS[M+H]+=398)

### (Preparation Example 2-3) Preparation of Compound BH-2

Compound BH-2 (10.0 g) was obtained by conducting synthesis in the same manner as in Preparation Example 1-3 except that Compound 2-1 was used instead of Compound 1-2. (Yield 45%, MS[M+H]+=446)

### Preparation Example 3: Preparation of Compound BH-3

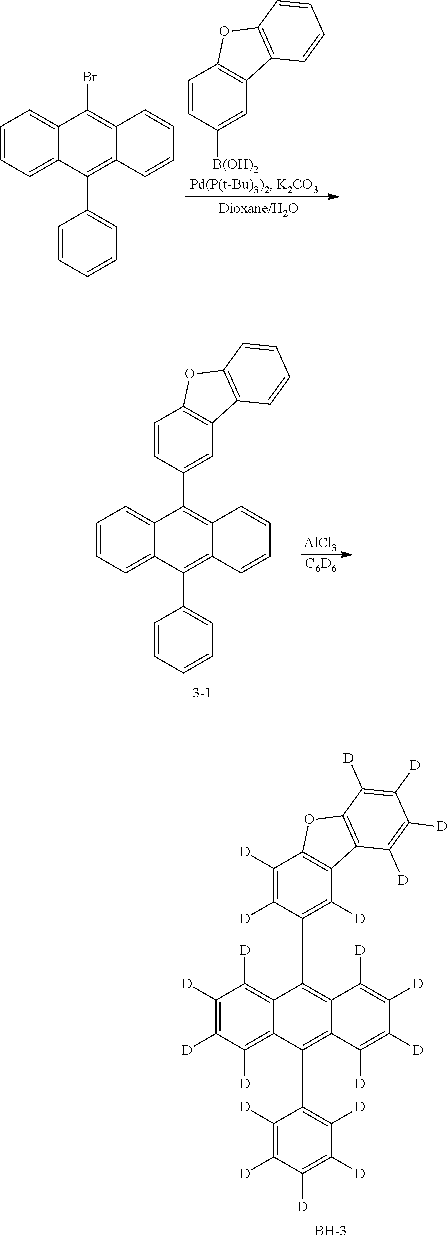

### (Preparation Example 3-1) Preparation of Compound 3-1

In a 3-neck flask, 9-bromo-10-phenylanthracene (20.0 g, 60.2 mmol) and dibenzofuran-2-boronic acid (14.0 g, 66.2 mmol) were dissolved in 1,4-dioxane (300 ml), and K₂CO₃ (16.6 g, 120 mmol) dissolved in H₂O (100 ml) was introduced thereto. Pd(P(t-Bu)₃)₂ (0.31 g, 0.60 mmol) was introduced thereto, and the result was stirred for 5 hours under an argon atmosphere reflux condition. When the reaction was finished, the reaction solution was cooled to room temperature, then transferred to a separatory funnel, and extracted with water and toluene. The extract was dried with MgSO₄, then filtered and concentrated, and the sample was purified by silica gel column chromatography to obtain Compound 3-1 (14.4 g). (Yield 57%, MS[M+H]+=421)

### (Preparation Example 3-2) Preparation of Compound BH-3

Compound BH-3 (15.9 g) was obtained by conducting synthesis in the same manner as in Preparation Example 1-4 except that Compound 3-1 was used instead of Compound 1-1. (Yield 76%, MS[M+H]+=441)

### Preparation Example 4: Preparation of Compound BH-4

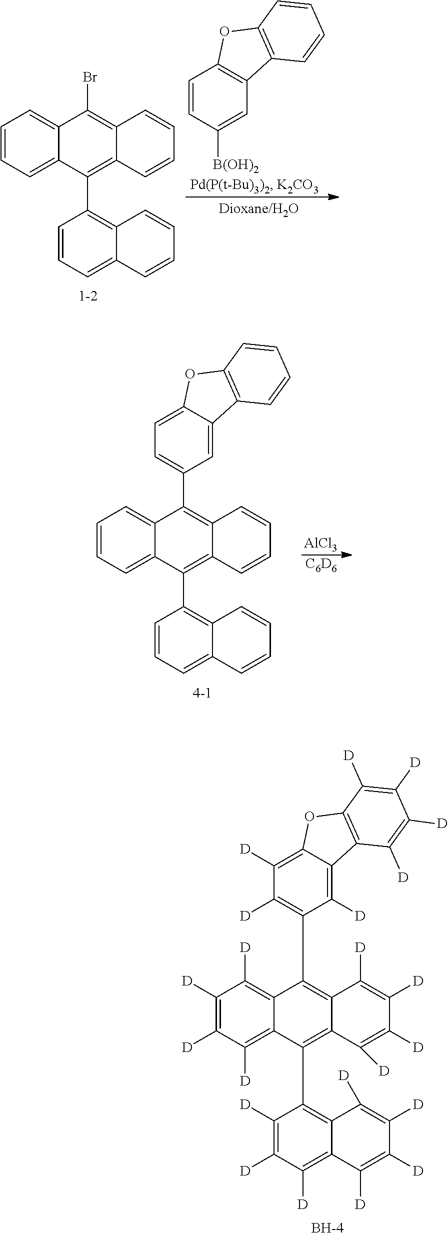

### (Preparation Example 4-1) Preparation of Compound 4-1

Compound 4-1 (12.3 g) was obtained by conducting synthesis in the same manner as in Preparation Example 3-1 except that Compound 1-2 was used instead of 9-bromo-10-phenylanthracene. (Yield 55%, MS[M+H]+=471)

### (Preparation Example 4-2) Preparation of Compound BH-4

Compound BH-4 (16.6 g) was obtained by conducting synthesis in the same manner as in Preparation Example 1-4 except that Compound 4-1 was used instead of Compound 1-1. (Yield 79%, MS[M+H]+=493)

### Preparation Example 5: Preparation of Compound BH-5

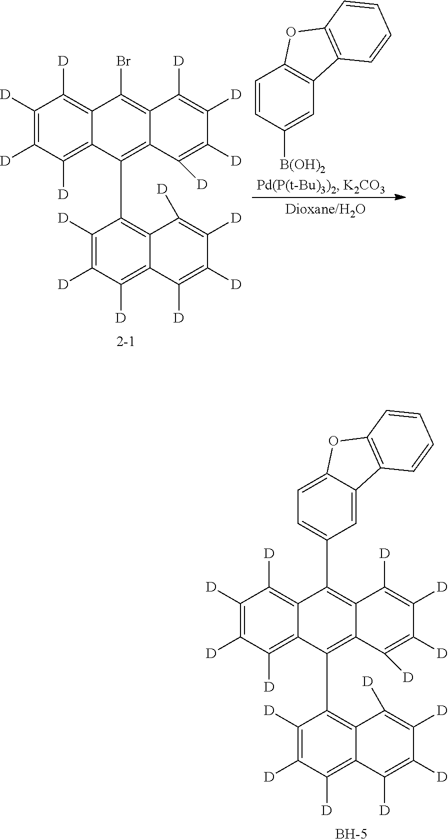

Compound BH-5 (11.8 g) was obtained by conducting synthesis in the same manner as in Preparation Example 4-1 except that Compound 2-1 was used instead of Compound 1-2. (Yield 48%, MS[M+H]+=486)

### Preparation Example 6: Preparation of Compound BH-6

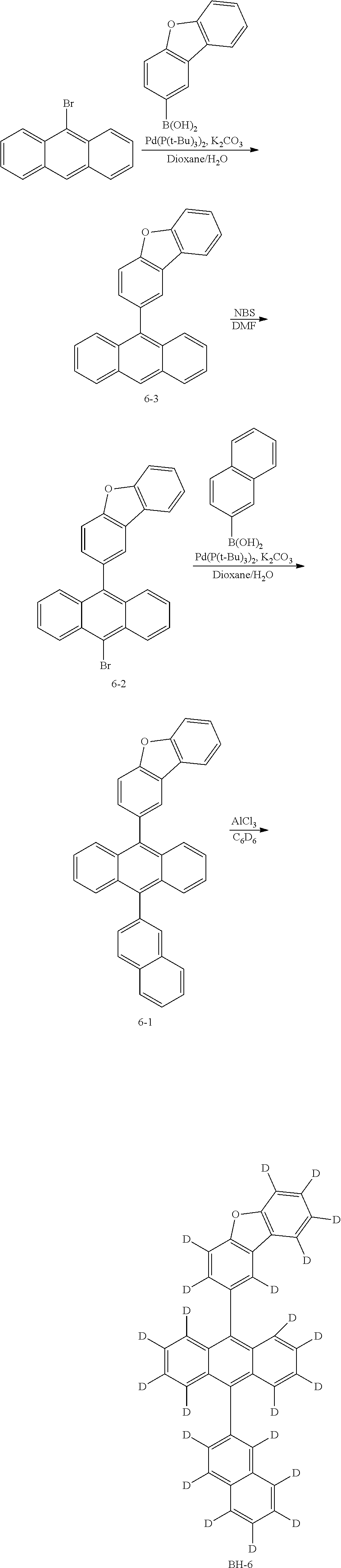

### (Preparation Example 6-1) Preparation of Compound 6-3

Compound 6-3 (21.1 g) was obtained by conducting synthesis in the same manner as in Preparation Example 1-1 except that dibenzofuran-2-boronic acid was used instead of naphthalene-1-boronic acid. (Yield 79%, MS[M+H]+=345)

### (Preparation Example 6-2) Preparation of Compound 6-2

Compound 6-2 (18.2 g) was obtained by conducting synthesis in the same manner as in Preparation Example 1-2 except that Compound 6-3 was used instead of Compound 1-3. (Yield 72%, MS[M+H]+=433)

### (Preparation Example 6-3) Preparation of Compound 6-1

Compound 6-1 (13.5 g) was obtained by conducting synthesis in the same manner as in Preparation Example 1-3 except that Compound 6-2 was used instead of Compound 1-2. (Yield 62%, MS[M+H]+=471)

### (Preparation Example 6-4) Preparation of Compound BH-6

Compound BH-6 (15.4 g) was obtained by conducting synthesis in the same manner as in Preparation Example 1-4 except that Compound 6-1 was used instead of Compound 1-1. (Yield 73%, MS[M+H]+=493)

### Preparation Example 7: Preparation of Compound BH-7

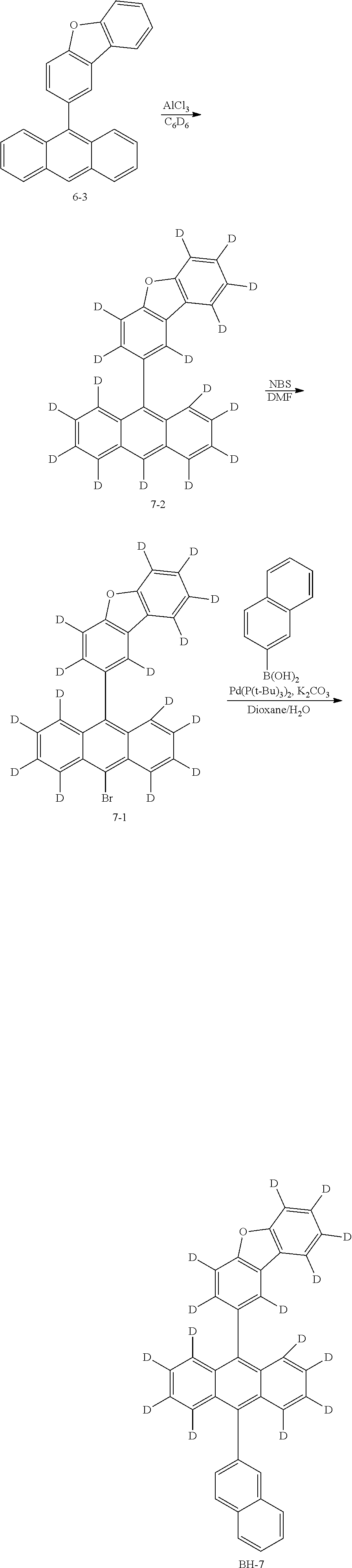

### (Preparation Example 7-1) Preparation of Compound 7-2

Compound 7-2 (17.1 g) was obtained by conducting synthesis in the same manner as in Preparation Example 1-4 except that Compound 6-3 was used instead of Compound 1-1. (Yield 82%, MS[M+H]+=361)

### (Preparation Example 7-2) Preparation of Compound 7-1

Compound 7-1 (16.3 g) was obtained by conducting synthesis in the same manner as in Preparation Example 1-2 except that Compound 7-2 was used instead of Compound 1-3. (Yield 67%, MS[M+H]+=439)

### (Preparation Example 7-3) Preparation of Compound BH-7

Compound BH-7 (10.9 g) was obtained by conducting synthesis in the same manner as in Preparation Example 1-3 except that Compound 7-1 was used instead of Compound 1-2. (Yield 49%, MS[M+H]+=486)

### Preparation Example 8: Preparation of Compound BH-8

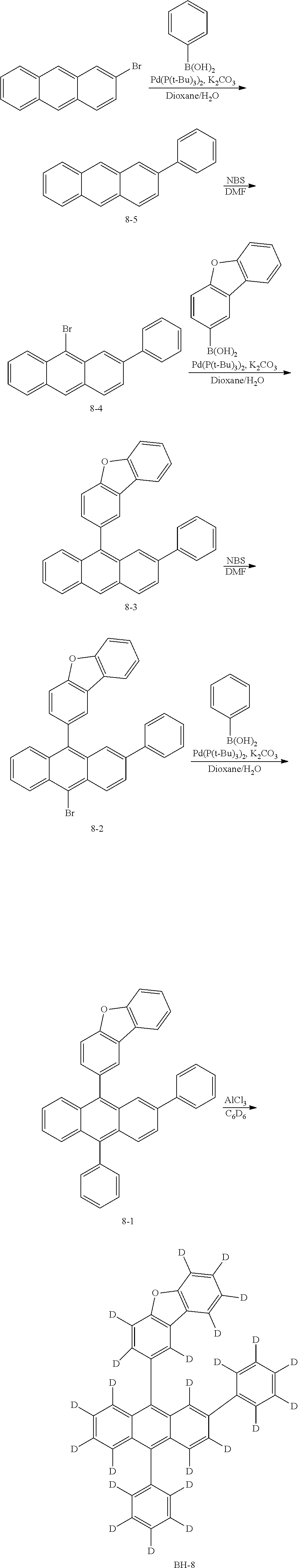

### (Preparation Example 8-1) Preparation of Compound 8-5

In a 3-neck flask, 2-bromoanthracene (50.0 g, 194 mmol) and phenylboronic acid (26.1 g, 214 mmol) were dissolved in 1,4-dioxane (500 ml), and K₂CO₃ (53.8 g, 389 mmol) dissolved in H₂O (200 ml) was introduced thereto. Pd(P(t-Bu)₃)₂ (0.99 g, 1.9 mmol) was introduced thereto, and the result was stirred for 5 hours under an argon atmosphere reflux condition. When the reaction was finished, the reaction solution was cooled to room temperature, then transferred to a separatory funnel, and extracted with water and toluene. The extract was dried with MgSO₄, then filtered and concentrated, and the sample was purified by silica gel column chromatography to obtain Compound 8-5 (48.4 g). (Yield 98%, MS[M+H]+=255)

### (Preparation Example 8-2) Preparation of Compound 8-4

Compound 8-4 (23.1 g) was obtained by conducting synthesis in the same manner as in Preparation Example 1-2 except that Compound 8-5 was used instead of Compound 1-3. (Yield 88%, MS[M+H]+=334)

### (Preparation Example 8-3) Preparation of Compound 8-3

Compound 8-3 (22.6 g) was obtained by conducting synthesis in the same manner as in Preparation Example 6-1 except that Compound 8-4 was used instead of 9-bromoanthracene. (Yield 90%, MS[M+H]+=421)

### (Preparation Example 8-4) Preparation of Compound 8-2

Compound 8-2 (19.2 g) was obtained by conducting synthesis in the same manner as in Preparation Example 1-2 except that Compound 8-3 was used instead of Compound 1-3. (Yield 81%, MS[M+H]+=500)

### (Preparation Example 8-5) Preparation of Compound 8-1

Compound 8-1 (14.0 g) was obtained by conducting synthesis in the same manner as in Preparation Example 1-3 except that Compound 8-2 was used instead of Compound 1-2, and phenylboronic acid was used instead of naphthalene-2-boronic acid. (Yield 70%, MS[M+H]+=497)

### (Preparation Example 8-6) Preparation of Compound BH-8

Compound BH-8 (13.2 g) was obtained by conducting synthesis in the same manner as in Preparation Example 1-4 except that Compound 8-1 was used instead of Compound 1-1. (Yield 63%, MS[M+H]+=520)

### Preparation Example 9: Preparation of Compound BH-9

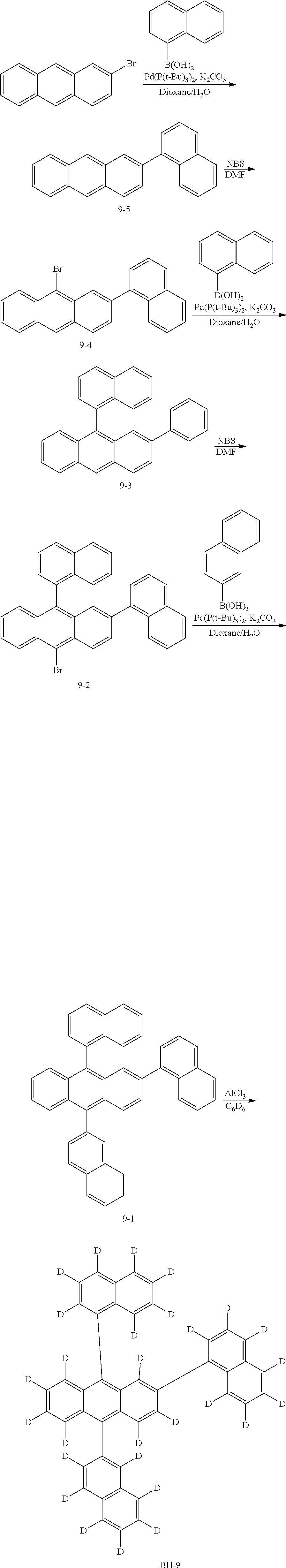

### (Preparation Example 9-1) Preparation of Compound 9-5

Compound 9-5 (20.6 g) was obtained by conducting synthesis in the same manner as in Preparation Example 8-1 except that naphthalene-1-boronic acid was used instead of phenylboronic acid. (Yield 87%, MS[M+H]+=305)

### (Preparation Example 9-2) Preparation of Compound 9-4

Compound 9-4 (17.2 g) was obtained by conducting synthesis in the same manner as in Preparation Example 1-2 except that Compound 9-5 was used instead of Compound 1-3. (Yield 68%, MS[M+H]+=384)

### (Preparation Example 9-3) Preparation of Compound 9-3

Compound 9-3 (19.1 g) was obtained by conducting synthesis in the same manner as in Preparation Example 1-1 except that Compound 9-4 was used instead of 9-bromoanthracene. (Yield 85%, MS[M+H]+=431)

### (Preparation Example 9-4) Preparation of Compound 9-2

Compound 9-2 (18.4 g) was obtained by conducting synthesis in the same manner as in Preparation Example 1-2 except that Compound 9-3 was used instead of Compound 1-3. (Yield 78%, MS[M+H]+=510)

### (Preparation Example 9-5) Preparation of Compound 9-1

Compound 9-1 (11.4 g) was obtained by conducting synthesis in the same manner as in Preparation Example 1-3 except that Compound 9-2 was used instead of Compound 1-2. (Yield 52%, MS[M+H]+=557)

### (Preparation Example 9-6) Preparation of Compound BH-9

Compound BH-9 (17.2 g) was obtained by conducting synthesis in the same manner as in Preparation Example 1-4 except that Compound 9-1 was used instead of Compound 1-1. (Yield 82%, MS[M+H]+=585)

### Preparation Example 10: Preparation of Compound HT-1

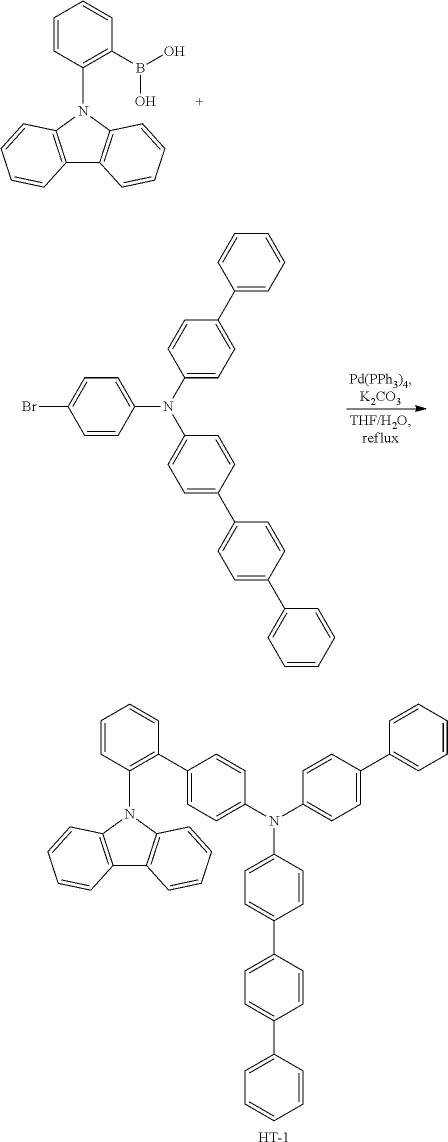

After completely dissolving compounds N-([1,1′-biphenyl]-4-yl)-N-(4-bromophenyl)-[1,1′:4′,1″-terphenyl]-4-amine (6.74 g, 12.23 mmol) and (2-(9H-carbazol-9-yl)phenyl)boronic acid (4.04 g, 14.07 mmol) in tetrahydrofuran (240 ml) in a 500 ml round bottom flask under the nitrogen atmosphere, a 2 M aqueous potassium carbonate solution (120 ml) was added thereto, and after introducing tetrakis-(triphenylphosphine)palladium (0.42 g, 0.37 mmol) thereto, the result was stirred for 3 hours while heating. After lowering the temperature to room temperature, the water layer was removed, and the result was dried with anhydrous magnesium sulfate, then vacuum concentrated, and recrystallized with ethyl acetate (240 ml) to prepare Compound HT-1 (6.11 g, 70%).

MS [M+H]₊=715

### Preparation Example 11: Preparation of Compound HT-2

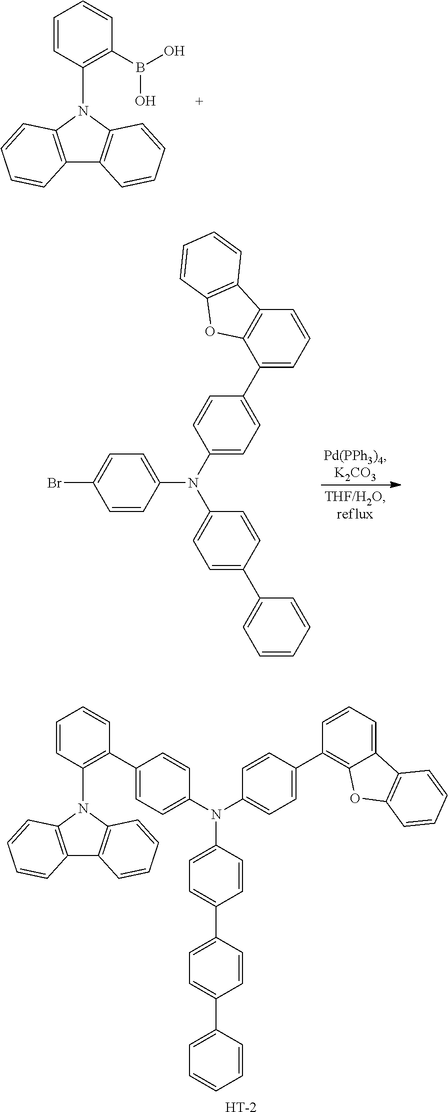

After completely dissolving compounds N-(4-bromophenyl)-N-(4-(dibenzo[b,d] furan-4-yl)phenyl)-[1,1′-biphenyl]-4-amine (11.09 g, 19.25 mmol) and (2-(9H-carbazol-9-yl)phenyl)boronic acid (6.08 g, 21.18 mmol) in tetrahydrofuran (240 ml) in a 500 ml round bottom flask under the nitrogen atmosphere, a 2 M aqueous potassium carbonate solution (120 ml) was added thereto, and after introducing tetrakis-(triphenylphosphine)palladium (0.67 g, 0.58 mmol) thereto, the result was stirred for 3 hours while heating. After lowering the temperature to room temperature, the water layer was removed, and the result was dried with anhydrous magnesium sulfate, then vacuum concentrated, and recrystallized with ethyl acetate (250 ml) to prepare Compound HT-2 (8.88 g, 62%).

MS[M+H]⁺=729

### Preparation Example 12: Preparation of Compound HT-3

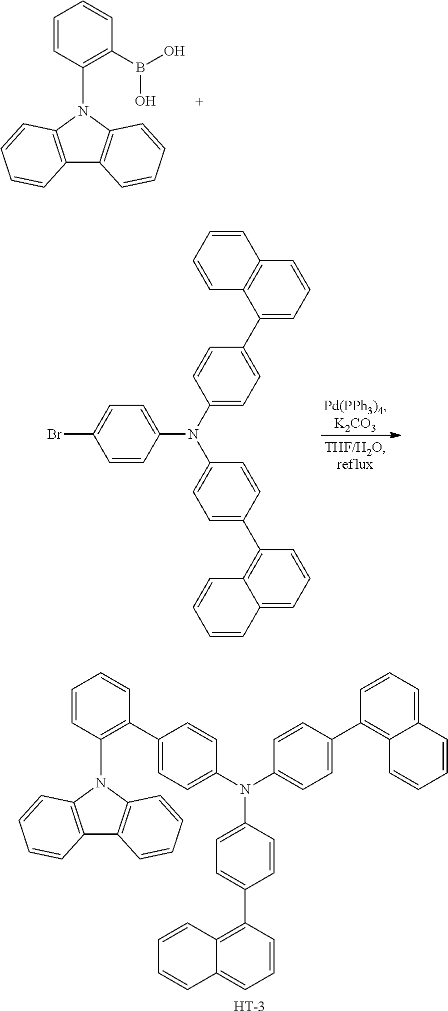

After completely dissolving compounds 4-bromo-N,N-bis(4-(naphthalen-1-yl)phenyl)aniline (8.45 g, 14.66 mmol) and (2-(9H-carbazol-9-yl)phenyl)boronic acid (5.06 g, 17.64 mmol) in tetrahydrofuran (240 ml) in a 500 ml round bottom flask under the nitrogen atmosphere, a 2 M aqueous potassium carbonate solution (120 ml) was added thereto, and after introducing tetrakis-(triphenylphosphine)palladium (0.53 g, 0.46 mmol) thereto, the result was stirred for 3 hours while heating. After lowering the temperature to room temperature, the water layer was removed, and the result was dried with anhydrous magnesium sulfate, then vacuum concentrated, and recrystallized with ethyl acetate (250 ml) to prepare Compound HT-3 (7.16 g, 63%).

MS[M+H]⁺=739

### Example 1

A glass substrate on which indium tin oxide (ITO) was coated as a thin film to a thickness of 1,400 Å was placed in distilled water containing dissolved detergent and ultrasonically cleaned. Herein, a Decon™ CON705 product of Fischer Co. was used as the detergent, and as the distilled water, distilled water filtered twice with a 0.22 μm sterilizing filter manufactured by Millipore Co. was used. After the ITO was cleaned for 30 minutes, ultrasonic cleaning was repeated twice using distilled water for 10 minutes. After the cleaning with distilled water was finished, the substrate was ultrasonically cleaned with solvents of isopropyl alcohol, acetone and methanol for 10 minutes each, then dried, and then transferred to a plasma cleaner. The substrate was cleaned for 5 minutes using oxygen plasma, and then transferred to a vacuum deposition apparatus.

On the transparent ITO electrode prepared as above, a hole injection layer was formed by consecutively thermal vacuum depositing the following compound HI-A and the following compound HAT-CN to a thickness of 650 Å and a thickness of 50 Å, respectively. A hole transfer layer was formed on the hole injection layer by vacuum depositing the following compound HTL to a thickness of 600 Å. On the hole transfer layer, an electron blocking layer was formed by thermal vacuum depositing the following compound HT-1 to a thickness of 50 Å. A light emitting layer was formed on the electron blocking layer by vacuum depositing BH-1 prepared above and the following compound BD-1 to a thickness of 200 Å in a 96:4 weight ratio. On the light emitting layer, a hole blocking layer was formed by vacuum depositing the following compound ET-A to a thickness of 50 Å. An electron transfer layer was formed on the hole blocking layer by thermal vacuum depositing the following compound ET-B and the following compound Liq to a thickness of 310 Å in a 1:1 weight ratio. On the electron transfer layer, an electron injection layer was formed by vacuum depositing the following compound Liq compound to a thickness of 5 Å. A cathode was formed on the electron injection layer by consecutively depositing magnesium and silver to a thickness of 120 Å in a 10:1 weight ratio and aluminum to a thickness of 1000 Å, and as a result, an organic light emitting device was manufactured.

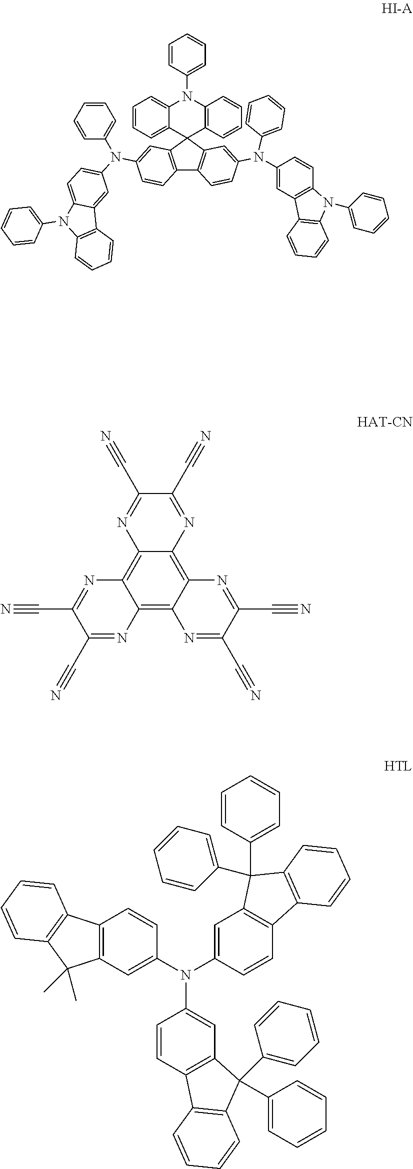 [SMILES: c1ccc(N(c2ccc3c(c2)C2(c4cc(N(c5ccccc5)c5ccc6c(c5)c5ccccc5n6-c5ccccc5)ccc4-3)c3ccccc3N(c3ccccc3)c3ccccc32)c2ccc3c(c2)c2ccccc2n3-c2ccccc2)cc1 ; N#Cc1nc2c3nc(C#N)c(C#N)nc3c3nc(C#N)c(C#N)nc3c2nc1C#N ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

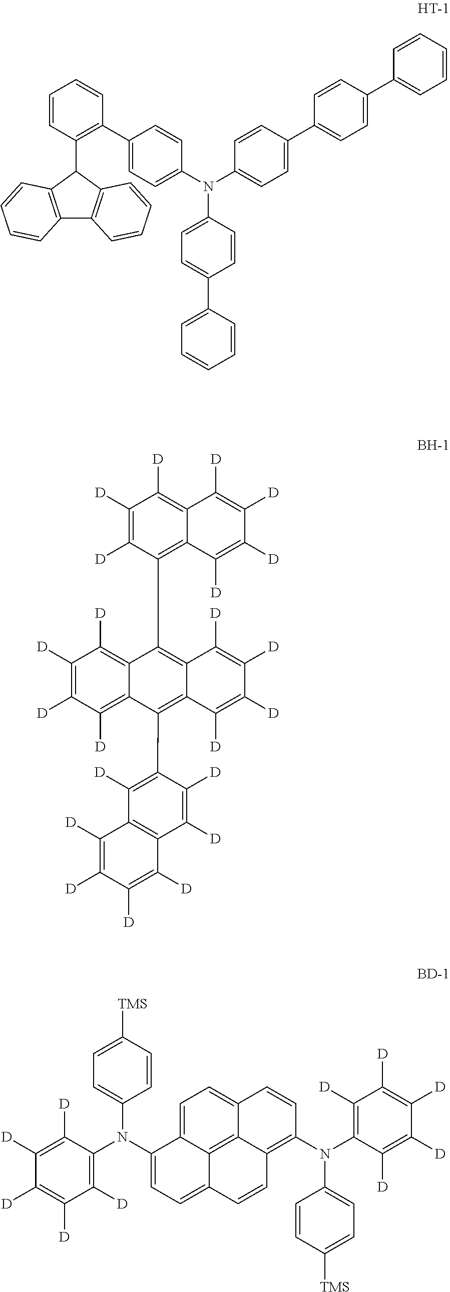 [SMILES: c1ccc(-c2ccc(-c3ccc(N(c4ccc(-c5ccccc5)cc4)c4ccc(-c5ccccc5C5c6ccccc6-c6ccccc65)cc4)cc3)cc2)cc1 ; [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H] ; [2H]c1c([2H])c([2H])c(N(c2ccc([Si](C)(C)C)cc2)c2ccc3ccc4c(N(c5ccc([Si](C)(C)C)cc5)c5c([2H])c([2H])c([2H])c([2H])c5[2H])ccc5ccc2c3c54)c([2H])c1[2H]]

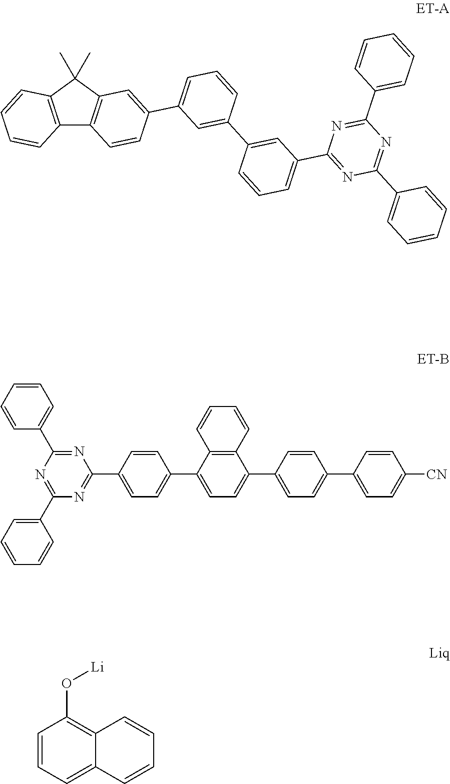

### Examples 2 to 18

Organic light emitting devices were manufactured in the same manner as in Example 1 except that compounds described in the following Table 1 were used instead of HT-1 and BH-1.

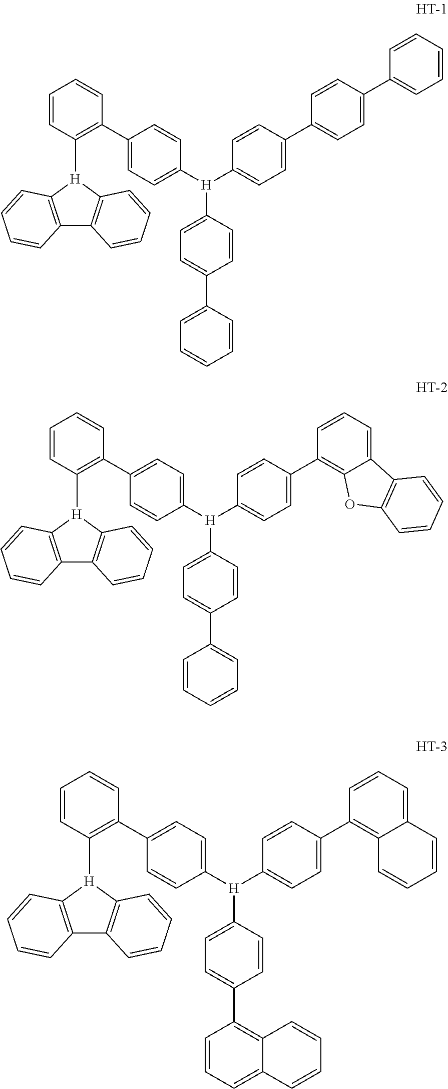

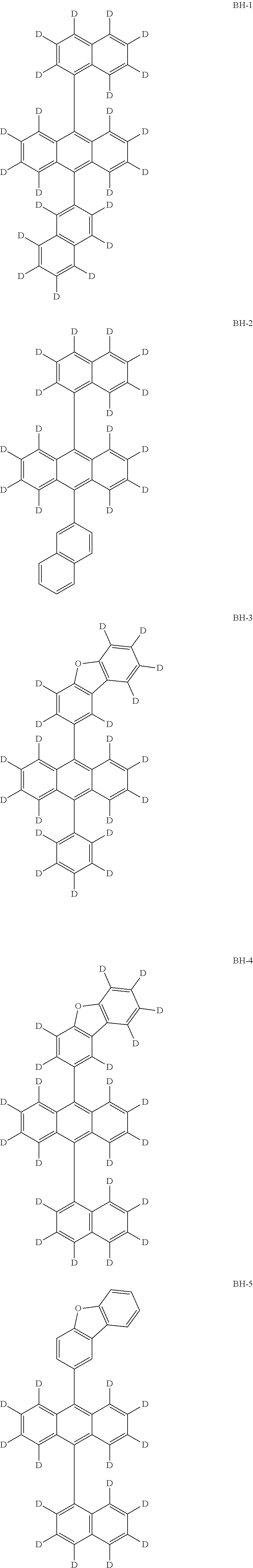

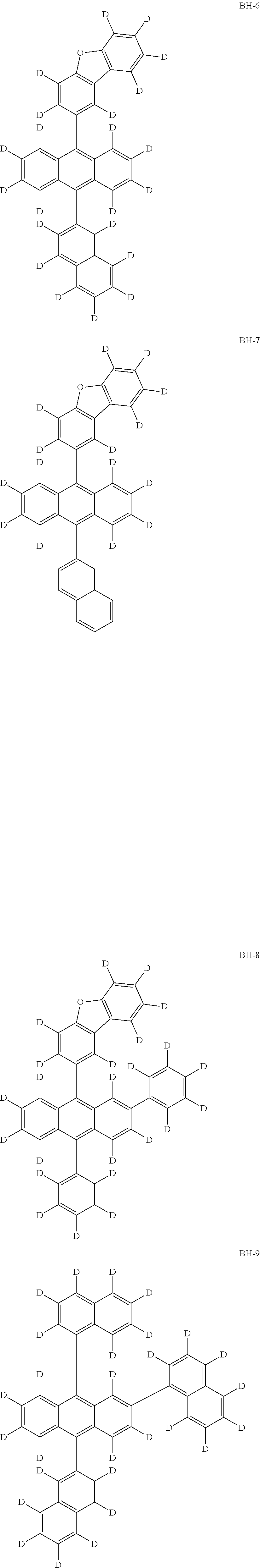

BH-1 had a deuterium substitution rate of 100%, BH-2 had a deuterium substitution rate of approximately 68.2%, BH-3 had a deuterium substitution rate of 100%, BH-4 had a deuterium substitution rate of 100%, BH-5 had a deuterium substitution rate of approximately 68.2%, BH-6 had a deuterium substitution rate of 100%, BH-7 had a deuterium substation rate of approximately 68.2%, BH-8 had a deuterium substitution rate of 100%, and BH-9 had a deuterium substitution rate of 100%.

### Examples 19 and 20

Organic light emitting devices were manufactured in the same manner as in Example 1 except that the following BD-2 was used instead of BD-1, and compounds described in the following Table 1 were used instead of BH-1.

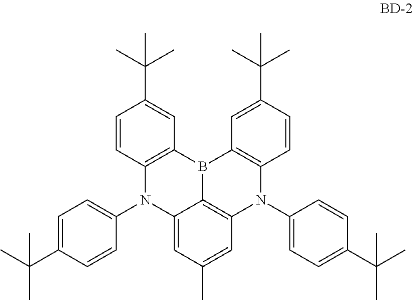 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### Comparative Examples 1 to 14

Organic light emitting devices were manufactured in the same manner as in Example 1 except that compounds described in the following Table 1 were used instead of HT-1 and BH-1.

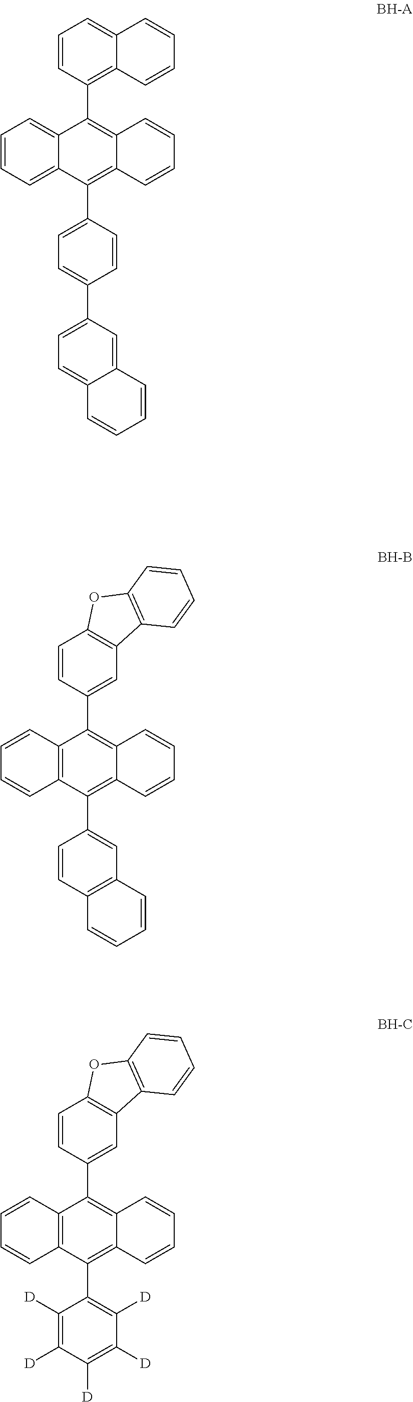

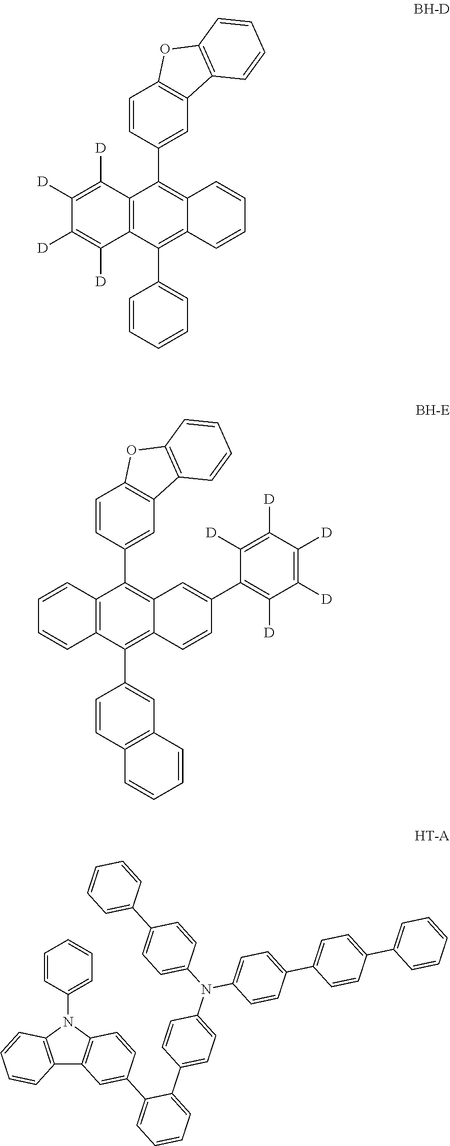 [SMILES: [2H]c1c([2H])c([2H])c2c(-c3ccc4oc5ccccc5c4c3)c3ccccc3c(-c3ccccc3)c2c1[2H] ; [2H]c1c([2H])c([2H])c(-c2ccc3c(-c4ccc5ccccc5c4)c4ccccc4c(-c4ccc5oc6ccccc6c5c4)c3c2)c([2H])c1[2H] ; c1ccc(-c2ccc(-c3ccc(N(c4ccc(-c5ccccc5)cc4)c4ccc(-c5ccccc5-c5ccc6c(c5)c5ccccc5n6-c5ccccc5)cc4)cc3)cc2)cc1]

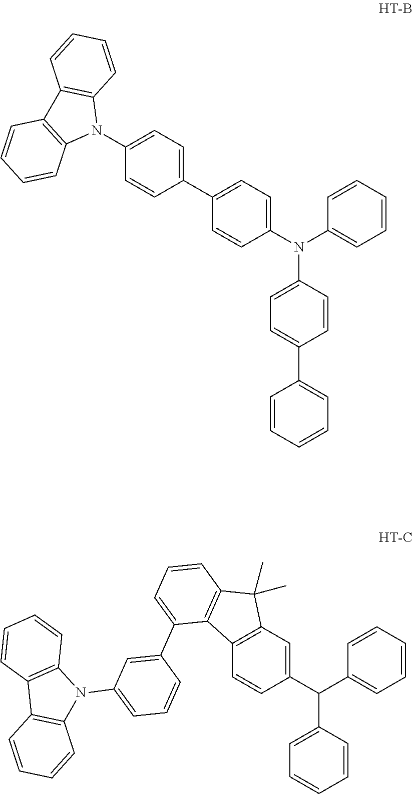 [SMILES: c1ccc(-c2ccc(N(c3ccccc3)c3ccc(-c4ccc(-n5c6ccccc6c6ccccc65)cc4)cc3)cc2)cc1 ; CC1(C)c2cc(C(c3ccccc3)c3ccccc3)ccc2-c2c(-c3cccc(-n4c5ccccc5c5ccccc54)c3)cccc21]

External quantum efficiency and lifetime (T95) were measured by applying a current to each of the organic light emitting devices manufactured in the examples and the comparative examples, and the results are shown in the following Table 1. T95 means time taken for initial luminance to decrease to 95% at current density of 20 mA/cm2.

TABLE 1

| | Electron | | | External | Lifetime |
|---|---|---|---|---|---|
| | Blocking | | | Quantum | (T95, hr) |
| | Layer | Host | Dopant | Efficiency | (@20 |
| | Material | Material | Material | EQE (%) | mA/cm²) |
| Example 1 | HT-1 | BH-1 | BD-1 | 9.9 | 90 |
| Example 2 | HT-1 | BH-2 | BD-1 | 9.8 | 83 |
| Example 3 | HT-1 | BH-3 | BD-1 | 10.1 | 82 |
| Example 4 | HT-1 | BH-4 | BD-1 | 10.5 | 80 |
| Example 5 | HT-1 | BH-5 | BD-1 | 10.5 | 78 |
| Example 6 | HT-1 | BH-6 | BD-1 | 9.9 | 80 |
| Example 7 | HT-1 | BH-7 | BD-1 | 9.8 | 78 |
| Example 8 | HT-1 | BH-8 | BD-1 | 9.7 | 98 |
| Example 9 | HT-1 | BH-9 | BD-1 | 9.8 | 86 |
| Example 10 | HT-3 | BH-1 | BD-1 | 9.9 | 95 |
| Example 11 | HT-3 | BH-2 | BD-1 | 9.9 | 90 |
| Example 12 | HT-2 | BH-3 | BD-1 | 10.2 | 90 |
| Example 13 | HT-2 | BH-4 | BD-1 | 10.5 | 85 |
| Example 14 | HT-2 | BH-5 | BD-1 | 10.3 | 82 |
| Example 15 | HT-2 | BH-6 | BD-1 | 9.8 | 86 |
| Example 16 | HT-2 | BH-7 | BD-1 | 9.8 | 80 |
| Example 17 | HT-2 | BH-8 | BD-1 | 9.6 | 94 |
| Example 18 | HT-3 | BH-9 | BD-1 | 9.6 | 82 |
| Example 19 | HT-1 | BH-1 | BD-2 | 10.6 | 96 |
| Example 20 | HT-1 | BH-2 | BD-2 | 10.5 | 91 |
| Comparative | HT-1 | BH-A | BD-1 | 9.8 | 44 |
| Example 1 | | | | | |
| Comparative | HT-1 | BH-B | BD-1 | 9.8 | 30 |
| Example 2 | | | | | |
| Comparative | HT-1 | BH-C | BD-1 | 9.9 | 52 |
| Example 3 | | | | | |
| Comparative | HT-1 | BH-D | BD-1 | 9.9 | 56 |
| Example 4 | | | | | |
| Comparative | HT-1 | BH-E | BD-1 | 9.5 | 60 |
| Example 5 | | | | | |
| Comparative | HT-A | BH-1 | BD-1 | 8.7 | 85 |
| Example 6 | | | | | |
| Comparative | HT-A | BH-2 | BD-1 | 8.7 | 82 |
| Example 7 | | | | | |
| Comparative | HT-A | BH-3 | BD-1 | 8.9 | 87 |
| Example 8 | | | | | |
| Comparative | HT-B | BH-1 | BD-1 | 8.9 | 80 |
| Example 9 | | | | | |
| Comparative | HT-B | BH-2 | BD-1 | 8.9 | 77 |
| Example 10 | | | | | |
| Comparative | HT-B | BH-3 | BD-1 | 9.1 | 79 |
| Example 11 | | | | | |
| Comparative | HT-C | BH-1 | BD-1 | 8.8 | 80 |
| Example 12 | | | | | |
| Comparative | HT-C | BH-2 | BD-1 | 8.9 | 75 |
| Example 13 | | | | | |
| Comparative | HT-C | BH-3 | BD-1 | 8.7 | 75 |
| Example 14 | | | | | |

From the results of Table 1, it was identified that the organic light emitting devices using the deuterium-substituted host compounds BH-1 to BH-9 together with compounds HT-1 to HT-3 exhibited superior lifetime properties while maintaining efficiency compared to Comparative Examples 1 to 5 using Compounds BH-A to BH-E that are either not substituted with deuterium, or substituted with deuterium by less than 40% as a host. In addition, from the results of Table 1, it was identified that Examples 1 to 20 using Compounds HT-1 to HT-3 of Chemical Formula 1 of the present disclosure having an ortho-phenylene linker as an electron blocking layer material exhibited effects of improving efficiency and lifetime compared to Comparative Examples 6 to 14 using HT-A having a different phenylene and carbazole bonding position and HT-B and HT-C having a para or meta-phenylene linker.

1. An organic light emitting device comprising:
an anode;
a cathode; and
a first organic material layer and a second organic material layer provided between the anode and the cathode,
wherein the first organic material layer includes a compound of the following Chemical Formula 1; and
the second organic material layer includes a compound of the following Chemical Formula 2: 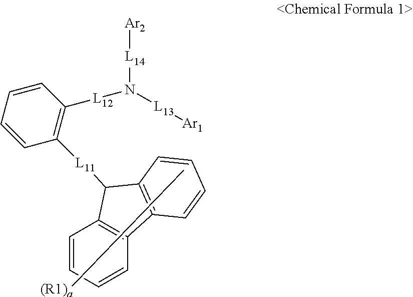
wherein in Chemical Formula 1;
L11 to L14 are the same as or different from each other, and each independently is a direct bond or a substituted or unsubstituted arylene group;
Ar1 and Ar2 are the same as or different from each other, and each independently is a substituted or unsubstituted aryl group or a substituted or unsubstituted heterocyclic group;
R1 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group; and
a is an integer of 0 to 8, and when a is 2 or greater, the two or more R1s are the same as or different from each other; 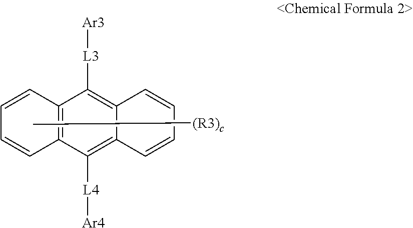
wherein in Chemical Formula 2:
L3 and L4 are the same as or different from each other, and each independently is a direct bond or a substituted or unsubstituted arylene group;
Ar3 and Ar4 are the same as or different from each other, and each independently is a substituted or unsubstituted aryl group or a substituted or unsubstituted heterocyclic group;
R3 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group or a substituted or unsubstituted heterocyclic group;
c is an integer of 0 to 8, and when c is 2 or greater, the two or more R3s are the same as or different from each other; and
the compound of Chemical Formula 2 is substituted with deuterium by at least 40%.

2. The organic light emitting device of claim 1, wherein the second organic material layer is a light emitting layer, and the first organic material layer is provided between the light emitting layer and the anode.

3. The organic light emitting device of claim 1, wherein Ar1 and Ar2 are the same as or different from each other, and each independently is a substituted or unsubstituted phenyl group, a substituted or unsubstituted biphenyl group, a substituted or unsubstituted terphenyl group; a substituted or unsubstituted naphthyl group, a substituted or unsubstituted fluorenyl group, a substituted or unsubstituted phenanthrenyl group, a substituted or unsubstituted triphenylenyl group, a substituted or unsubstituted dibenzofuran group, or a substituted or unsubstituted dibenzothiophene group.

4. The organic light emitting device of claim 1, wherein Chemical Formula 1 is the following Chemical Formula 1-1: 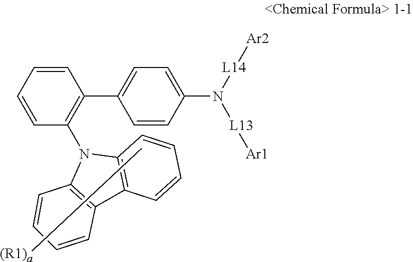
wherein in Chemical Formula 1-1:
L13, L14, Ar1, Ar2, R1 and a have the same definitions as in Chemical Formula 1.

5. The organic light emitting device of claim 1, wherein Chemical Formula 1 is the following Chemical Formula 1-2: 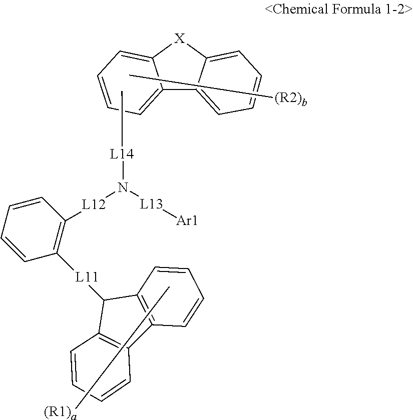
wherein in Chemical Formula 1-2 :
L11 to L14, Ar1, R1 and a have the same definitions as in Chemical Formula 1;
X is O or S;
R2 is hydrogen, deuterium, a halogen group, a cyano group, a substituted or unsubstituted silyl group, a substituted or unsubstituted alkyl group; a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group; and
b is an integer of 0 to 7, and when b is 2 or greater, the two or more R2s are the same as or different from each other.

6. The organic light emitting device of claim 1, wherein R3 is deuterium, and c is 8.

7. The organic light emitting device of claim 1, wherein Chemical Formula 2 is any one of the following Chemical Formulae 2-1 to 2-3: 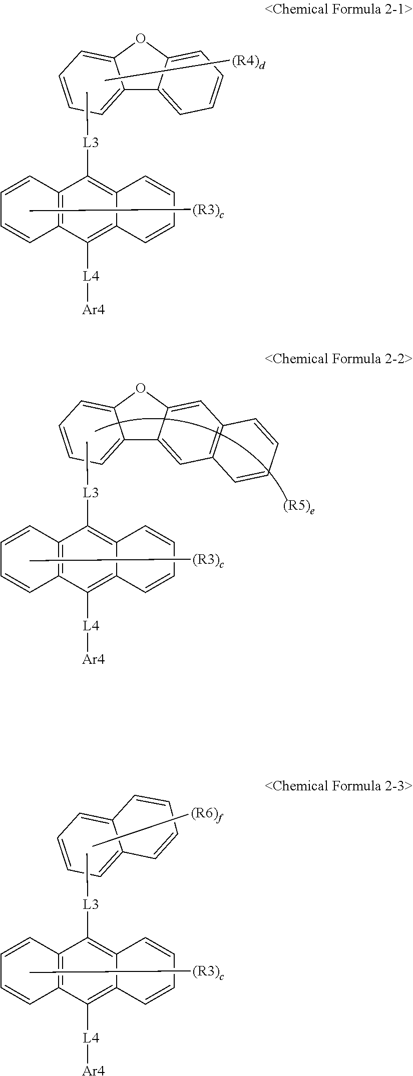
wherein in Chemical Formulae 2-1 to 2-3;
L3, L4, Ar4, R3 and c have the same definitions as in Chemical Formula 2;
R4 to R6 are the same as or different from each other, and each independently is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group, or a substituted or unsubstituted heterocyclic group;
d is an integer of 0 to 7, and when d is 2 or greater, the two or more R4s are the same as or different from each other;
e is an integer of 0 to 9, and when e is 2 or greater, the two or more R5s are the same as or different from each other; and
f is an integer of 0 to 7, and when f is 2 or greater, the two or more R6s are the same as or different from each other.

8. The organic light emitting device of claim 1, wherein Chemical Formula 2 is the following Chemical Formula 2-4 or 2-5: 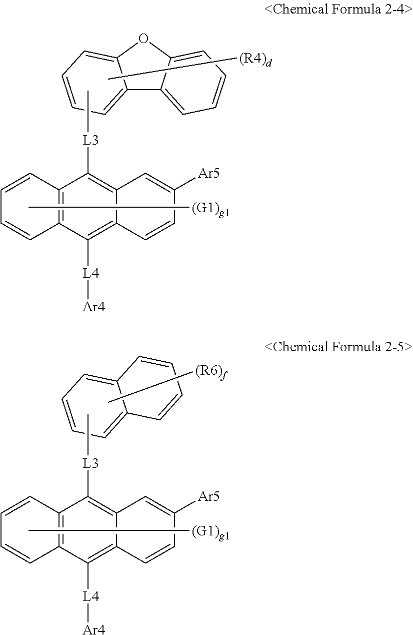
wherein in Chemical Formulae 2-4 and 2-5:
L3, L4 and Ar4 have the same definitions as in Chemical Formula 2;
Ar5 is a substituted or unsubstituted aryl group;
R4 and R6 are the same as or different from each other, and each independently is hydrogen, deuterium, a halogen group, a cyano group, a substituted or unsubstituted silyl group, a substituted or unsubstituted alkyl group, a substituted or unsubstituted cycloalkyl group; a substituted or unsubstituted alkoxy group, a substituted or unsubstituted aryloxy group, a substituted or unsubstituted aryl group, or a substituted or unsubstituted heterocyclic group;
G1 is hydrogen, deuterium, a halogen group, a cyano group, a substituted or unsubstituted silyl group, a substituted or unsubstituted alkyl group, a substituted or unsubstituted cycloalkyl group, a substituted or unsubstituted alkoxy group, a substituted or unsubstituted aryloxy group, a substituted or unsubstituted aryl group or a substituted or unsubstituted heterocyclic group;
d is an integer of 0 to 7, and when d is 2 or greater, the two or more R4s are the same as or different from each other;
f is an integer of 0 to 7, and when f is 2 or greater, the two or more R6s are the same as or different from each other; and
g1 is an integer of 0 to 7, and when g1 is 2 or greater, the two or more GIs are the same as or different from each other.

9. The organic light emitting device of claim 1, wherein the compound of Chemical Formula 2 is substituted with deuterium by 60% or greater.

10. The organic light emitting device of claim 1, wherein the compound of Chemical Formula 2 is substituted with deuterium by 80% or greater.

11. The organic light emitting device of claim 1, wherein Chemical Formula 2 is the following Chemical Formula A-1 or A-2: 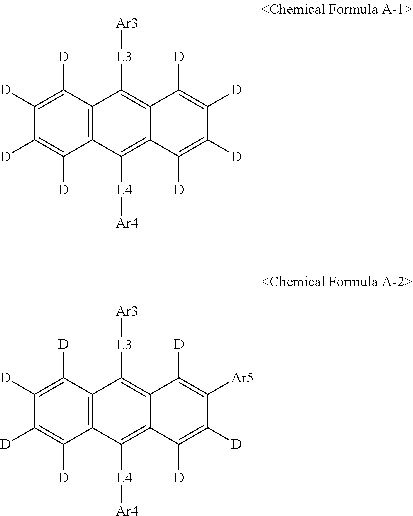
wherein in Chemical Formulae A-1 and A-2;
D means deuterium, and L3, L4, Ar3 and Ar4 have the same definitions as in Chemical Formula 2; and
Ar5 is a substituted or unsubstituted aryl group.

12. The organic light emitting device of claim 1, wherein the compound of Chemical Formula 1 is any one of the following compounds:

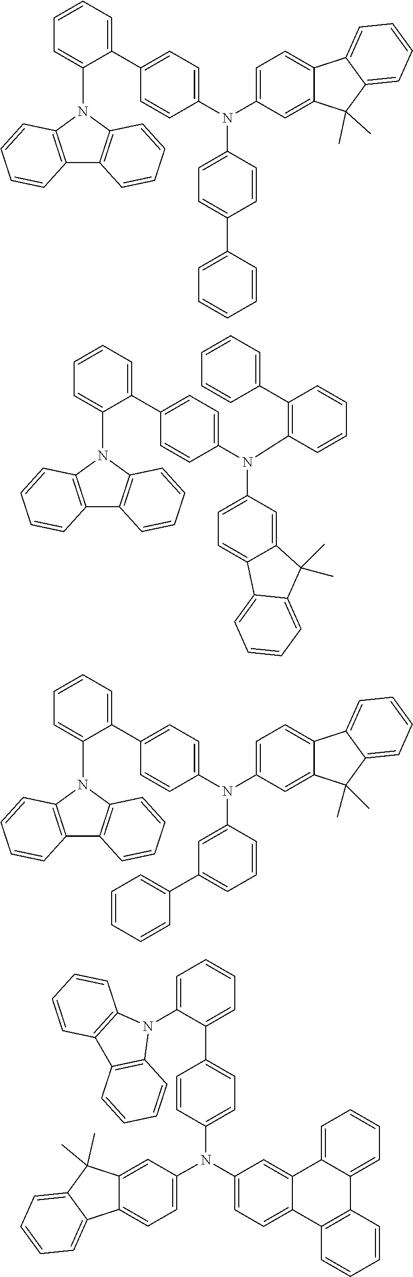

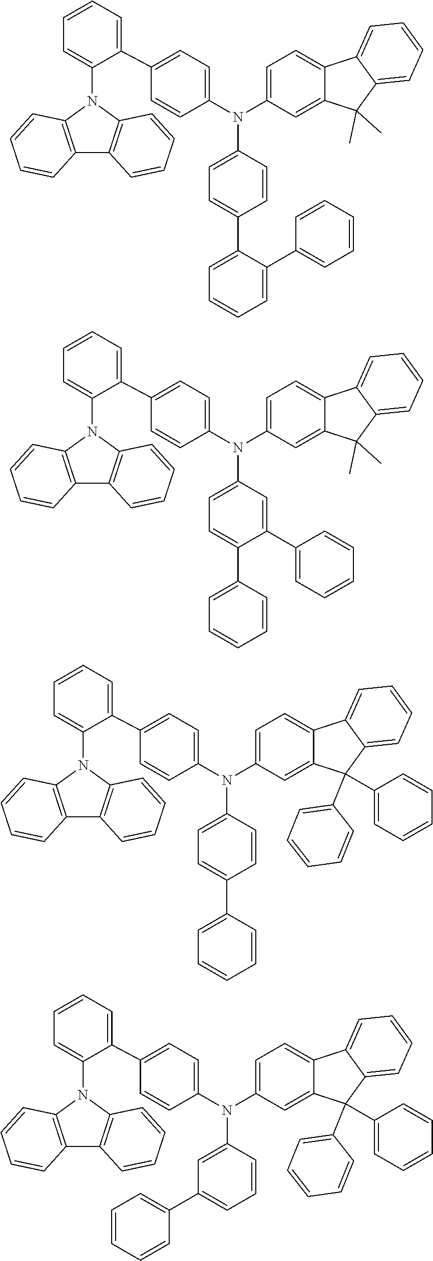 [SMILES: CC1(C)c2ccccc2-c2ccc(N(c3ccc(-c4ccccc4-c4ccccc4)cc3)c3ccc(-c4ccccc4-n4c5ccccc5c5ccccc54)cc3)cc21 ; CC1(C)c2ccccc2-c2ccc(N(c3ccc(-c4ccccc4-n4c5ccccc5c5ccccc54)cc3)c3ccc(-c4ccccc4)c(-c4ccccc4)c3)cc21 ; c1ccc(-c2ccc(N(c3ccc(-c4ccccc4-n4c5ccccc5c5ccccc54)cc3)c3ccc4c(c3)C(c3ccccc3)(c3ccccc3)c3ccccc3-4)cc2)cc1 ; c1ccc(-c2cccc(N(c3ccc(-c4ccccc4-n4c5ccccc5c5ccccc54)cc3)c3ccc4c(c3)C(c3ccccc3)(c3ccccc3)c3ccccc3-4)c2)cc1]

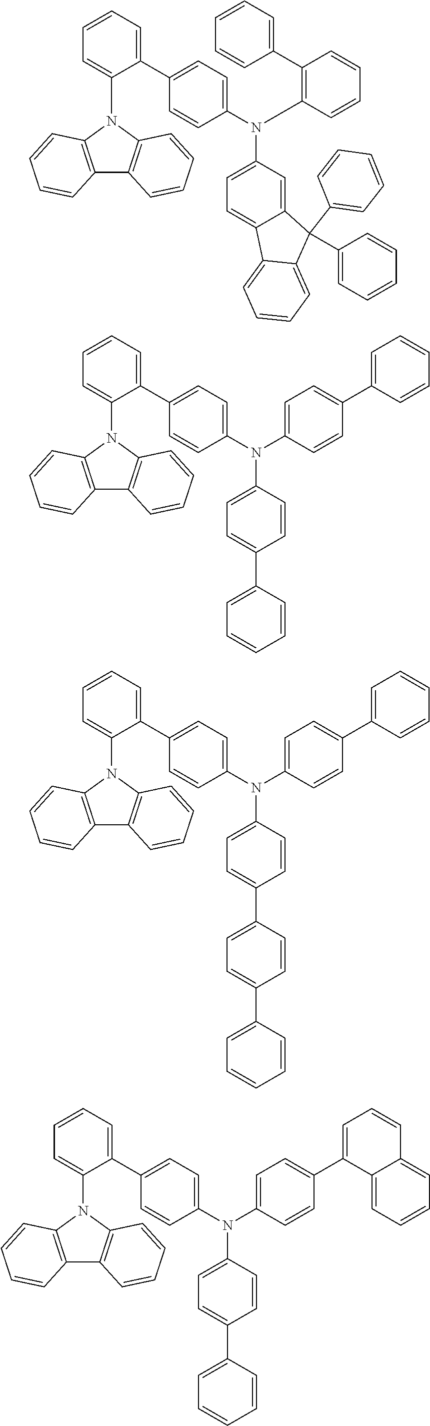 [SMILES: c1ccc(-c2ccccc2N(c2ccc(-c3ccccc3-n3c4ccccc4c4ccccc43)cc2)c2ccc3c(c2)C(c2ccccc2)(c2ccccc2)c2ccccc2-3)cc1 ; c1ccc(-c2ccc(N(c3ccc(-c4ccccc4)cc3)c3ccc(-c4ccccc4-n4c5ccccc5c5ccccc54)cc3)cc2)cc1 ; c1ccc(-c2ccc(-c3ccc(N(c4ccc(-c5ccccc5)cc4)c4ccc(-c5ccccc5-n5c6ccccc6c6ccccc65)cc4)cc3)cc2)cc1 ; c1ccc(-c2ccc(N(c3ccc(-c4ccccc4-n4c5ccccc5c5ccccc54)cc3)c3ccc(-c4cccc5ccccc45)cc3)cc2)cc1]

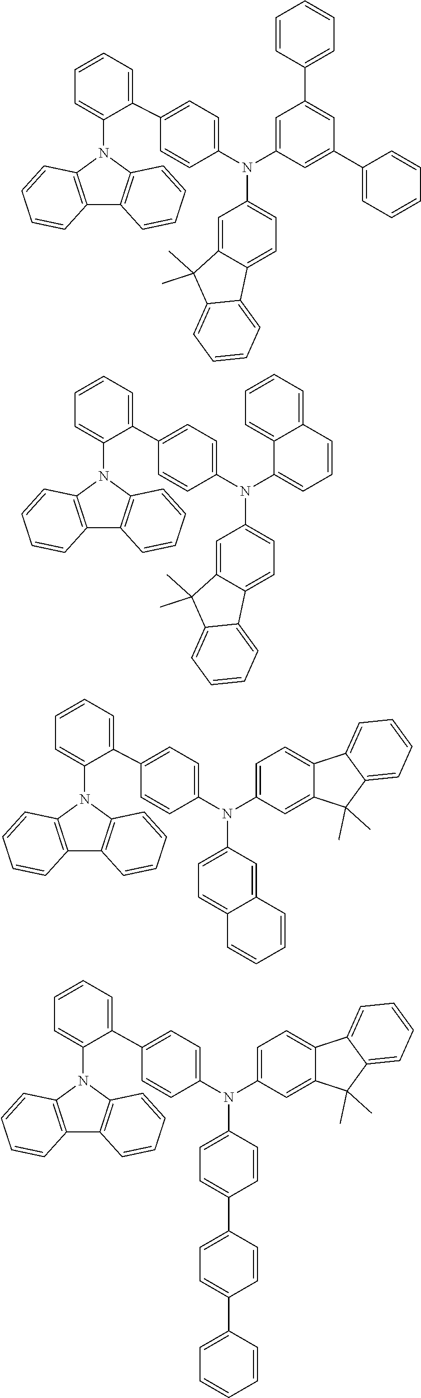

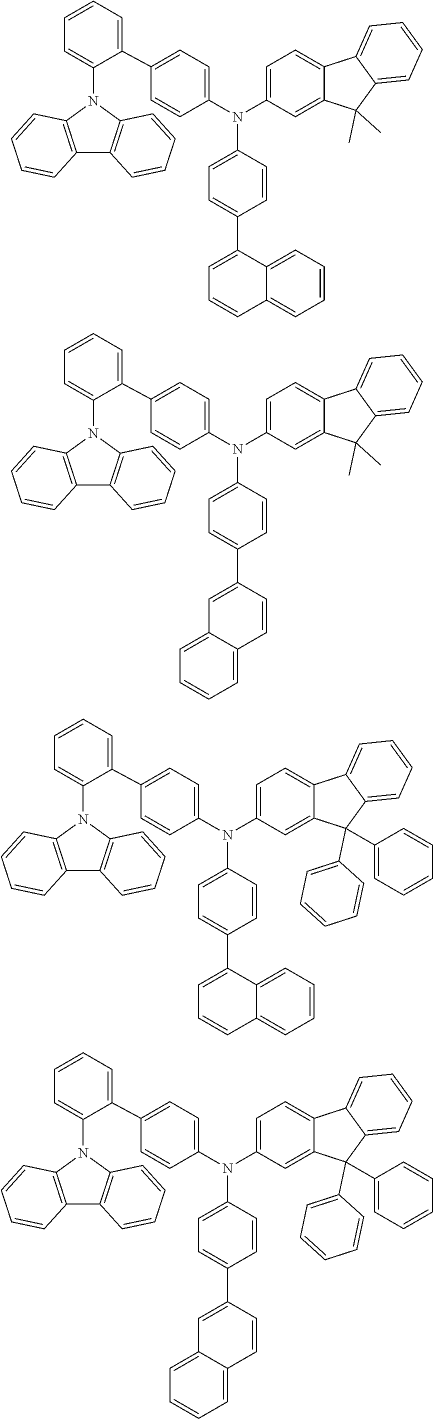 [SMILES: CC1(C)c2ccccc2-c2ccc(N(c3ccc(-c4ccccc4-n4c5ccccc5c5ccccc54)cc3)c3ccc(-c4cccc5ccccc45)cc3)cc21 ; CC1(C)c2ccccc2-c2ccc(N(c3ccc(-c4ccc5ccccc5c4)cc3)c3ccc(-c4ccccc4-n4c5ccccc5c5ccccc54)cc3)cc21 ; c1ccc(C2(c3ccccc3)c3ccccc3-c3ccc(N(c4ccc(-c5ccccc5-n5c6ccccc6c6ccccc65)cc4)c4ccc(-c5cccc6ccccc56)cc4)cc32)cc1 ; c1ccc(C2(c3ccccc3)c3ccccc3-c3ccc(N(c4ccc(-c5ccc6ccccc6c5)cc4)c4ccc(-c5ccccc5-n5c6ccccc6c6ccccc65)cc4)cc32)cc1]

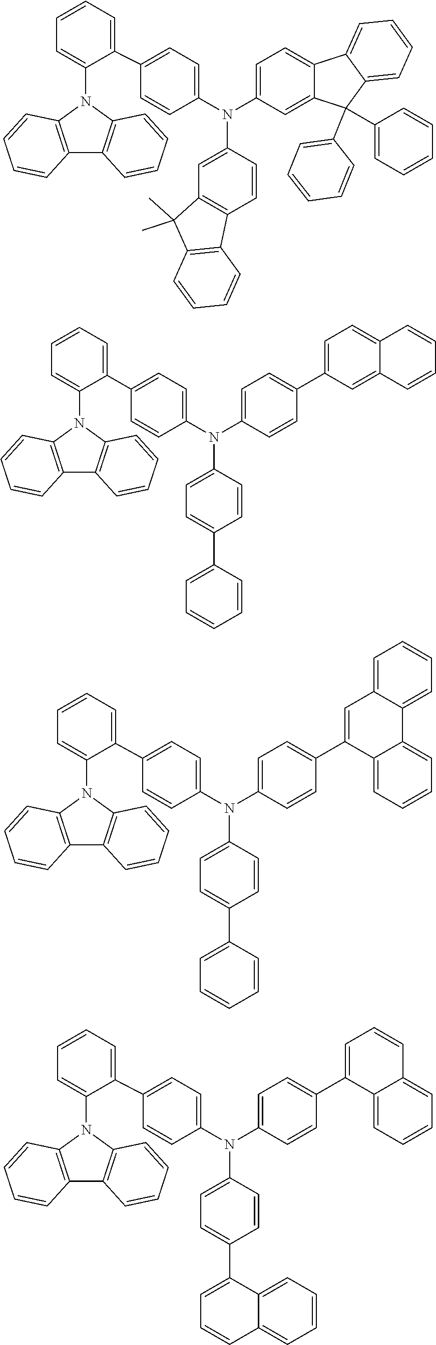 [SMILES: CC1(C)c2ccccc2-c2ccc(N(c3ccc(-c4ccccc4-n4c5ccccc5c5ccccc54)cc3)c3ccc4c(c3)C(c3ccccc3)(c3ccccc3)c3ccccc3-4)cc21 ; c1ccc(-c2ccc(N(c3ccc(-c4ccc5ccccc5c4)cc3)c3ccc(-c4ccccc4-n4c5ccccc5c5ccccc54)cc3)cc2)cc1 ; c1ccc(-c2ccc(N(c3ccc(-c4ccccc4-n4c5ccccc5c5ccccc54)cc3)c3ccc(-c4cc5ccccc5c5ccccc45)cc3)cc2)cc1 ; c1ccc(-n2c3ccccc3c3ccccc32)c(-c2ccc(N(c3ccc(-c4cccc5ccccc45)cc3)c3ccc(-c4cccc5ccccc45)cc3)cc2)c1]

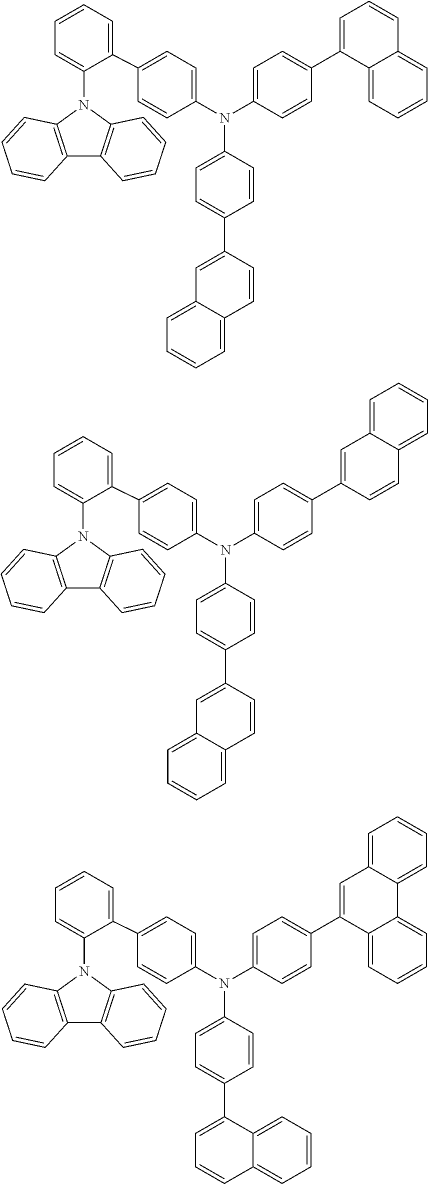 [SMILES: c1ccc(-n2c3ccccc3c3ccccc32)c(-c2ccc(N(c3ccc(-c4ccc5ccccc5c4)cc3)c3ccc(-c4cccc5ccccc45)cc3)cc2)c1 ; c1ccc(-n2c3ccccc3c3ccccc32)c(-c2ccc(N(c3ccc(-c4ccc5ccccc5c4)cc3)c3ccc(-c4ccc5ccccc5c4)cc3)cc2)c1 ; c1ccc(-n2c3ccccc3c3ccccc32)c(-c2ccc(N(c3ccc(-c4cccc5ccccc45)cc3)c3ccc(-c4cc5ccccc5c5ccccc45)cc3)cc2)c1]

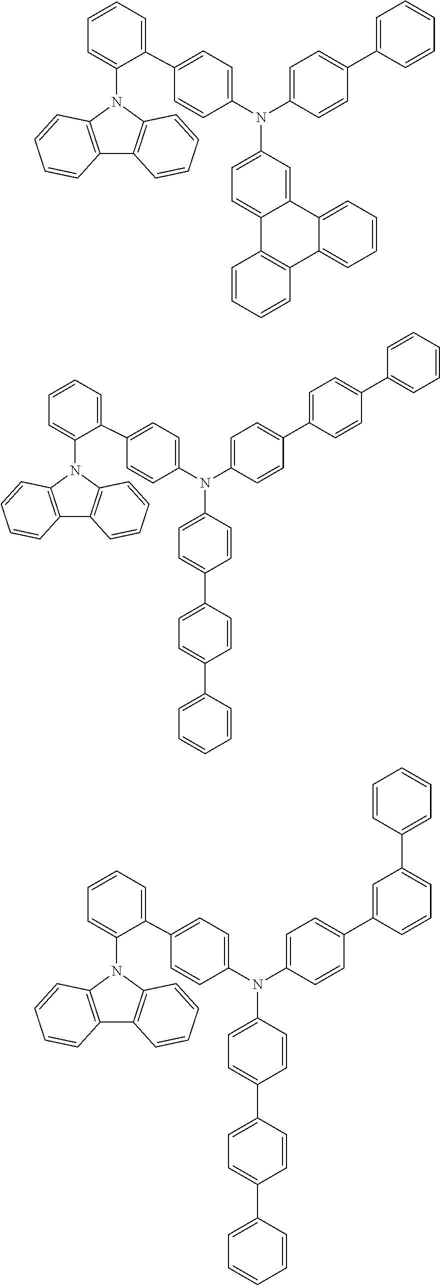 [SMILES: c1ccc(-c2ccc(N(c3ccc(-c4ccccc4-n4c5ccccc5c5ccccc54)cc3)c3ccc4c5ccccc5c5ccccc5c4c3)cc2)cc1 ; c1ccc(-c2ccc(-c3ccc(N(c4ccc(-c5ccc(-c6ccccc6)cc5)cc4)c4ccc(-c5ccccc5-n5c6ccccc6c6ccccc65)cc4)cc3)cc2)cc1 ; c1ccc(-c2ccc(-c3ccc(N(c4ccc(-c5cccc(-c6ccccc6)c5)cc4)c4ccc(-c5ccccc5-n5c6ccccc6c6ccccc65)cc4)cc3)cc2)cc1]

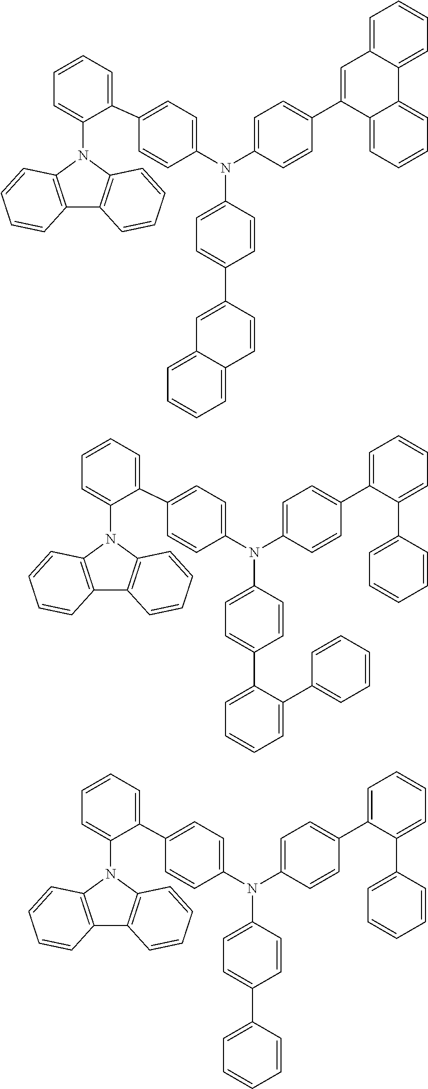 [SMILES: c1ccc(-n2c3ccccc3c3ccccc32)c(-c2ccc(N(c3ccc(-c4ccc5ccccc5c4)cc3)c3ccc(-c4cc5ccccc5c5ccccc45)cc3)cc2)c1 ; c1ccc(-c2ccccc2-c2ccc(N(c3ccc(-c4ccccc4-c4ccccc4)cc3)c3ccc(-c4ccccc4-n4c5ccccc5c5ccccc54)cc3)cc2)cc1 ; c1ccc(-c2ccc(N(c3ccc(-c4ccccc4-c4ccccc4)cc3)c3ccc(-c4ccccc4-n4c5ccccc5c5ccccc54)cc3)cc2)cc1]

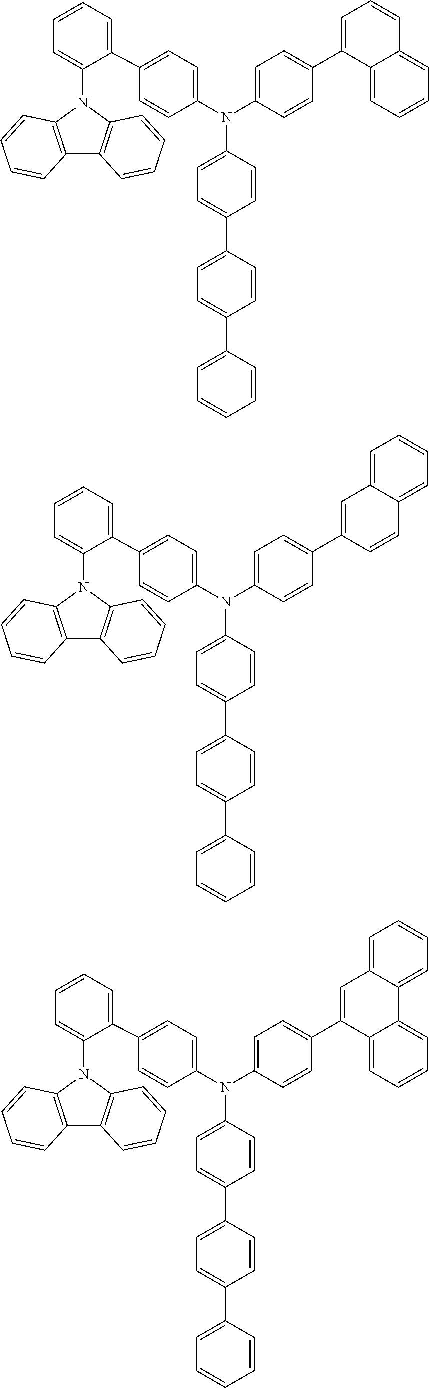 [SMILES: c1ccc(-c2ccc(-c3ccc(N(c4ccc(-c5ccccc5-n5c6ccccc6c6ccccc65)cc4)c4ccc(-c5cccc6ccccc56)cc4)cc3)cc2)cc1 ; c1ccc(-c2ccc(-c3ccc(N(c4ccc(-c5ccc6ccccc6c5)cc4)c4ccc(-c5ccccc5-n5c6ccccc6c6ccccc65)cc4)cc3)cc2)cc1 ; c1ccc(-c2ccc(-c3ccc(N(c4ccc(-c5ccccc5-n5c6ccccc6c6ccccc65)cc4)c4ccc(-c5cc6ccccc6c6ccccc56)cc4)cc3)cc2)cc1]

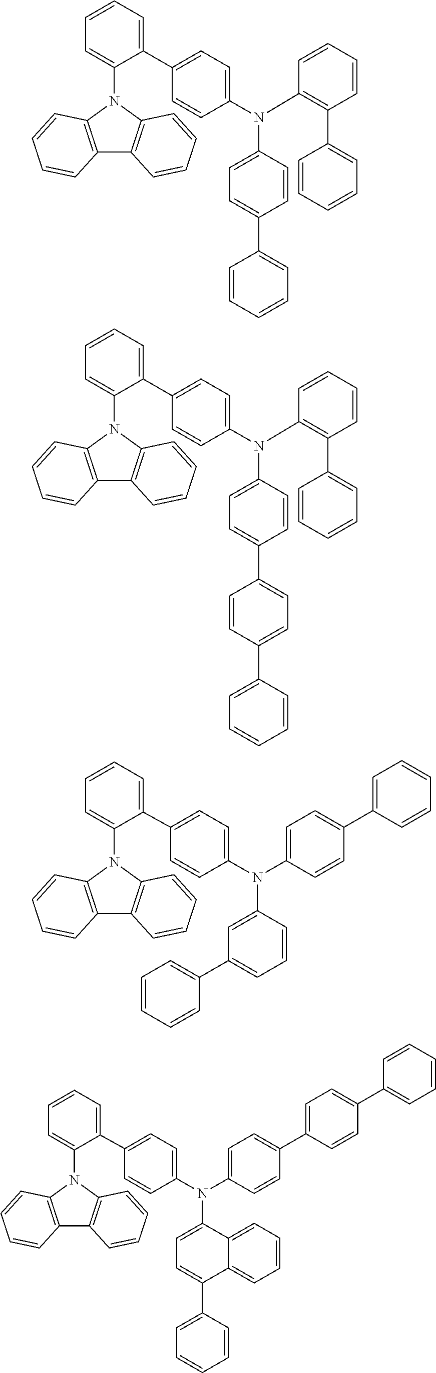 [SMILES: c1ccc(-c2ccc(N(c3ccc(-c4ccccc4-n4c5ccccc5c5ccccc54)cc3)c3ccccc3-c3ccccc3)cc2)cc1 ; c1ccc(-c2ccc(-c3ccc(N(c4ccc(-c5ccccc5-n5c6ccccc6c6ccccc65)cc4)c4ccccc4-c4ccccc4)cc3)cc2)cc1 ; c1ccc(-c2ccc(N(c3ccc(-c4ccccc4-n4c5ccccc5c5ccccc54)cc3)c3cccc(-c4ccccc4)c3)cc2)cc1 ; c1ccc(-c2ccc(-c3ccc(N(c4ccc(-c5ccccc5-n5c6ccccc6c6ccccc65)cc4)c4ccc(-c5ccccc5)c5ccccc45)cc3)cc2)cc1]

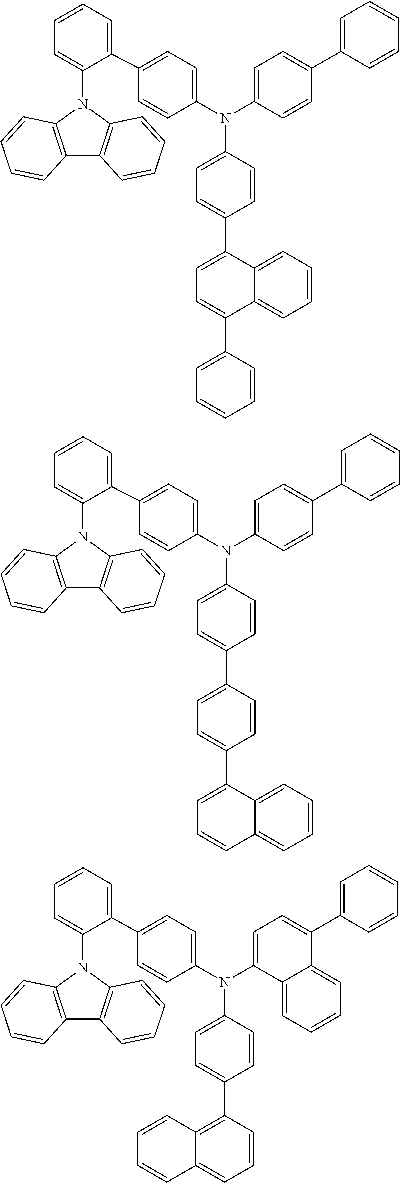 [SMILES: c1ccc(-c2ccc(N(c3ccc(-c4ccccc4-n4c5ccccc5c5ccccc54)cc3)c3ccc(-c4ccc(-c5ccccc5)c5ccccc45)cc3)cc2)cc1 ; c1ccc(-c2ccc(N(c3ccc(-c4ccc(-c5cccc6ccccc56)cc4)cc3)c3ccc(-c4ccccc4-n4c5ccccc5c5ccccc54)cc3)cc2)cc1 ; c1ccc(-c2ccc(N(c3ccc(-c4ccccc4-n4c5ccccc5c5ccccc54)cc3)c3ccc(-c4cccc5ccccc45)cc3)c3ccccc23)cc1]

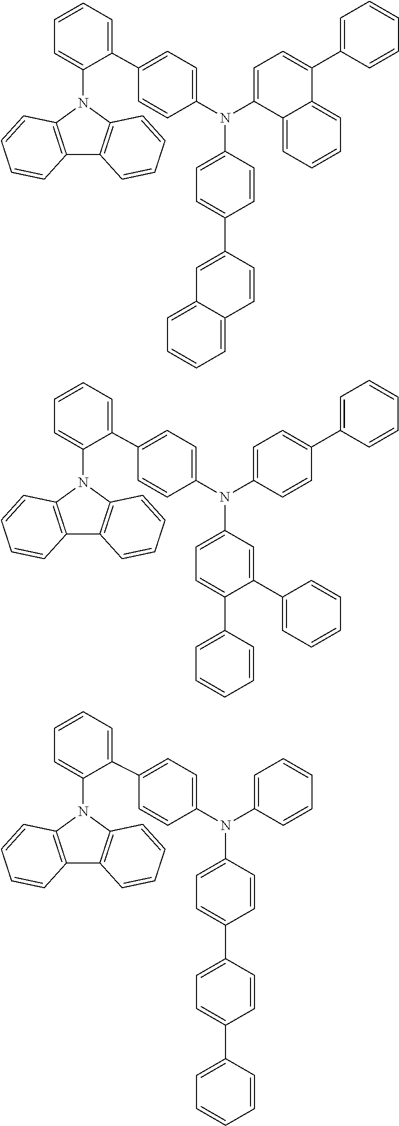 [SMILES: c1ccc(-c2ccc(N(c3ccc(-c4ccc5ccccc5c4)cc3)c3ccc(-c4ccccc4-n4c5ccccc5c5ccccc54)cc3)c3ccccc23)cc1 ; c1ccc(-c2ccc(N(c3ccc(-c4ccccc4-n4c5ccccc5c5ccccc54)cc3)c3ccc(-c4ccccc4)c(-c4ccccc4)c3)cc2)cc1 ; c1ccc(-c2ccc(-c3ccc(N(c4ccccc4)c4ccc(-c5ccccc5-n5c6ccccc6c6ccccc65)cc4)cc3)cc2)cc1]

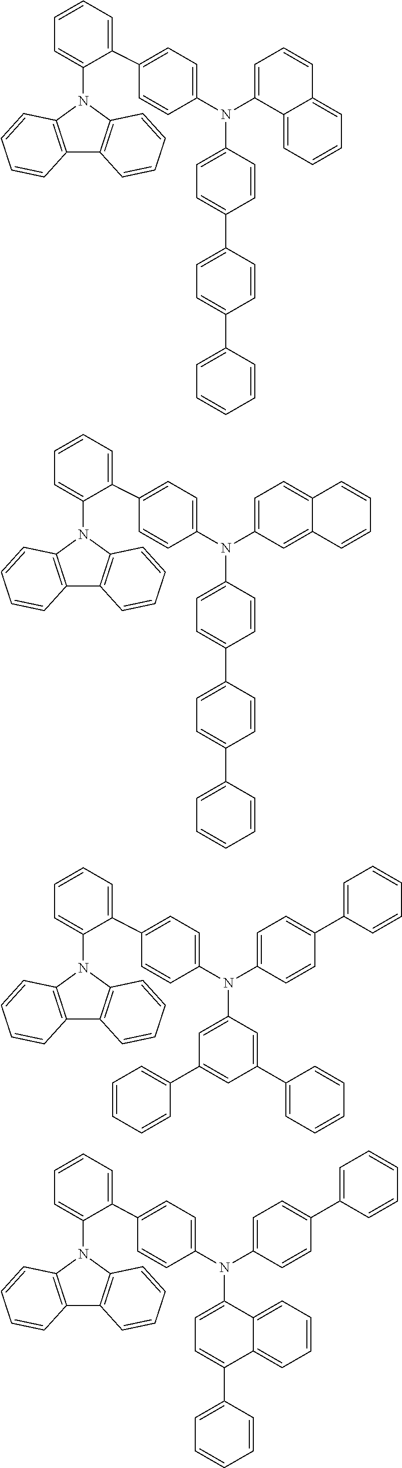

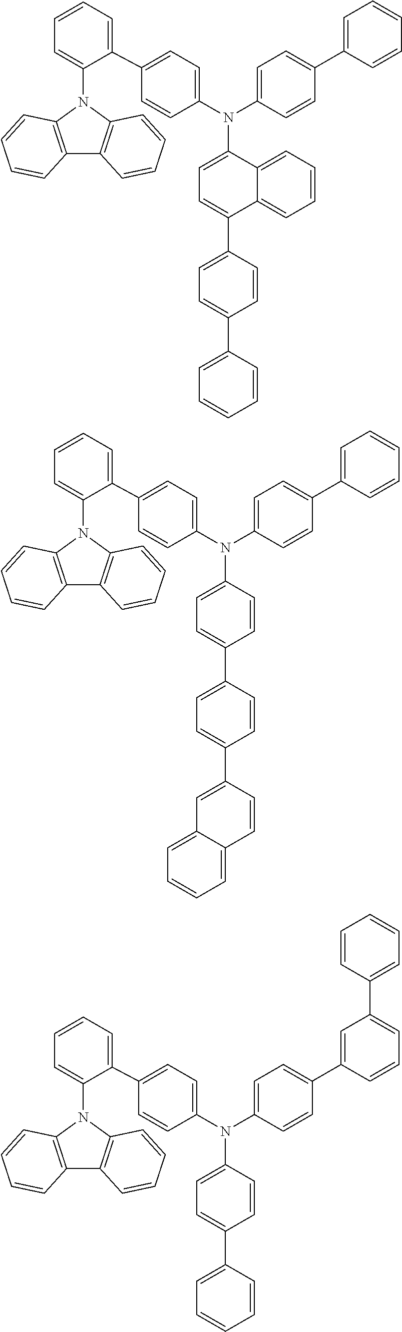 [SMILES: c1ccc(-c2ccc(-c3ccc(N(c4ccc(-c5ccccc5)cc4)c4ccc(-c5ccccc5-n5c6ccccc6c6ccccc65)cc4)c4ccccc34)cc2)cc1 ; c1ccc(-c2ccc(N(c3ccc(-c4ccc(-c5ccc6ccccc6c5)cc4)cc3)c3ccc(-c4ccccc4-n4c5ccccc5c5ccccc54)cc3)cc2)cc1 ; c1ccc(-c2ccc(N(c3ccc(-c4cccc(-c5ccccc5)c4)cc3)c3ccc(-c4ccccc4-n4c5ccccc5c5ccccc54)cc3)cc2)cc1]

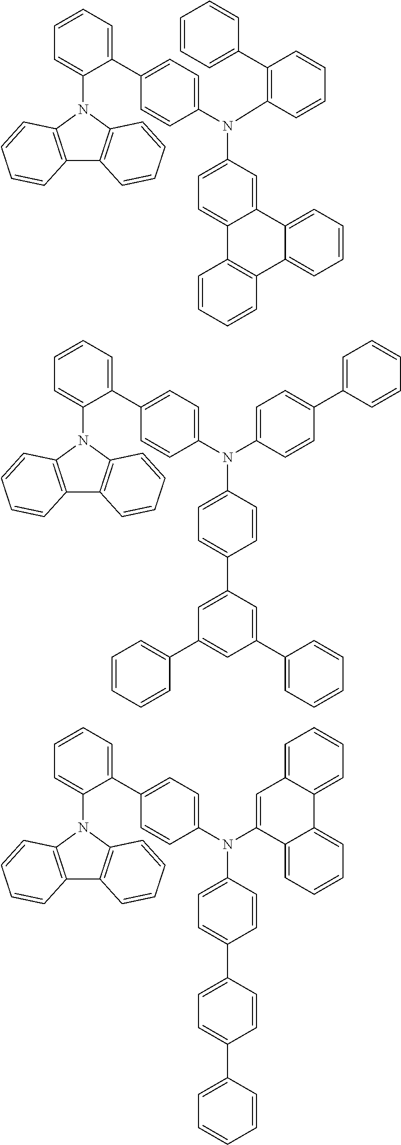

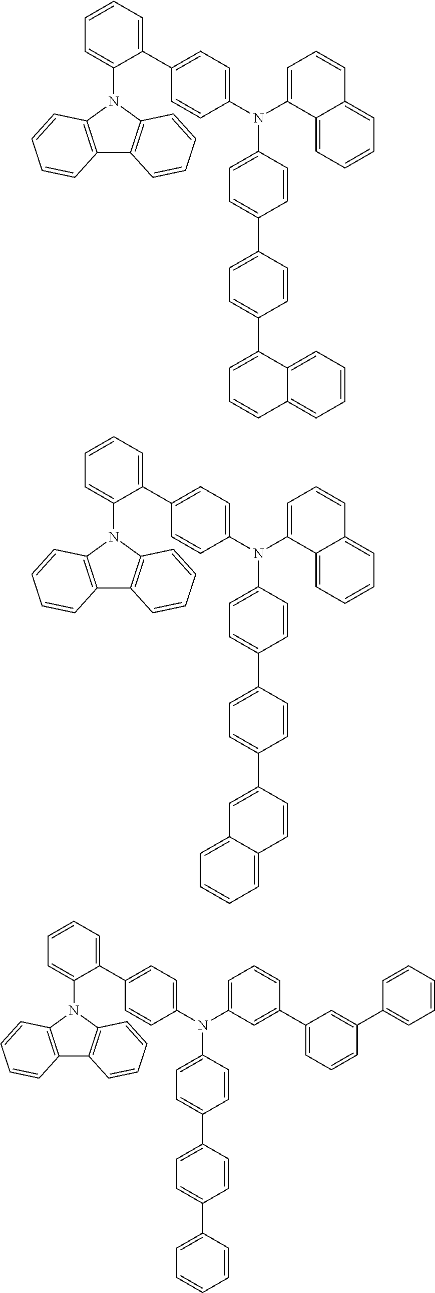 [SMILES: c1ccc(-n2c3ccccc3c3ccccc32)c(-c2ccc(N(c3ccc(-c4ccc(-c5cccc6ccccc56)cc4)cc3)c3cccc4ccccc34)cc2)c1 ; c1ccc(-n2c3ccccc3c3ccccc32)c(-c2ccc(N(c3ccc(-c4ccc(-c5ccc6ccccc6c5)cc4)cc3)c3cccc4ccccc34)cc2)c1 ; c1ccc(-c2ccc(-c3ccc(N(c4ccc(-c5ccccc5-n5c6ccccc6c6ccccc65)cc4)c4cccc(-c5cccc(-c6ccccc6)c5)c4)cc3)cc2)cc1]

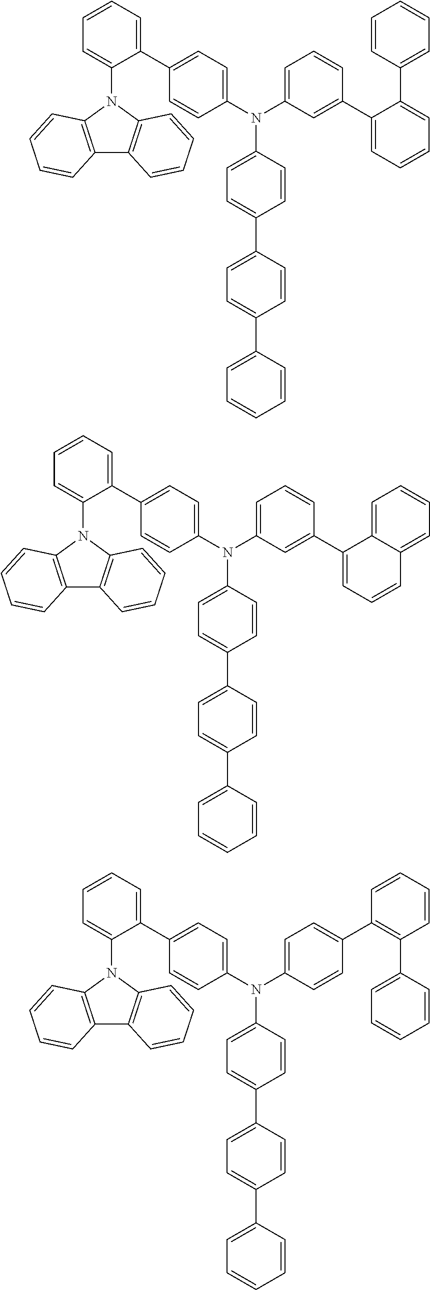 [SMILES: c1ccc(-c2ccc(-c3ccc(N(c4ccc(-c5ccccc5-n5c6ccccc6c6ccccc65)cc4)c4cccc(-c5ccccc5-c5ccccc5)c4)cc3)cc2)cc1 ; c1ccc(-c2ccc(-c3ccc(N(c4ccc(-c5ccccc5-n5c6ccccc6c6ccccc65)cc4)c4cccc(-c5cccc6ccccc56)c4)cc3)cc2)cc1 ; c1ccc(-c2ccc(-c3ccc(N(c4ccc(-c5ccccc5-c5ccccc5)cc4)c4ccc(-c5ccccc5-n5c6ccccc6c6ccccc65)cc4)cc3)cc2)cc1]

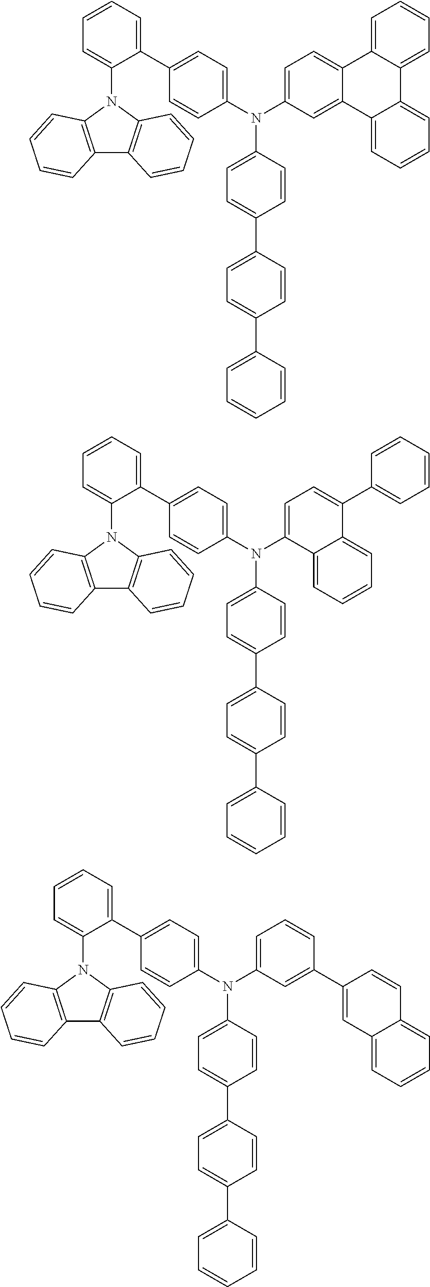 [SMILES: c1ccc(-c2ccc(-c3ccc(N(c4ccc(-c5ccccc5-n5c6ccccc6c6ccccc65)cc4)c4ccc5c6ccccc6c6ccccc6c5c4)cc3)cc2)cc1 ; c1ccc(-c2ccc(-c3ccc(N(c4ccc(-c5ccccc5-n5c6ccccc6c6ccccc65)cc4)c4ccc(-c5ccccc5)c5ccccc45)cc3)cc2)cc1 ; c1ccc(-c2ccc(-c3ccc(N(c4ccc(-c5ccccc5-n5c6ccccc6c6ccccc65)cc4)c4cccc(-c5ccc6ccccc6c5)c4)cc3)cc2)cc1]

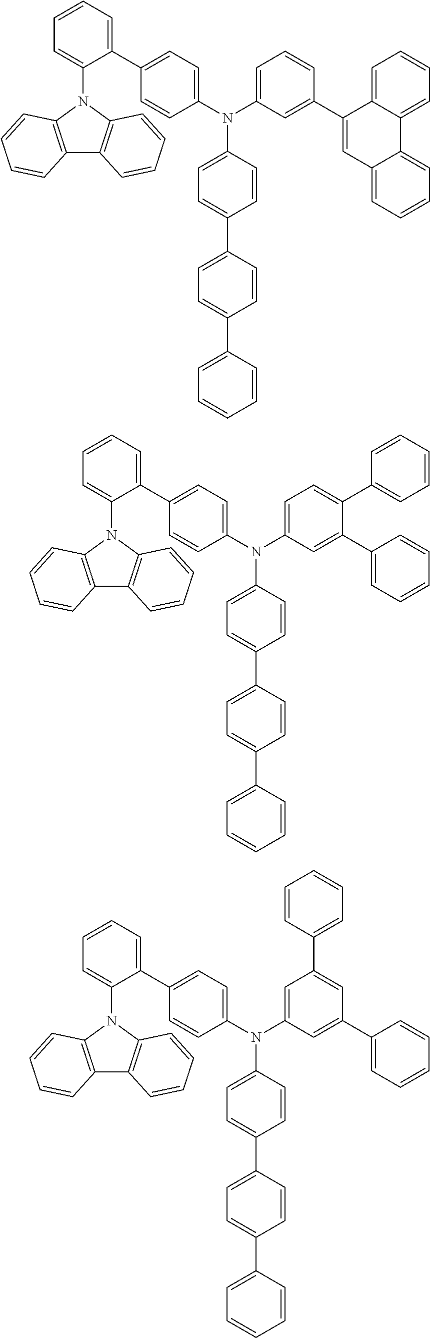

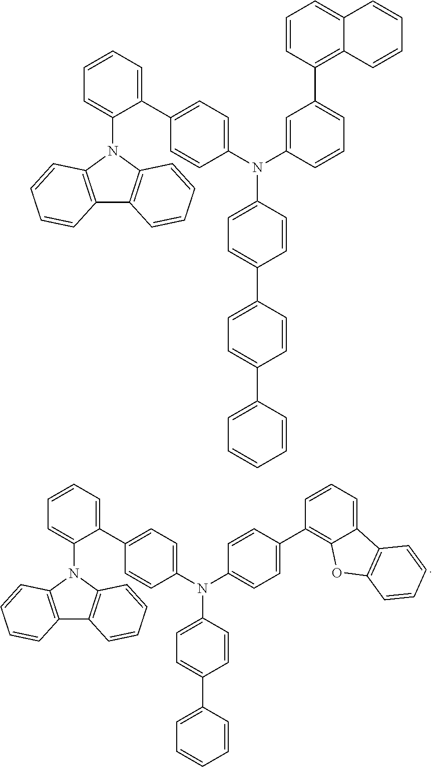 [SMILES: c1ccc(-c2ccc(-c3ccc(N(c4ccc(-c5ccccc5-n5c6ccccc6c6ccccc65)cc4)c4cccc(-c5cccc6ccccc56)c4)cc3)cc2)cc1 ; c1ccc(-c2ccc(N(c3ccc(-c4ccccc4-n4c5ccccc5c5ccccc54)cc3)c3ccc(-c4cccc5c4oc4ccccc45)cc3)cc2)cc1]

13. The organic light emitting device of claim 1, wherein the compound of Chemical Formula 2 is any one of the following compounds:

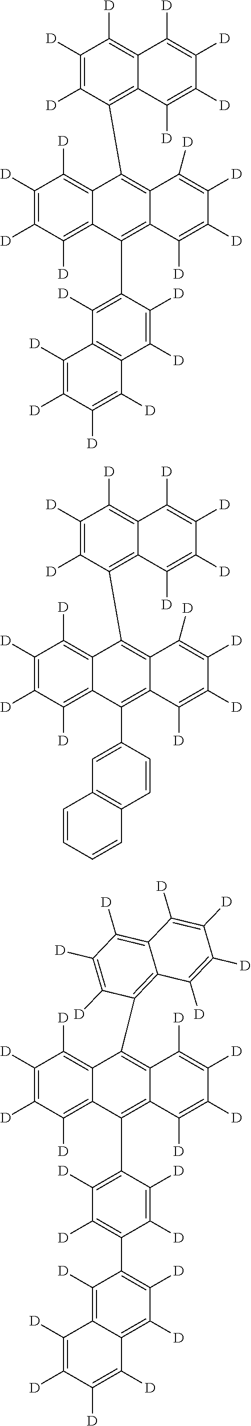

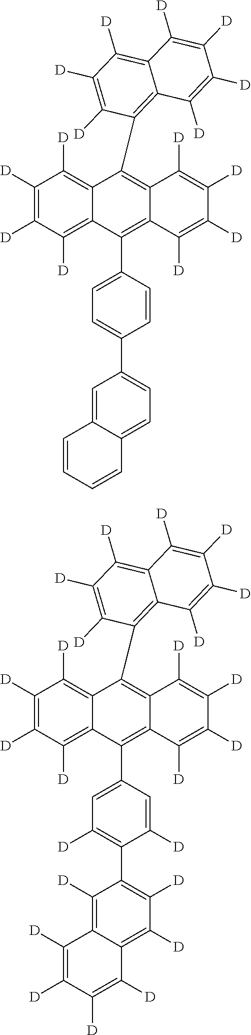

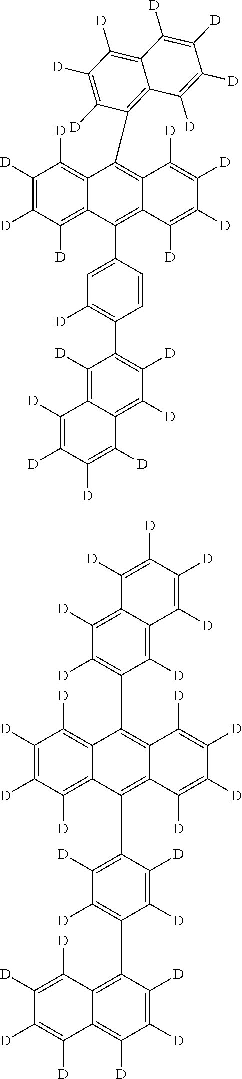 [SMILES: [2H]c1cc(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)ccc1-c1c([2H])c([2H])c2c([2H])c([2H])c([2H])c([2H])c2c1[2H] ; [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c([2H])c2c([2H])c([2H])c([2H])c([2H])c12]

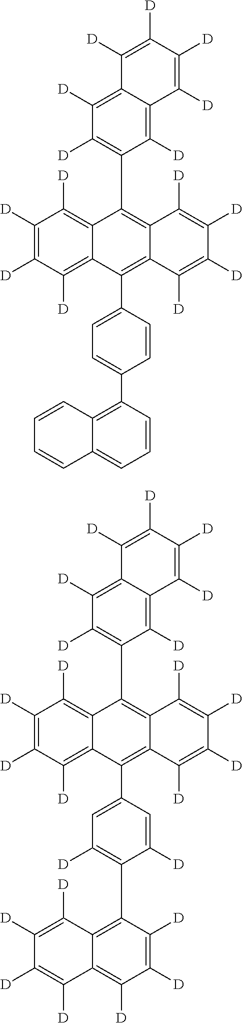

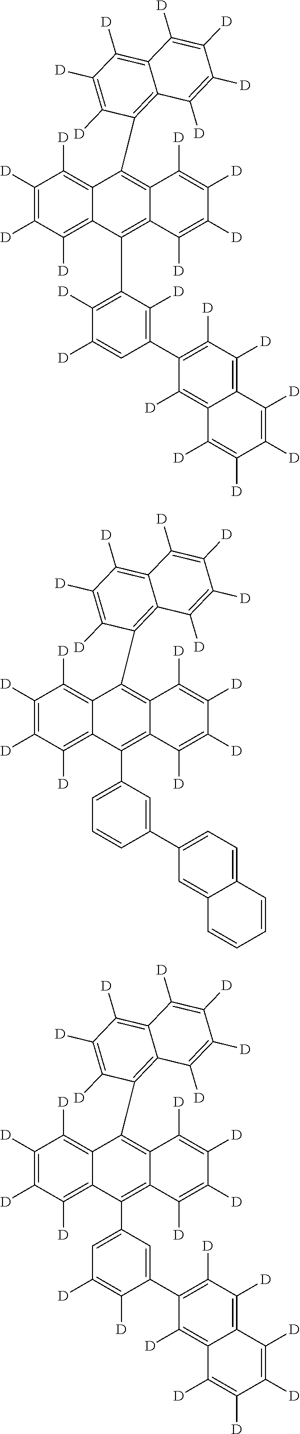

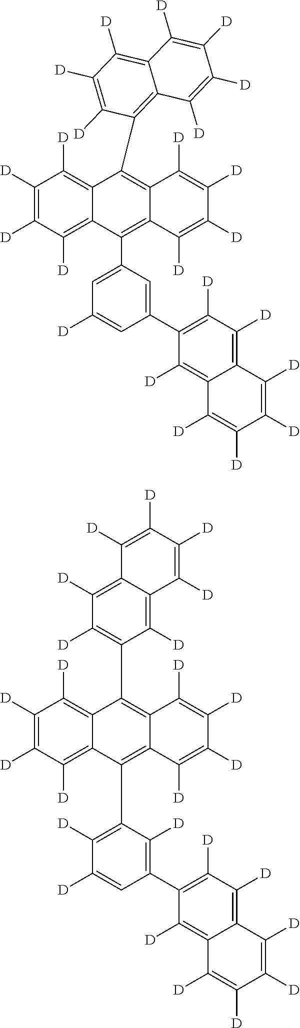 [SMILES: [2H]c1cc(-c2c([2H])c([2H])c3c([2H])c([2H])c([2H])c([2H])c3c2[2H])cc(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c1 ; [2H]c1cc(-c2c([2H])c([2H])c3c([2H])c([2H])c([2H])c([2H])c3c2[2H])c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c1[2H]]

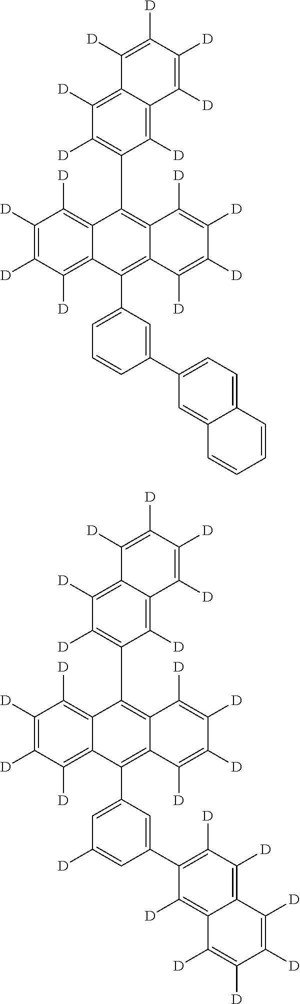 [SMILES: [2H]c1c([2H])c([2H])c2c([2H])c(-c3c4c([2H])c([2H])c([2H])c([2H])c4c(-c4cccc(-c5ccc6ccccc6c5)c4)c4c([2H])c([2H])c([2H])c([2H])c34)c([2H])c([2H])c2c1[2H] ; [2H]c1cc(-c2c([2H])c([2H])c3c([2H])c([2H])c([2H])c([2H])c3c2[2H])cc(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c1]

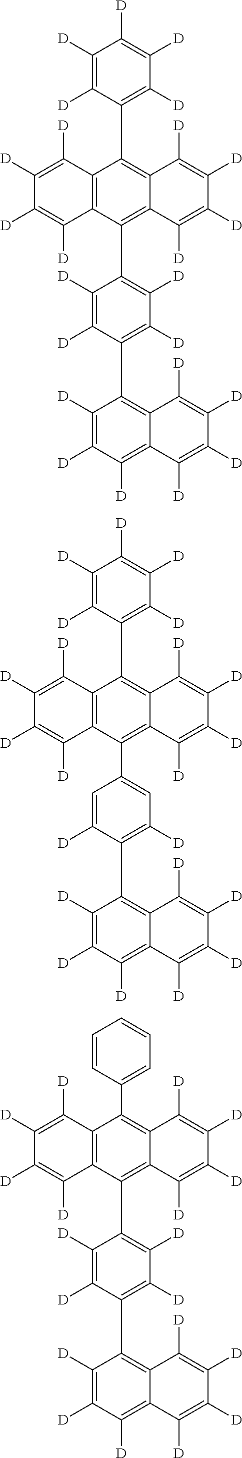

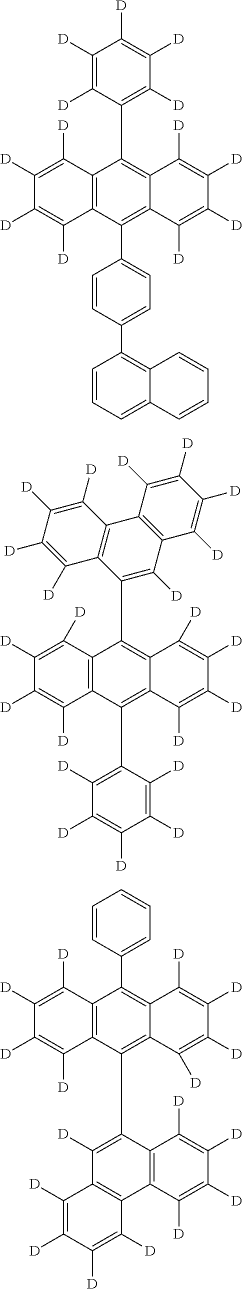

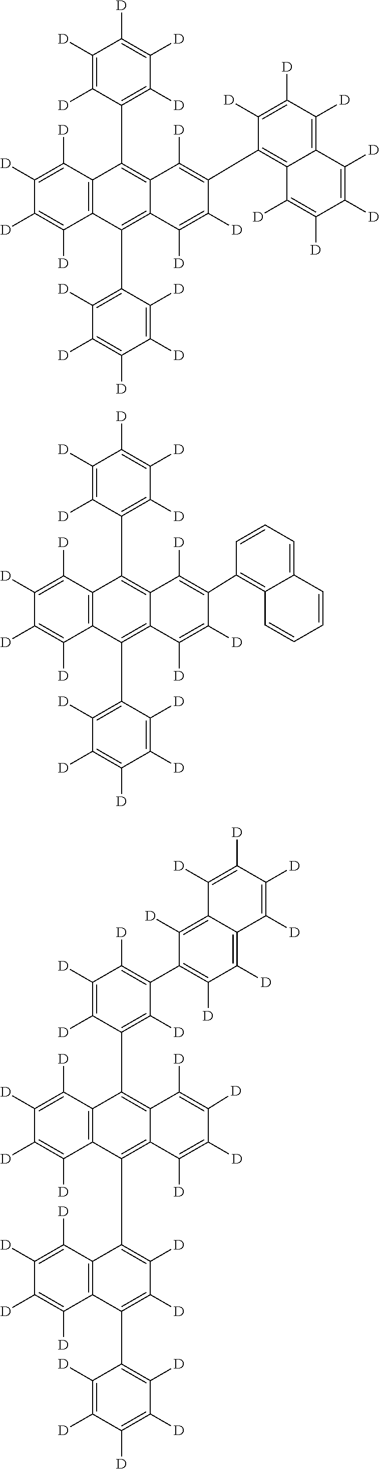

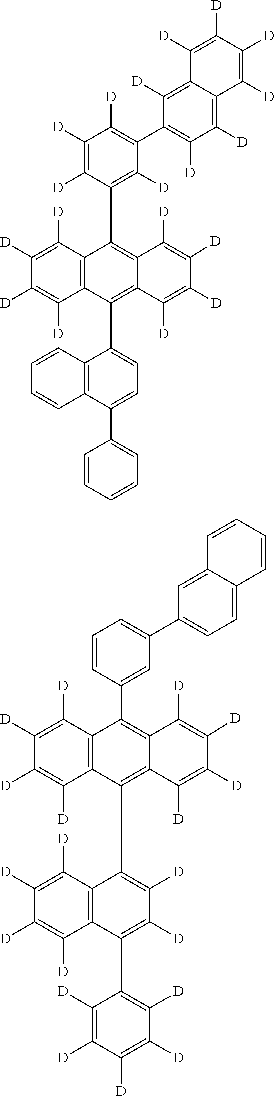 [SMILES: [2H]c1c([2H])c(-c2c([2H])c([2H])c3c([2H])c([2H])c([2H])c([2H])c3c2[2H])c([2H])c(-c2c3c([2H])c([2H])c([2H])c([2H])c3c(-c3ccc(-c4ccccc4)c4ccccc34)c3c([2H])c([2H])c([2H])c([2H])c23)c1[2H] ; [2H]c1c([2H])c([2H])c(-c2c([2H])c([2H])c(-c3c4c([2H])c([2H])c([2H])c([2H])c4c(-c4cccc(-c5ccc6ccccc6c5)c4)c4c([2H])c([2H])c([2H])c([2H])c34)c3c([2H])c([2H])c([2H])c([2H])c23)c([2H])c1[2H]]

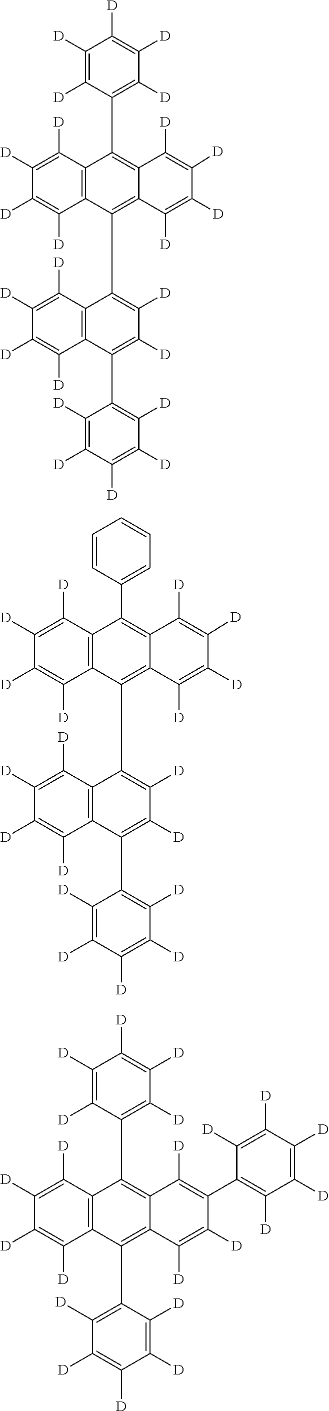

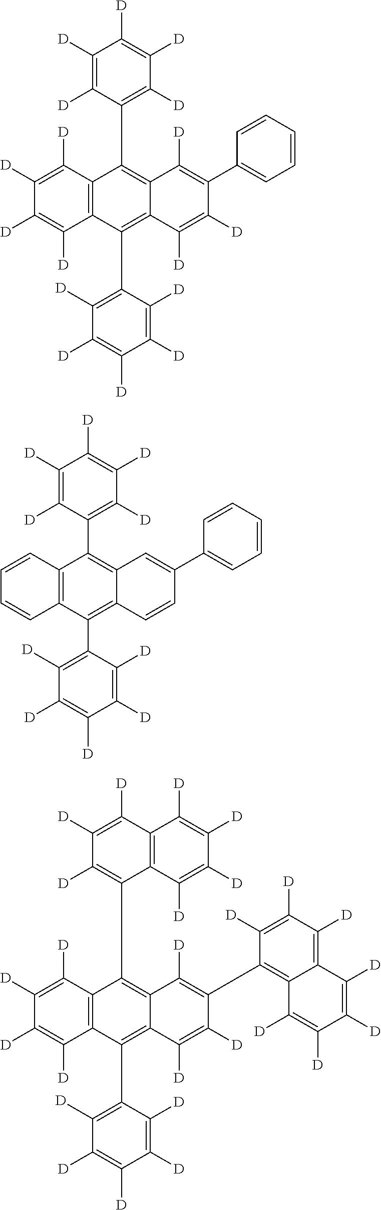

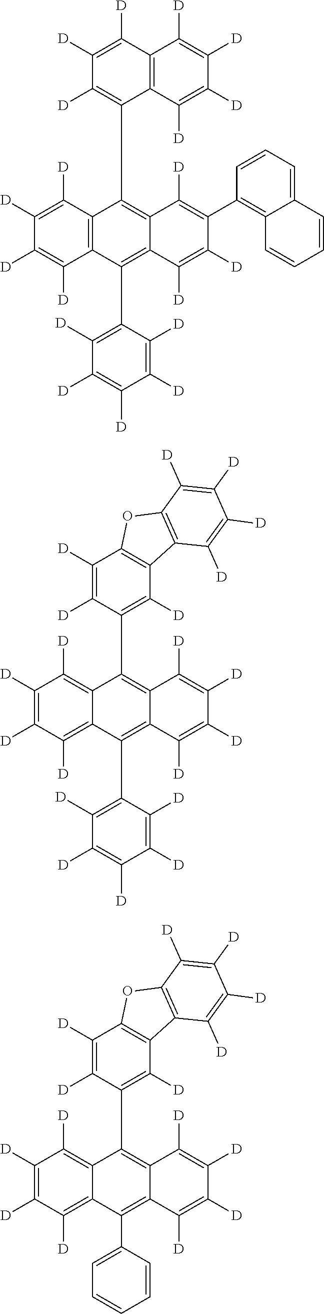 [SMILES: [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c(-c4cccc5ccccc45)c([2H])c([2H])c23)c([2H])c1[2H] ; [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H] ; [2H]c1c([2H])c([2H])c2c(oc3c([2H])c([2H])c(-c4c5c([2H])c([2H])c([2H])c([2H])c5c(-c5ccccc5)c5c([2H])c([2H])c([2H])c([2H])c45)c([2H])c32)c1[2H]]

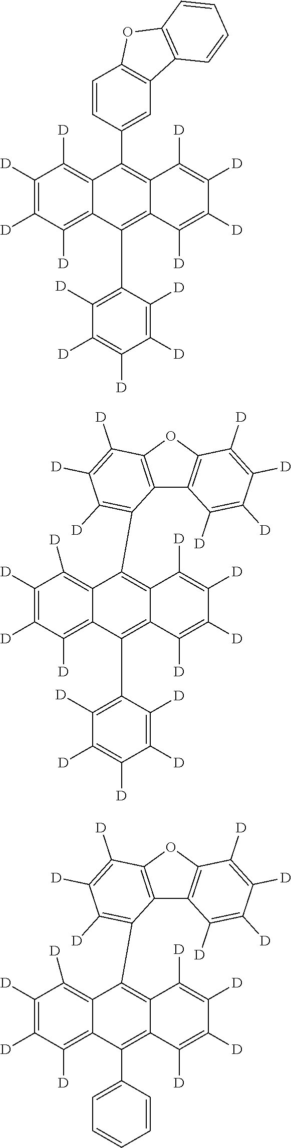

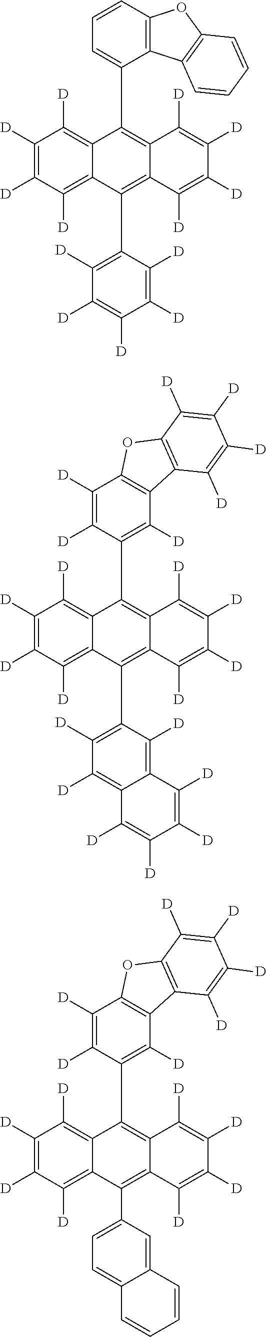

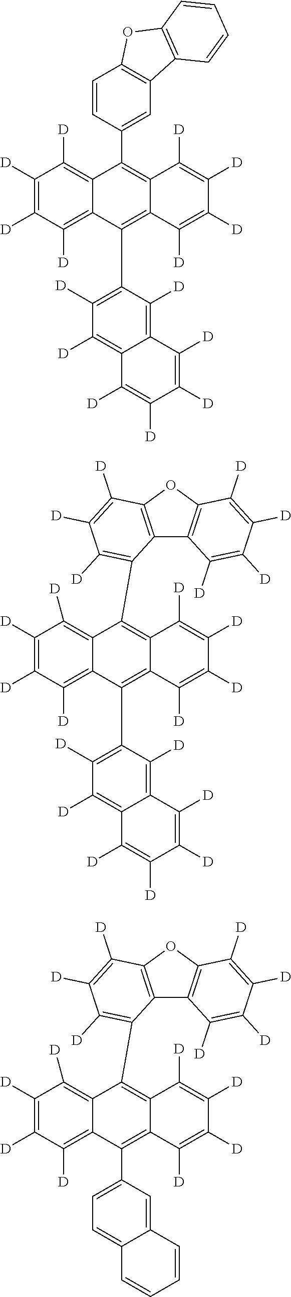 [SMILES: [2H]c1c([2H])c([2H])c2c([2H])c(-c3c4c([2H])c([2H])c([2H])c([2H])c4c(-c4ccc5oc6ccccc6c5c4)c4c([2H])c([2H])c([2H])c([2H])c34)c([2H])c([2H])c2c1[2H] ; [2H]c1c([2H])c([2H])c2c(oc3c([2H])c([2H])c([2H])c(-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c32)c1[2H] ; [2H]c1c([2H])c([2H])c2c(oc3c([2H])c([2H])c([2H])c(-c4c5c([2H])c([2H])c([2H])c([2H])c5c(-c5ccc6ccccc6c5)c5c([2H])c([2H])c([2H])c([2H])c45)c32)c1[2H]]

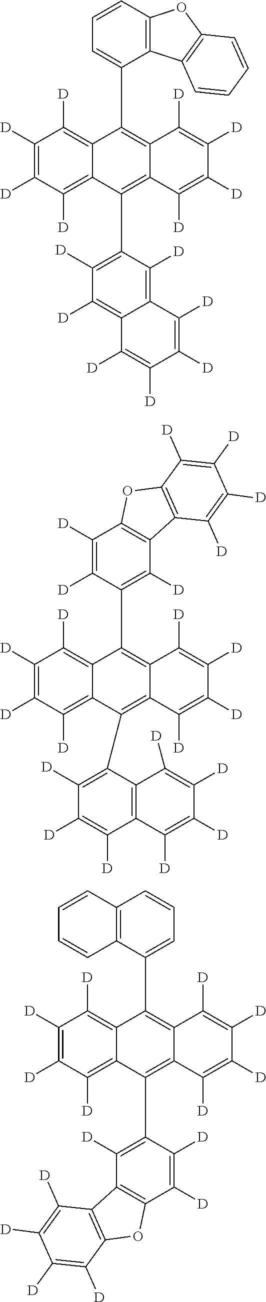

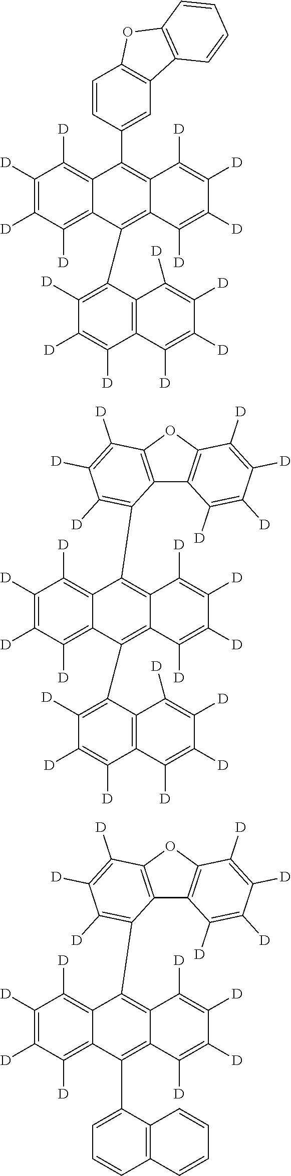

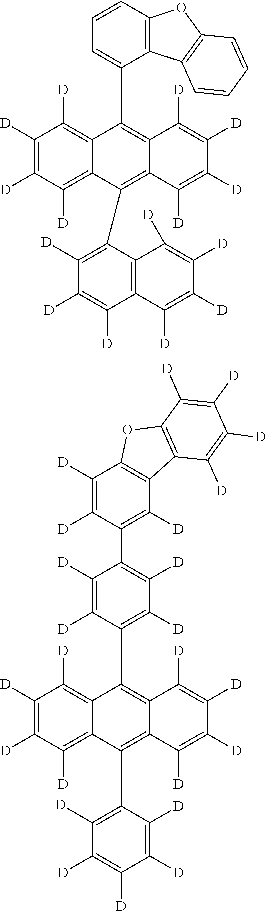

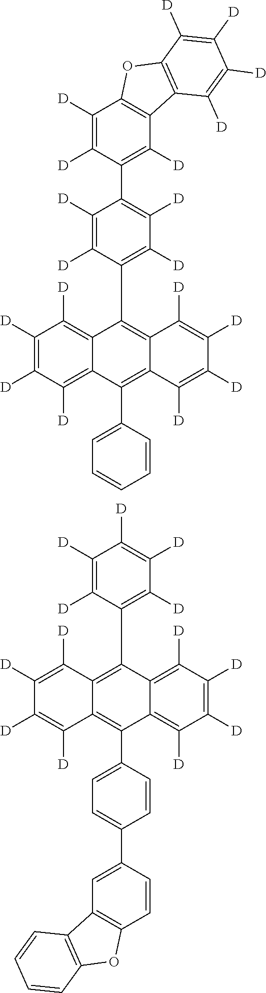

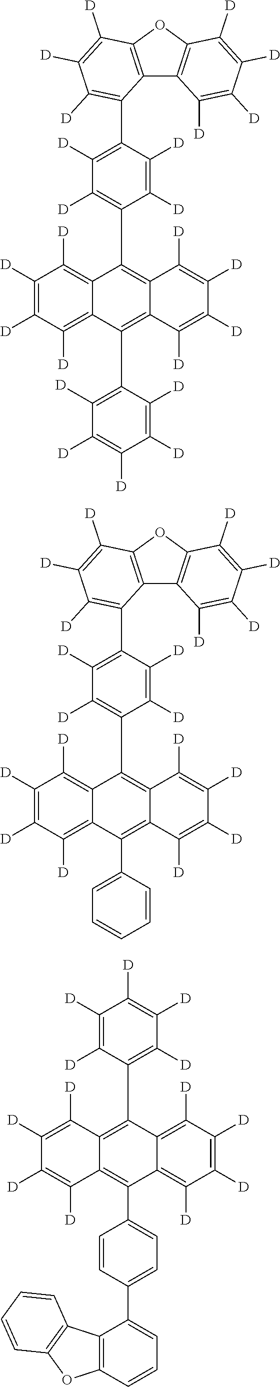

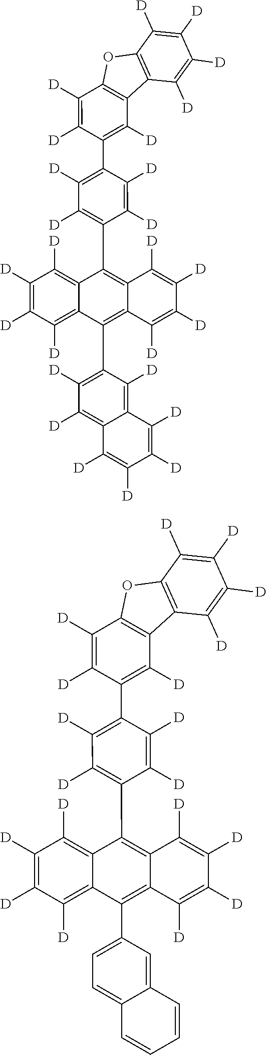 [SMILES: [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c2oc3c([2H])c([2H])c([2H])c([2H])c3c2c1[2H] ; [2H]c1c([2H])c(-c2c3c([2H])c([2H])c([2H])c([2H])c3c(-c3ccc4ccccc4c3)c3c([2H])c([2H])c([2H])c([2H])c23)c([2H])c([2H])c1-c1c([2H])c([2H])c2oc3c([2H])c([2H])c([2H])c([2H])c3c2c1[2H]]

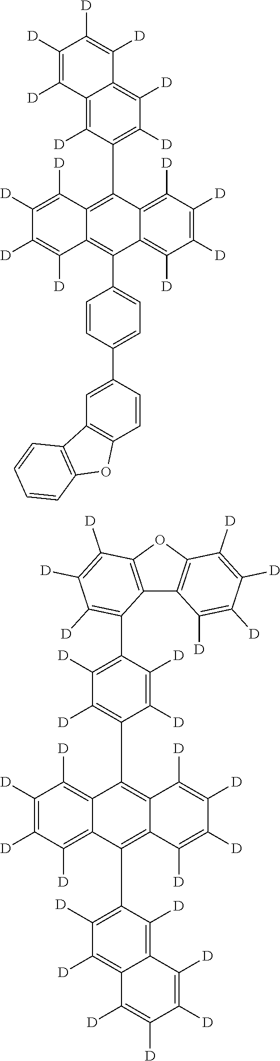

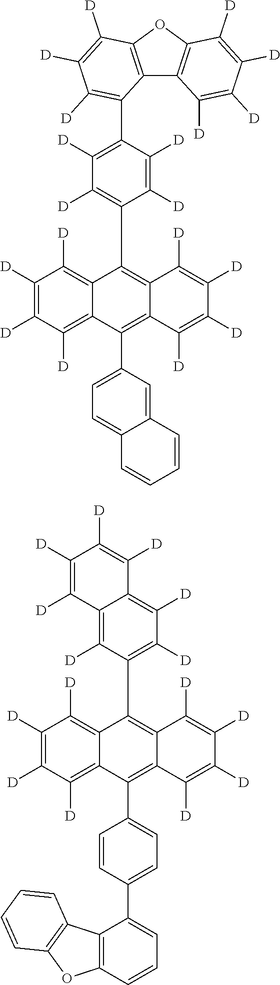 [SMILES: [2H]c1c([2H])c(-c2c([2H])c([2H])c([2H])c3oc4c([2H])c([2H])c([2H])c([2H])c4c23)c([2H])c([2H])c1-c1c2c([2H])c([2H])c([2H])c([2H])c2c(-c2ccc3ccccc3c2)c2c([2H])c([2H])c([2H])c([2H])c12 ; [2H]c1c([2H])c([2H])c2c([2H])c(-c3c4c([2H])c([2H])c([2H])c([2H])c4c(-c4ccc(-c5cccc6oc7ccccc7c56)cc4)c4c([2H])c([2H])c([2H])c([2H])c34)c([2H])c([2H])c2c1[2H]]

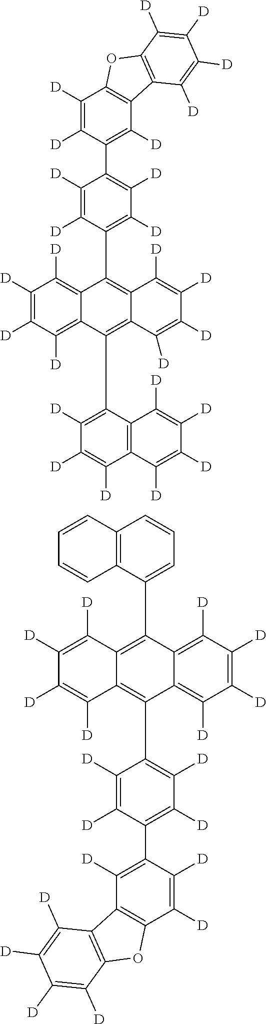

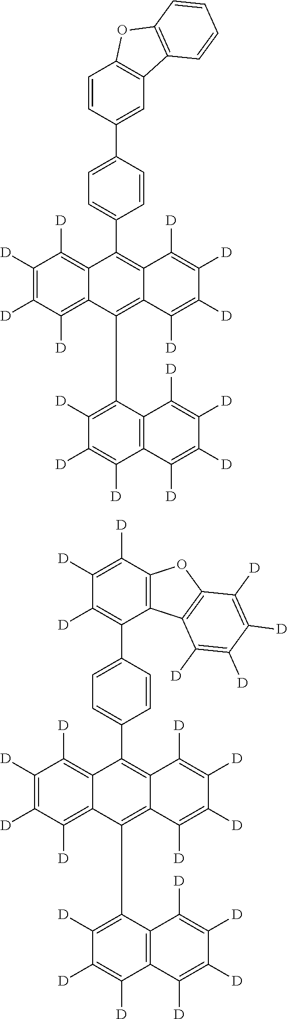

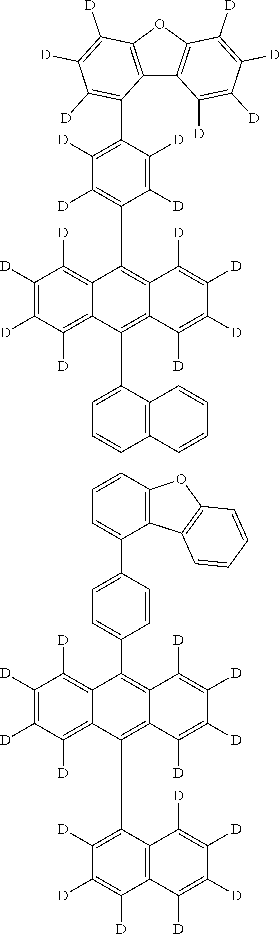

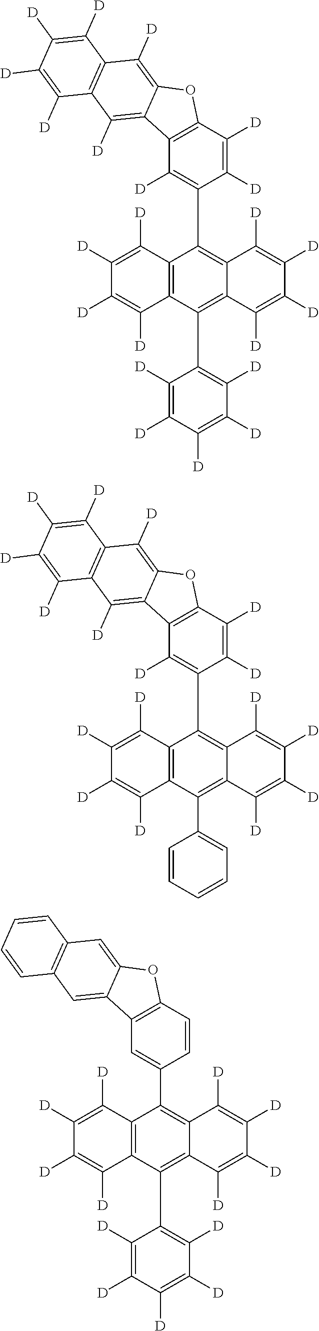 [SMILES: [2H]c1c([2H])c([2H])c(-c2c3c([2H])c([2H])c([2H])c([2H])c3c(-c3c([2H])c([2H])c4oc5c([2H])c6c([2H])c([2H])c([2H])c([2H])c6c([2H])c5c4c3[2H])c3c([2H])c([2H])c([2H])c([2H])c23)c([2H])c1[2H] ; [2H]c1c(-c2c3c([2H])c([2H])c([2H])c([2H])c3c(-c3ccccc3)c3c([2H])c([2H])c([2H])c([2H])c23)c([2H])c2c(oc3c([2H])c4c([2H])c([2H])c([2H])c([2H])c4c([2H])c32)c1[2H] ; [2H]c1c([2H])c([2H])c(-c2c3c([2H])c([2H])c([2H])c([2H])c3c(-c3ccc4oc5cc6ccccc6cc5c4c3)c3c([2H])c([2H])c([2H])c([2H])c23)c([2H])c1[2H]]

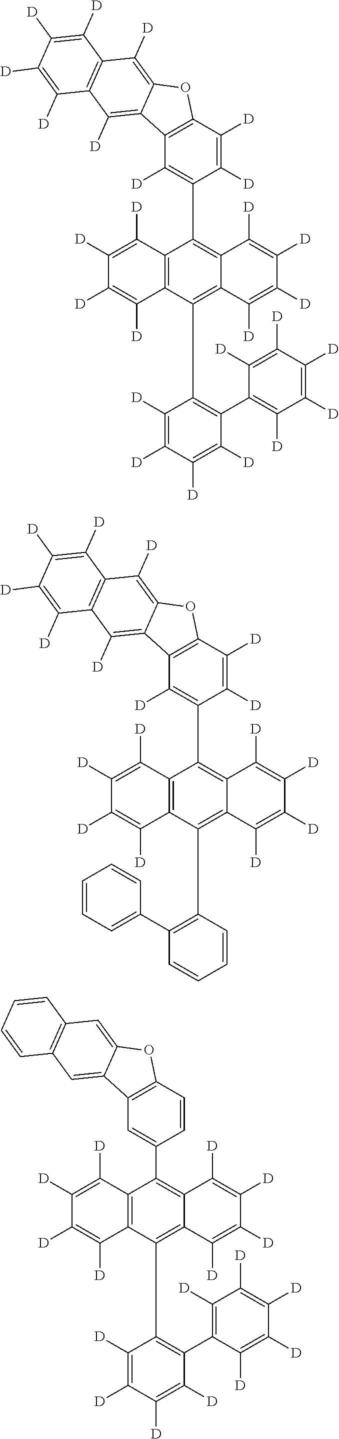

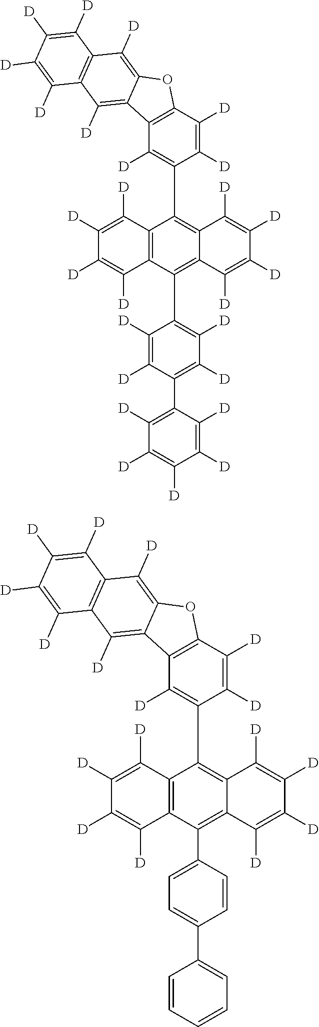 [SMILES: [2H]c1c([2H])c([2H])c(-c2c([2H])c([2H])c(-c3c4c([2H])c([2H])c([2H])c([2H])c4c(-c4c([2H])c([2H])c5oc6c([2H])c7c([2H])c([2H])c([2H])c([2H])c7c([2H])c6c5c4[2H])c4c([2H])c([2H])c([2H])c([2H])c34)c([2H])c2[2H])c([2H])c1[2H] ; [2H]c1c(-c2c3c([2H])c([2H])c([2H])c([2H])c3c(-c3ccc(-c4ccccc4)cc3)c3c([2H])c([2H])c([2H])c([2H])c23)c([2H])c2c(oc3c([2H])c4c([2H])c([2H])c([2H])c([2H])c4c([2H])c32)c1[2H]]

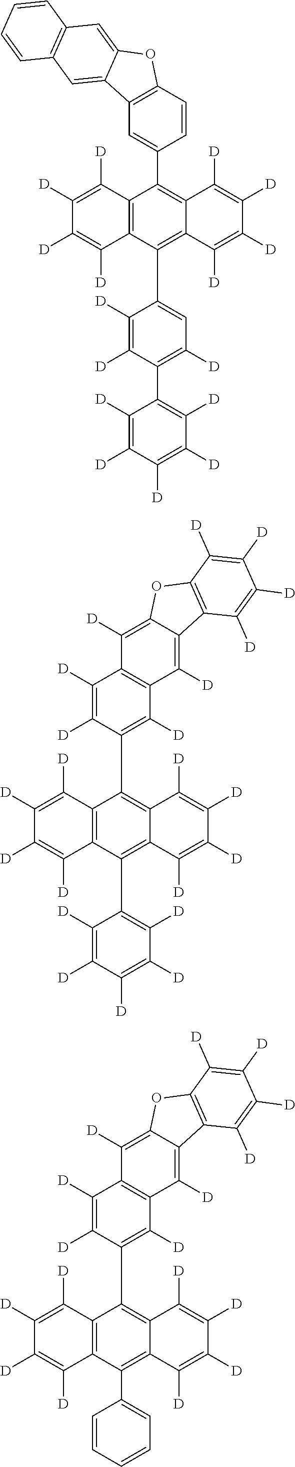

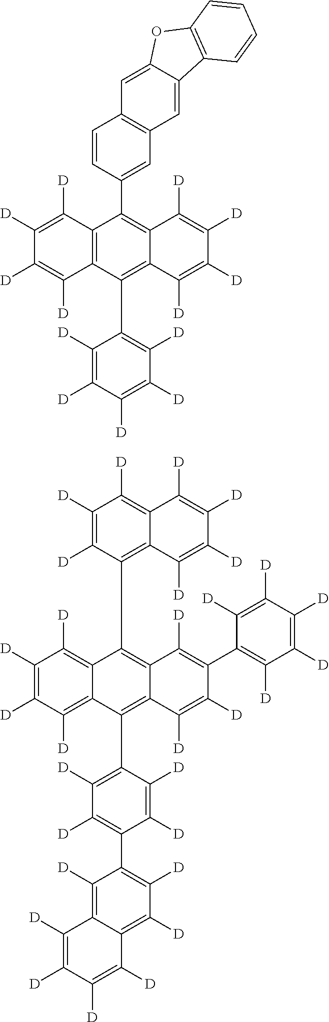

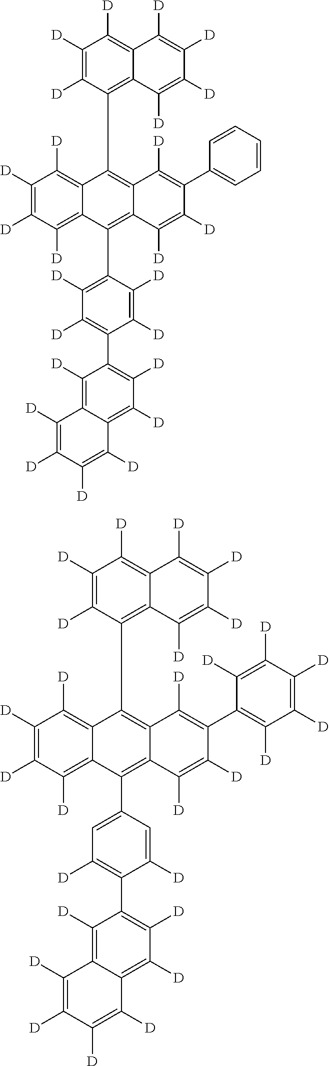 [SMILES: [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c(-c4ccccc4)c([2H])c([2H])c23)c([2H])c([2H])c1-c1c([2H])c([2H])c2c([2H])c([2H])c([2H])c([2H])c2c1[2H] ; [2H]c1cc(-c2c3c([2H])c([2H])c([2H])c([2H])c3c(-c3c([2H])c([2H])c([2H])c4c([2H])c([2H])c([2H])c([2H])c34)c3c([2H])c(-c4c([2H])c([2H])c([2H])c([2H])c4[2H])c([2H])c([2H])c23)cc([2H])c1-c1c([2H])c([2H])c2c([2H])c([2H])c([2H])c([2H])c2c1[2H]]

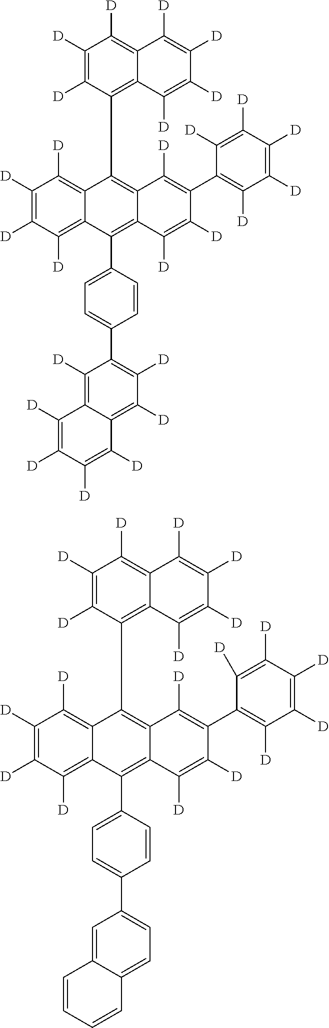 [SMILES: [2H]c1c([2H])c([2H])c(-c2c([2H])c([2H])c3c(-c4ccc(-c5c([2H])c([2H])c6c([2H])c([2H])c([2H])c([2H])c6c5[2H])cc4)c4c([2H])c([2H])c([2H])c([2H])c4c(-c4c([2H])c([2H])c([2H])c5c([2H])c([2H])c([2H])c([2H])c45)c3c2[2H])c([2H])c1[2H] ; [2H]c1c([2H])c([2H])c(-c2c([2H])c([2H])c3c(-c4ccc(-c5ccc6ccccc6c5)cc4)c4c([2H])c([2H])c([2H])c([2H])c4c(-c4c([2H])c([2H])c([2H])c5c([2H])c([2H])c([2H])c([2H])c45)c3c2[2H])c([2H])c1[2H]]

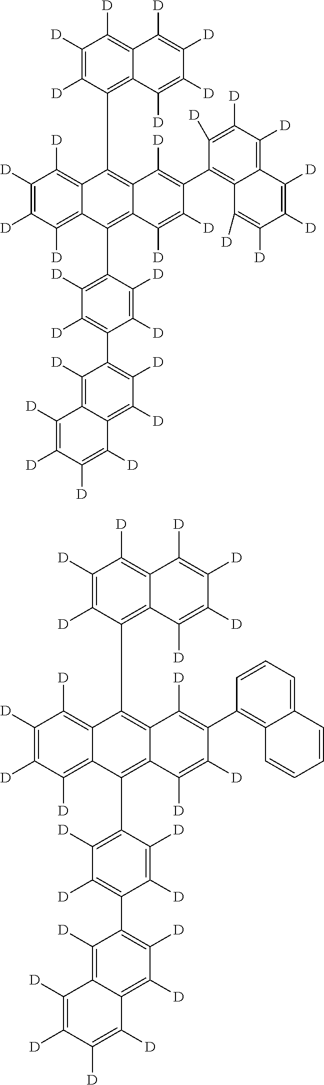 [SMILES: [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c(-c4c([2H])c([2H])c([2H])c5c([2H])c([2H])c([2H])c([2H])c45)c([2H])c([2H])c23)c([2H])c([2H])c1-c1c([2H])c([2H])c2c([2H])c([2H])c([2H])c([2H])c2c1[2H] ; [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c(-c4cccc5ccccc45)c([2H])c([2H])c23)c([2H])c([2H])c1-c1c([2H])c([2H])c2c([2H])c([2H])c([2H])c([2H])c2c1[2H]]

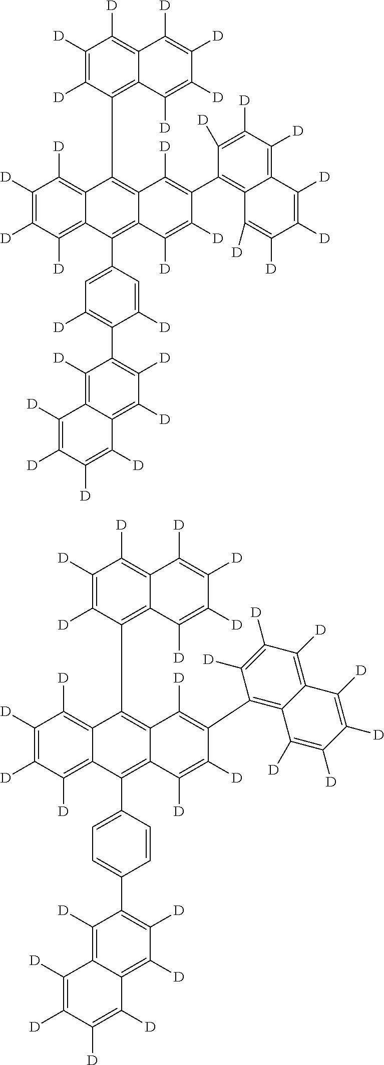

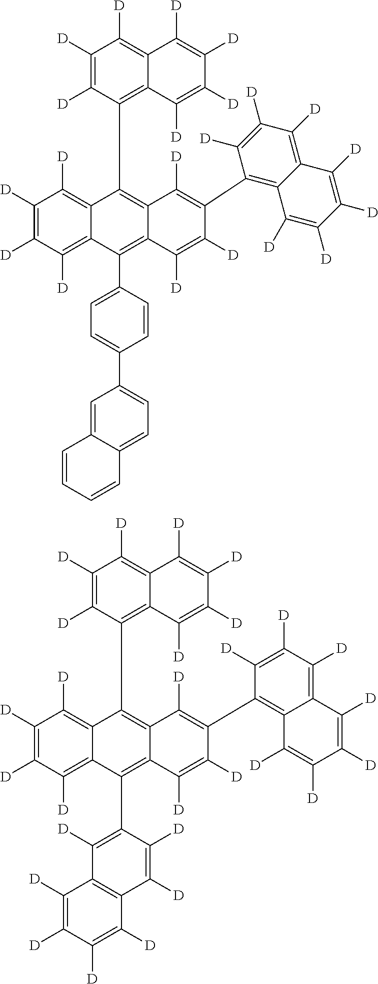

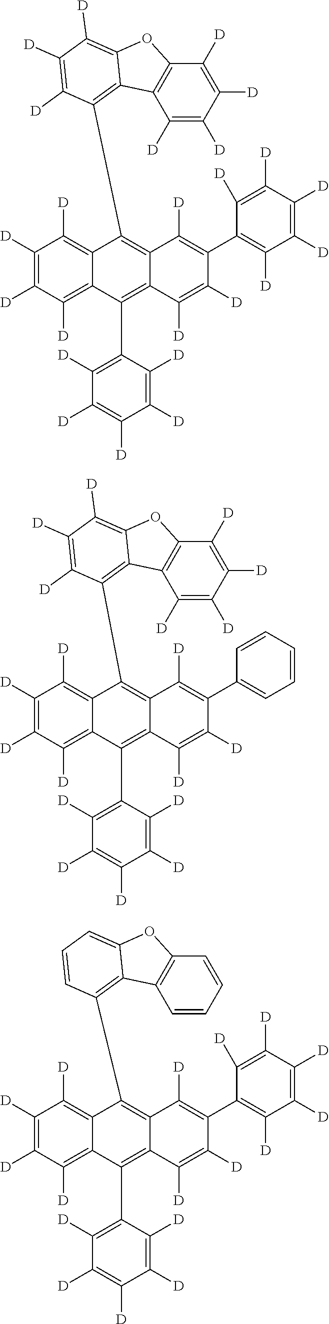

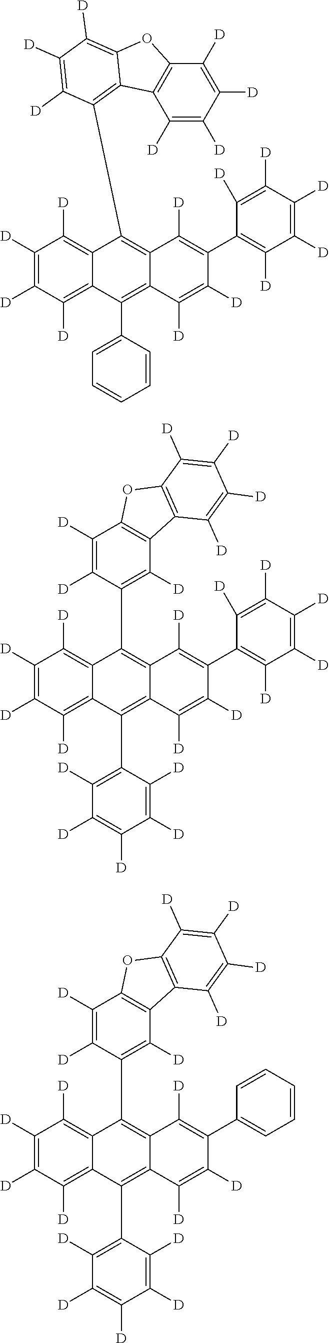

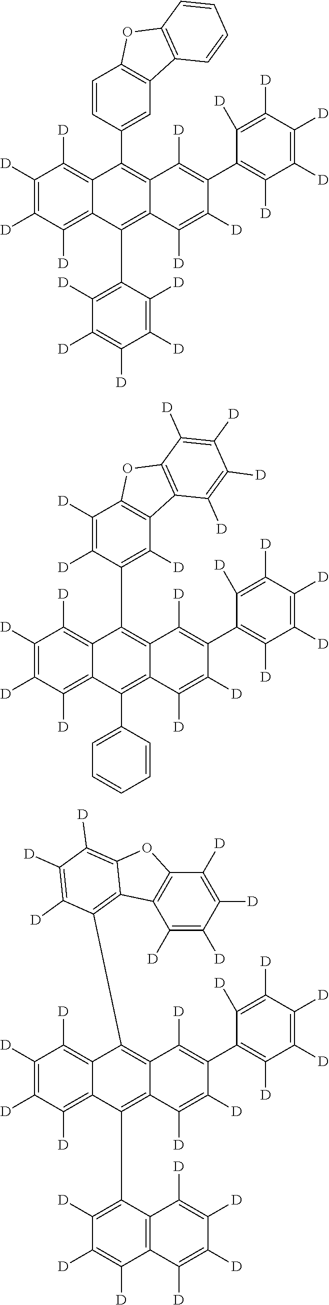

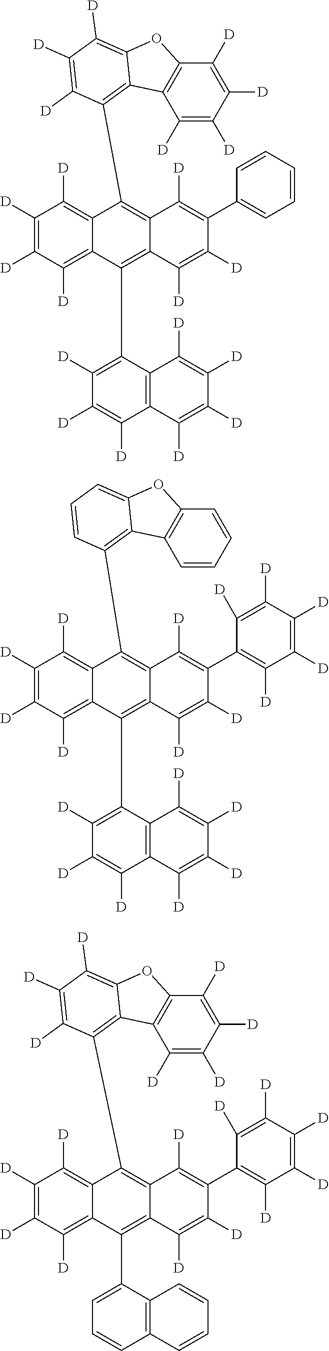

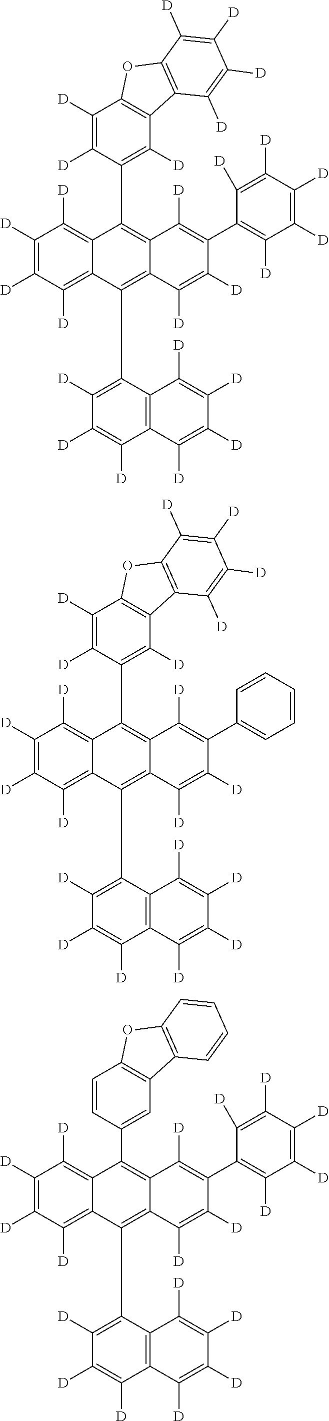

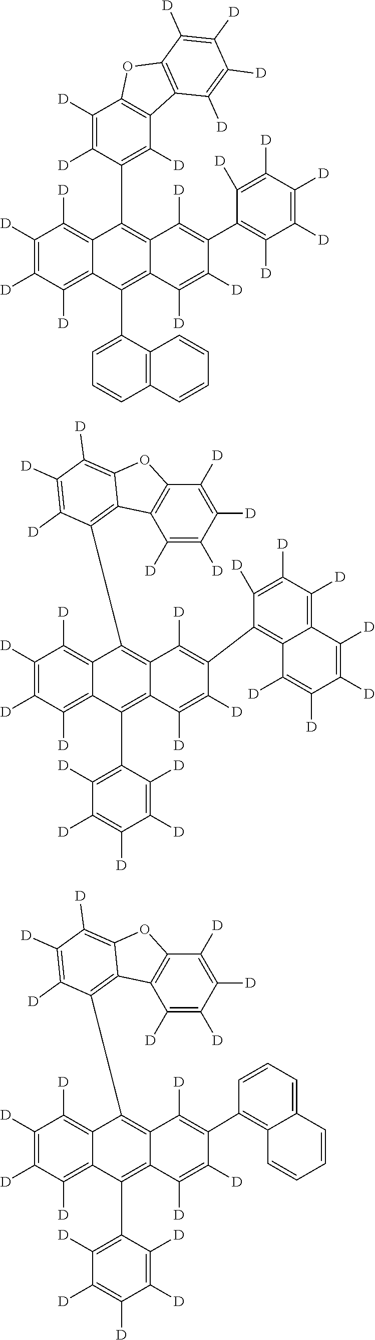

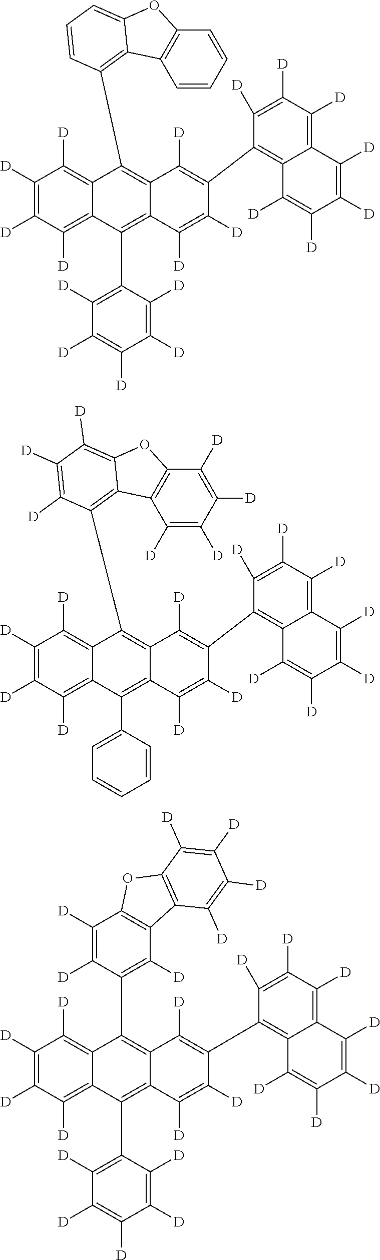

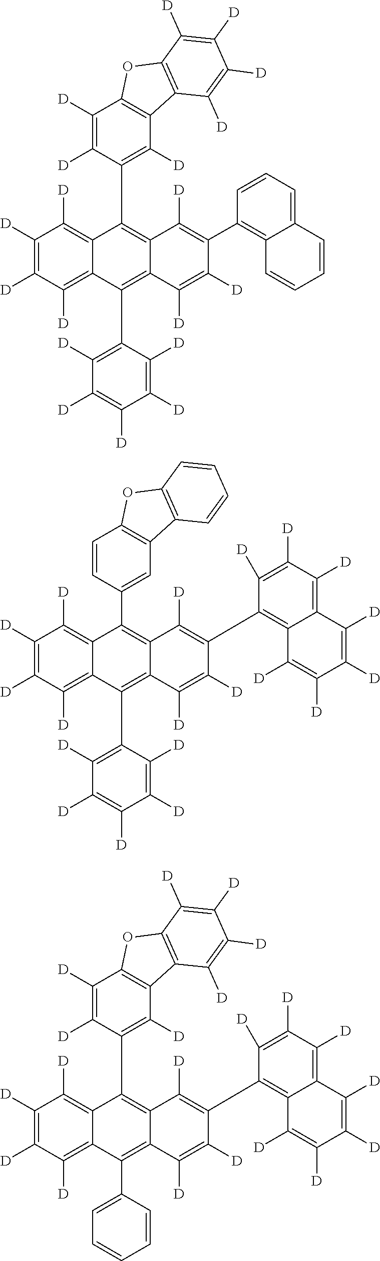

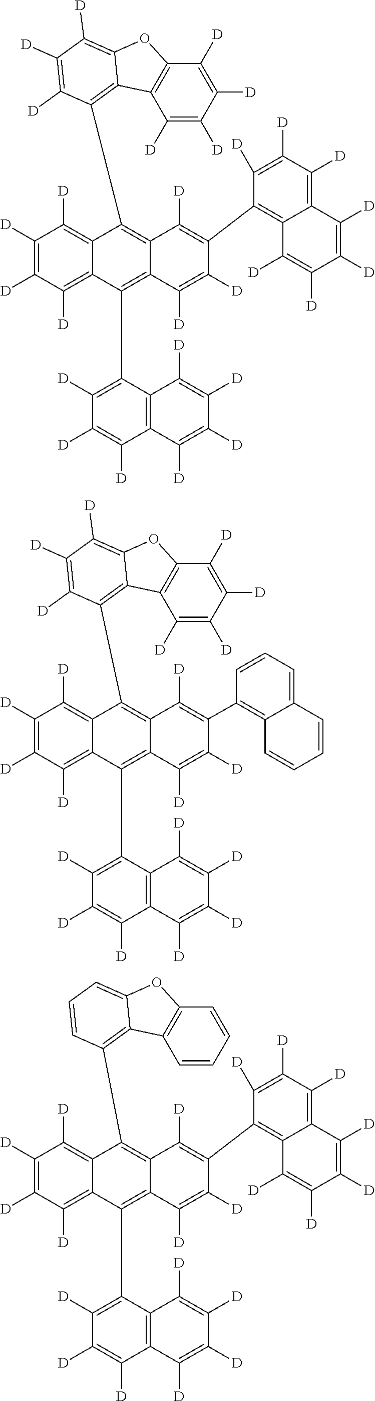

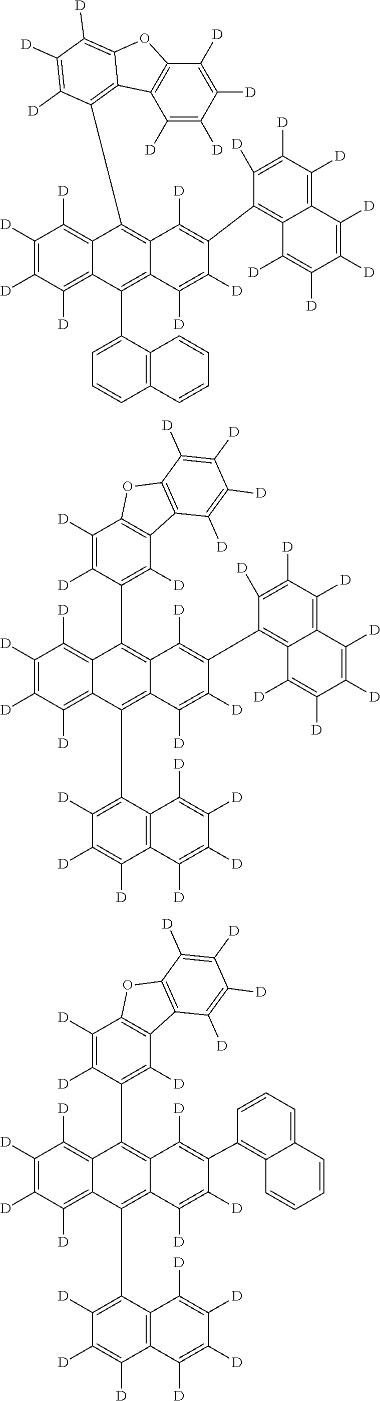

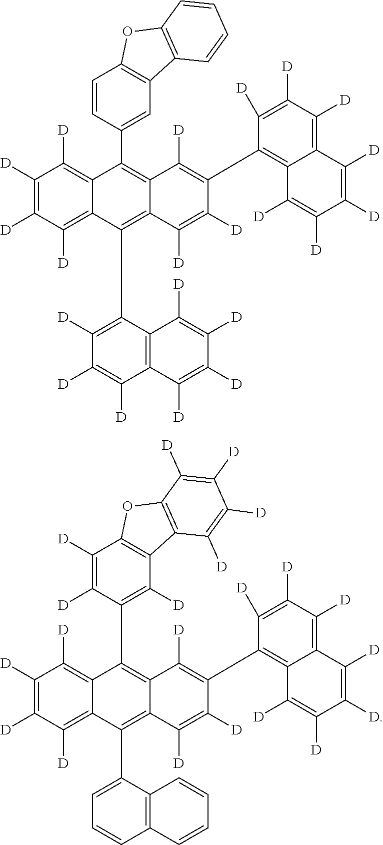

14. The organic light emitting device of claim 1, wherein the second organic material layer is provided in contact with the first organic material layer.

15. The organic light emitting device of claim 1, further comprising one or more organic material layers among a hole transfer layer, a hole injection layer, an electron blocking layer, an electron transfer and injection layer, an electron transfer layer, an electron injection layer, a hole blocking layer, and a hole transfer and injection layer.
